(19) United States
(12) Patent Application Publication
(10) Pub. No.: US 2002/0053000 A1
(43) Pub. Date: May 2, 2002

(54) Information processing apparatus and method, and computer readable memory

(76) Inventors: Masanori Wakai, Kanagawa (JP); Naoko Yamamoto, Kanagawa (JP)

Correspondence Address: FITZPATRICK CELLA HARPER & SCINTO, 30 ROCKEFELLER PLAZA, NEW YORK, NY, 10112, US

(21) Appl. No.: 09/984,698

(22) Filed: Oct. 31, 2001

(30) Foreign Application Priority Data
Nov. 2, 2000 (JP) 336529/2000
Nov. 2, 2000 (JP) 336531/2000

(51) Int. Cl. G11C 5/00

(52) U.S. Cl. 711/1

(57) ABSTRACT

An application IF layer interprets and processes manipulations of an application program. A database IF layer interprets and processes manipulations common to a plurality of types of databases. Individual database manipulation implementation embedded in the database IF layer executes processes unique to databases for each of the plurality of types of databases.

### FIELD OF THE INVENTION

The present invention relates to an information processing apparatus and method for processing a database that manages data, and a computer readable memory.

### BACKGROUND OF THE INVENTION

In prior arts, databases are often used to process permanent data, but complicated know-how including a coding sequence unique to a database module is required for this purpose. Since an application developer must implement according to interfaces corresponding to individual databases after he dr she has learned about these individual interfaces, development efficiency drop and quality drop may occur.

### SUMMARY OF THE INVENTION

The present invention has been made in consideration of the aforementioned problems, and has its object to provide an information processing apparatus and method, which can improve application development efficiency, and a computer readable memory

According to the present invention, the foregoing object is attained by providing an information processing apparatus for processing a database that manages data, comprising: a plurality of types of databases for storing the data; application interface interpretation processing means for interpreting and processing manipulations between the plurality of types of databases and an application program; database interface interpretation processing means for interpreting and processing manipulations common to the plurality of types of databases; and a plurality of individual database processing means for executing a processes unique to each database for each of the plurality of types of databases.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is a block diagram showing the hardware arrangement of an information processing apparatus according to the first embodiment of the present invention;

FIG. 2 is a flow chart showing the processing executed by the information processing apparatus of the first embodiment;

FIG. 3 shows an example of a database processing window of the first embodiment;

FIG. 4 is a flow chart showing details of a database process in step s205 of the first embodiment;

FIG. 5 shows an example of a transaction generation window of the first embodiment;

FIG. 6 is a flow chart showing details of a transaction generate process in step s406 of the first embodiment;

FIG. 7 shows an example of a transaction processing window of the first embodiment;

FIG. 8 is a flow chart showing details of a transaction process in step s408 of the first embodiment;

FIG. 9 shows an example of an additional object select window of the first embodiment;

FIG. 10 is a flow chart showing details of an object select/add process corresponding to an object add instruction in an event-induced process of the first embodiment;

FIG. 11 shows an example of an object edit window upon creating a new object in the first embodiment;

FIG. 12 is a flow chart showing details of an object generate process in step s1006 of the first embodiment;

FIG. 13 shows an example of a class select window of the first embodiment;

FIG. 14 shows an example of an object edit window upon editing an existing object in the first embodiment;

FIG. 15 is a flow chart showing details of an object select/edit process of the first embodiment;

FIG. 16 shows an example of an object reference window upon referring to an existing object in the first embodiment;

FIG. 17 is a flow chart showing details of an object select/delete process of the first embodiment;

FIG. 18 is a flow chart showing details of an all object acquisition confirm process in steps s1503 and s1703 of the first embodiment;

FIG. 19 is a flow chart showing details of an object addition confirm process in step s1007 of the first embodiment;

FIG. 20 is a flow chart showing details of an object update confirm process in step s1509 of the first embodiment;

FIG. 21 is a flow chart showing details of an object deletion confirm process in step s1709 of the first embodiment;

FIG. 22 is a diagram showing the functional arrangement of the information processing apparatus of the first embodiment;

FIG. 23 shows internal data of a DB transaction of the first embodiment;

FIG. 24 is a flow chart showing details of a DB transaction generate process in step s603 of the first embodiment;

FIG. 25 is a flow chart showing details of a DB transaction start process in steps s1801, s1901, s2001, and s2101 of the first embodiment;

FIG. 26 is a flow chart showing details of a DB transaction confirm process in steps s1804, s1904, s2004, and s2104 of the first embodiment;

FIG. 27 is a flow chart showing details of a DB transaction cancel process in steps s1805, s1905, s2005 and s2105 of the first embodiment;

FIG. 28 shows the relationships among objects used in the information processing apparatus of the first embodiment;

FIG. 29 shows programming codes of an application object of the first embodiment;

FIG. 30 shows a list of database objects of the first embodiment;

FIG. 31 is a flow chart showing details of an all object acquire process in step s1802 of the first embodiment;

FIG. 32 is a flow chart showing details of an object add process in step s1902 of the first embodiment;

FIG. 33 is a flow chart showing details of an object update process in step s2002 of the first embodiment;

FIG. 34 is a flow chart showing details of an object delete process in step s2102 of the first embodiment;

FIG. 35 is a flow chart showing details of an all DB object acquire process in step s5902 of the first embodiment;

FIG. 36 is a flow chart showing details of a DB object generate/add process in step s6002 of the first embodiment;

FIG. 37 is a flow chart showing details of a DB object delete process in step s6204 of the first embodiment;

FIG. 38 is a flow chart showing details of a DB object value set process in steps s5907 and s6003 of the first embodiment;

FIG. 39 is a flow chart showing details of an object generate process in step s5906 of the first embodiment;

FIG. 40 is a flow chart showing details of an object value set process in step s5907 of the first embodiment;

FIG. 41 is a flow chart showing details of an all writable field name acquire process in steps s7301 and s7501 of the first embodiment;

FIG. 42 is a diagram showing hierarchically structured database manipulation means of an information processing apparatus of the second embodiment;

FIG. 43 shows a hierarchical DB transaction structure of the second embodiment;

FIG. 44 shows internal data of a hierarchical DB transaction of the second embodiment;

FIG. 45 shows an example of a transaction generation window upon selecting the type of database of the second embodiment;

FIG. 46 shows an example of a transaction generation window upon inputting a server name of the second embodiment;

FIG. 47 is a flow chart showing details of a DB transaction generate process of the second embodiment;

FIG. 48 shows an example of the relationship between packages as groups of some purposes of the hierarchical DB transaction structure of the second embodiment;

FIG. 49 shows an example of the relationship between classes of the hierarchical DB transaction structure of the second embodiment;

FIG. 50 shows an example of a basic class layer of the hierarchical DB transaction structure of the second embodiment;

FIG. 51 shows an example of the hierarchical transaction structure when a database is present on the same device as an application program in the second embodiment;

FIG. 52 shows an example of a basic class layer upon expansion to a local database in the second embodiment;

FIG. 53 shows an example of a hierarchical DB transaction structure when a database is present on a device different from an application program in the second embodiment;

FIG. 54 shows an example of a basic class layer upon expansion to a remote database in the second embodiment;

FIG. 55 shows an example of a hierarchical transaction structure when a database service is provided to application programs on different devices in the second embodiment;

FIG. 56 shows an example of a basic class layer when a remote interface is expanded to allow use of a database IF layer from different devices in the second embodiment;

FIG. 57 shows an example of an application program in which a plurality of databases of different interfaces, which are present on different devices, are embedded using the second embodiment;

FIG. 58 shows an application program in which databases of different interfaces are embedded in the prior art;

FIG. 59 shows an application program in which databases on different devices are embedded in the prior art;

FIG. 60 shows an application program in which a database on an identical device is embedded using the same interface as that of a database on another device in the prior art;

FIG. 61 shows the flow of notify information upon a change in database or the like in the third embodiment;

FIG. 62 shows a hierarchical DB transaction structure of an information processing apparatus of the third embodiment;

FIG. 63 shows internal data of a hierarchical DB transaction of the third embodiment;

FIG. 64 is a flow chart showing details of a transaction discard process in step s409 of the third embodiment;

FIG. 65 is a flow chart showing details of a DB transaction generate process of the third embodiment;

FIG. 66 is a flow chart showing details of a DB transaction discard process in step s10301 of the third embodiment;

FIG. 67 is a flow chart showing details of a DB object generate/add process in step s6002 of the third embodiment;

FIG. 68 is a flow chart showing details of a DB object delete process of the third embodiment;

FIG. 69 is a flow chart showing details of a DB object value set process in steps s5907 and s6003 of the third embodiment;

FIG. 70 is a flow chart showing details of a DB transaction confirm process in steps s1804, s1904, s2004, and s2104 of the third embodiment;

FIG. 71 is a flow chart showing details of an update information generate/notify process in step s10906 of the third embodiment;

FIG. 72 shows an example of notify information generated by an update notify information generate process in step s11008 of the third embodiment;

FIG. 73 is a flow chart showing details of an add notify information generate process in step s11002 of the third embodiment;

FIG. 74 is a flow chart showing details of a delete notify information generate process in step s11005 of the third embodiment;

FIG. 75 is a flow chart showing details of an update notify information generate process in step s11008 of the third embodiment;

FIG. 76 is a flow chart showing details of a DBM add notify information notify process in step s11003 of the third embodiment;

FIG. 77 is a flow chart showing details of a DBM delete notify information notify process in step s11006 of the third embodiment;

FIG. 78 is a flow chart showing details of a DBM update notify information notify process in step s11009 of the third embodiment;

FIG. 79 is a flow chart showing details of a transaction add notify information notify process in step s11503 of the third embodiment;

FIG. 80 is a flow chart showing details of a transaction delete notify information notify process in step s11603 of the third embodiment;

FIG. 81 is a flow chart showing details of a transaction update notify information notify process in step s11703 of the third embodiment;

FIG. 82 is a flow chart showing details of a DB listener add notify information notify process in step s11804 of the third embodiment;

FIG. 83 is a flow chart showing details of a DB listener delete notify information notify process in step s11904 of the third embodiment;

FIG. 84 is a flow chart showing details of a DB listener update notify information notify process in step s12004 of the third embodiment;

FIG. 85 is a diagram showing the functional arrangement of an information processing apparatus of the fourth embodiment;

FIG. 86 shows a hierarchical DB transaction structure of the fourth embodiment;

FIG. 87 shows the flow of notify information in the server & remote arrangement upon change in database and the like in the fourth embodiment;

FIG. 88 shows internal data of a hierarchical DB transaction of the fourth embodiment;

FIG. 89 is a flow chart showing details of a DB transaction generate process in step s603 of the fourth embodiment;

FIG. 90 is a flow chart showing details of a remote-embedded DB transaction generate process in step s13410 of the fourth embodiment;

FIG. 91 is a flow chart showing details of a server-embedded DB transaction generate process in step s13505 of the fourth embodiment;

FIG. 92 is a flow chart showing details of a notifying remote add notify information notify process of the fourth embodiment;

FIG. 93 is a flow chart showing details of a notifying remote delete notify information notify process of the fourth embodiment;

FIG. 94 is a flow chart showing details of a notifying remote update notify information notify process of the fourth embodiment;

FIG. 95 is a flow chart showing details of a notifying server add notify information notify process in step s13703 of the fourth embodiment;

FIG. 96 is a flow chart showing details of a notifying server delete notify information notify process in step s13803 of the fourth embodiment;

FIG. 97 is a flow chart showing details of a notifying server update notify information notify process in step s13903 of the fourth embodiment;

FIG. 98 shows an example of an application program in which a plurality of databases present on different devices are embedded in an embodiment;

FIG. 99 shows an example of an application program in which a plurality of databases using identical interfaces, which are present on different devices, are embedded in the prior art; and

FIG. 100 shows an example of expanded inter-device communication means so that a local database can be similarly handled as a server database in the prior art.

### DESCRIPTION OF THE PREFERRED EMBODIMENTS

Preferred embodiments of the present invention will be described in detail hereinafter with reference to the accompanying drawings.

<First Embodiment>

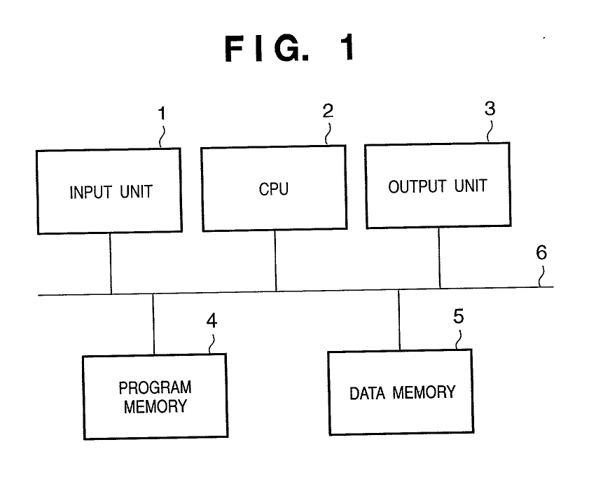

FIG. 1 is a block diagram showing the hardware arrangement of an information processing apparatus of the first embodiment.

Referring to FIG. 1, reference numeral 1 denotes an input unit for inputting information (data). Reference numeral 2 denotes a CPU which makes arithmetic operations, logical decisions, and the like for various processes to control respective building components connected to a bus 6. Reference numeral 3 denotes an output unit for outputting information (data). The output unit 3 includes a display such as an LCD, CRT, or the like, or a recording apparatus such as a printer or the like.

Reference numeral 4 denotes a program memory for storing programs for control by the CPU 2 that includes processing sequences of flow charts to be described later. The program memory 4 may comprise a ROM or a RAM to which a program is loaded from an external storage device or the like.

Reference numeral 5 denotes a data memory for storing data produced by various processes, and also data of a database (DB) to be described later. The data memory 5 comprises, e.g., a RAM, and data of the database are loaded from a nonvolatile external storage medium prior to processes or are referred to as needed.

Reference numeral 6 denotes a bus for transferring address signals that designate building components to be controlled by the CPU 2, control signals for controlling respective building components, and data exchanged among respective building components.

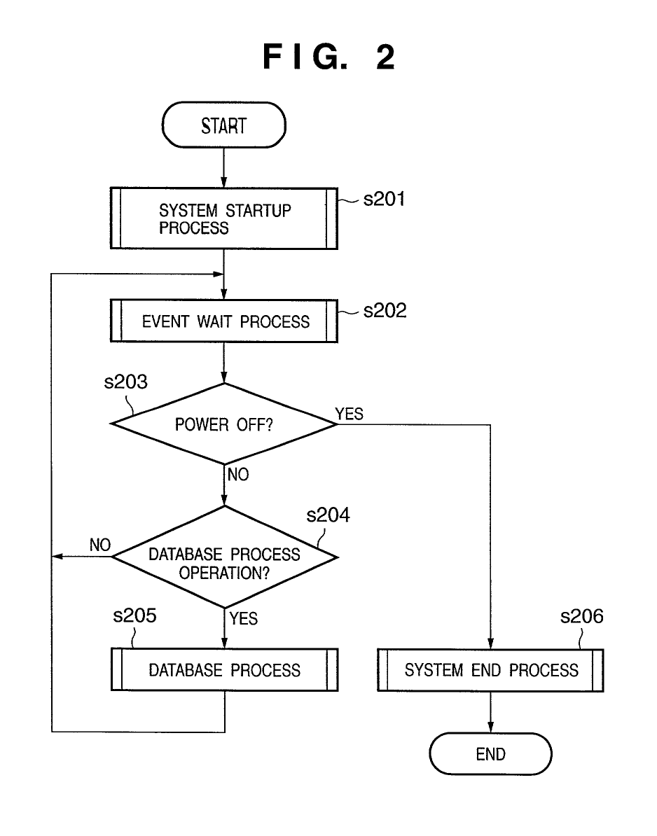

FIG. 2 is a flow chart showing the processing executed by the information processing apparatus of the first embodiment.

As shown in FIG. 2, when the system starts, a system startup process is executed in step s201 to initialize various data. In step s202, an event wait process is executed to wait for events corresponding to user's operations, events corresponding to various state changes, and the like.

It is then checked in step s203 if the generated event is a power OFF instruction. If the event is not a power OFF instruction (NO in step s203), the flow advances to step s204. It is checked in step s204 if the event is a database processing operation instruction. If the event is not a database processing operation instruction (NO in step s204), the flow returns to step s202. On the other hand, if the event is a database processing operation instruction (YES in step s204), the flow advances to step s205 to execute a database process, and the flow then returns to step s202 to repeat the above process.

On the other hand, if it is determined in step s203 that the event is a power OFF instruction (YES in step s203), the flow advances to step s206 to execute a system end process, and the processing ends.

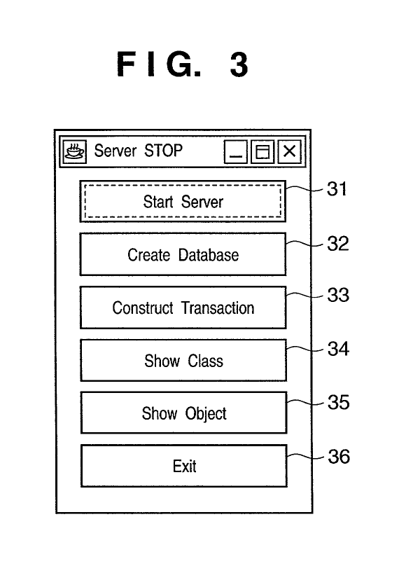

An example of the database processing window displayed in the database process in step s205 will be explained below using FIG. 3.

FIG. 3 shows an example of the database processing window of the first embodiment.

Reference numeral 31 denotes a button for instructing the start of a database server service. Reference numeral 32 denotes a button for instructing creation of a database. Reference numeral 33 denotes a button for instructing generation of a transaction. Reference numeral 34 denotes a button for instructing display of class definition information. Reference numeral 35 denotes a button for instructing display of object storage information. Reference numeral 36 denotes a button for instructing the end of the database process.

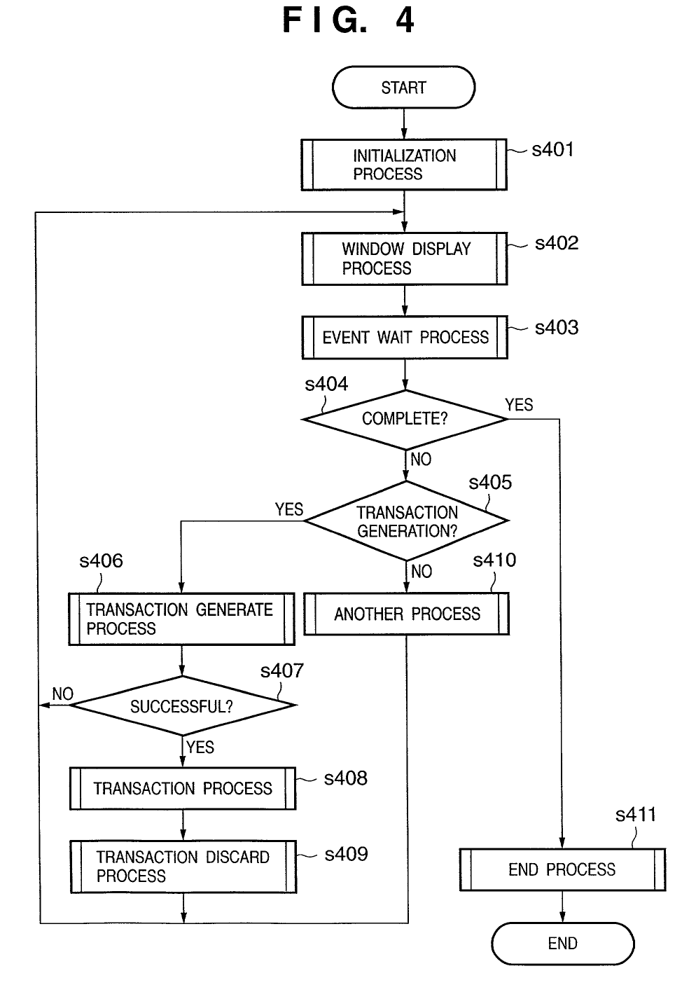

Details of the database process in step s205 will be described below using FIG. 4.

FIG. 4 is a flow chart showing details of the database process in step s205 of the first embodiment.

When the database process is launched, an initialization process is executed in step s401 to initialize various internal data.

In step s402, a window display process is executed to display the database processing window described using FIG. 3. In step s403, an event wait process is executed to wait for an event corresponding to user's operation.

It is checked in step s404 if an event generated in response to user's operation is an end instruction. If the event is an end instruction (YES in step s404), the flow advances to step s411 to execute an end process, thus ending the processing. On the other hand, if the event is not an end instruction (NO in step s404), the flow advances to step s405.

It is checked in step s405 if the event is a transaction generation instruction. If the event is not a transaction generation instruction (NO in 'step s405), the flow advances to step s410 to execute a process corresponding to that event, and the flow returns to step s402 to repeat the aforementioned process. On the other hand, if the event is a transaction generation instruction (YES in step s405), the flow advances to step s406.

In step s406, a transaction generate process is executed to generate a transaction corresponding to a condition designated by the user. It is then checked in step s407 if transaction generation has succeeded. If transaction generation has failed (NO in step s407), the flow returns to step s402 to repeat the above process. On the other hand, if transaction generation has succeeded (YES in step s407), the flow advances to step s408.

In step s408, a transaction process is executed according to a user's instruction. In step s409, a transaction discard process is executed to discard the processed transaction, which becomes unnecessary, and the flow returns to step s402 to repeat the above process.

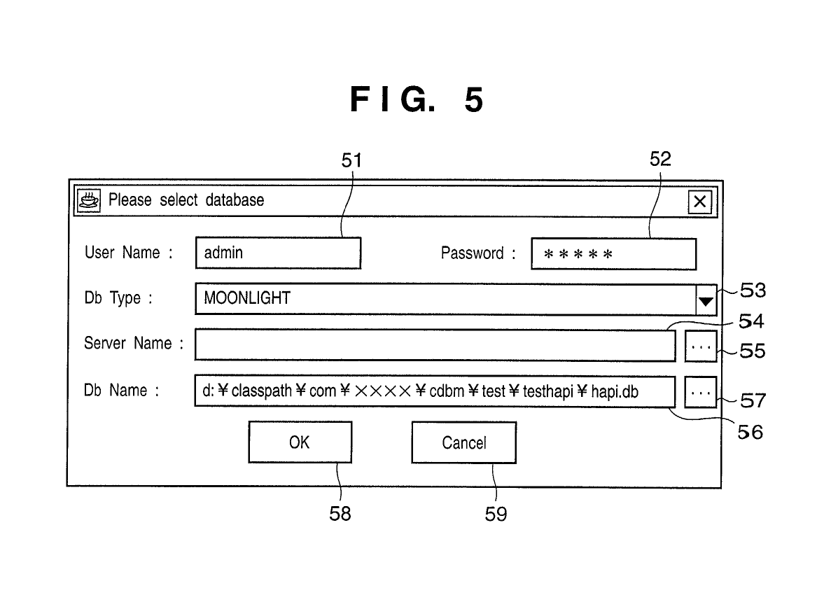

An example of the transaction generation window displayed in the transaction generate process in step s406 will be described below using FIG. 5.

FIG. 5 shows an example of the transaction generation window of the first embodiment.

Reference numeral 51 denotes an input area of a user name. Reference numeral 52 denotes an input area of a password corresponding to the user name. Reference numeral 53 denotes a combo box used to designate the type of database. Reference numeral 54 denotes an input area of a server name that provides a connection service to a database. Reference numeral 55 denotes a button for displaying a server name select dialog used when a server name to be input to the server name input area is unknown. Reference numeral 56 denotes an input area of a database name. Reference numeral 57 denotes a button for displaying a database name select dialog used when a database name to be input to the database name input area is unknown.

Reference numeral 58 denotes a button used when transaction generation using the values designated in the respective areas is instructed. Reference numeral 59 denotes a butt-on for canceling transaction generation.

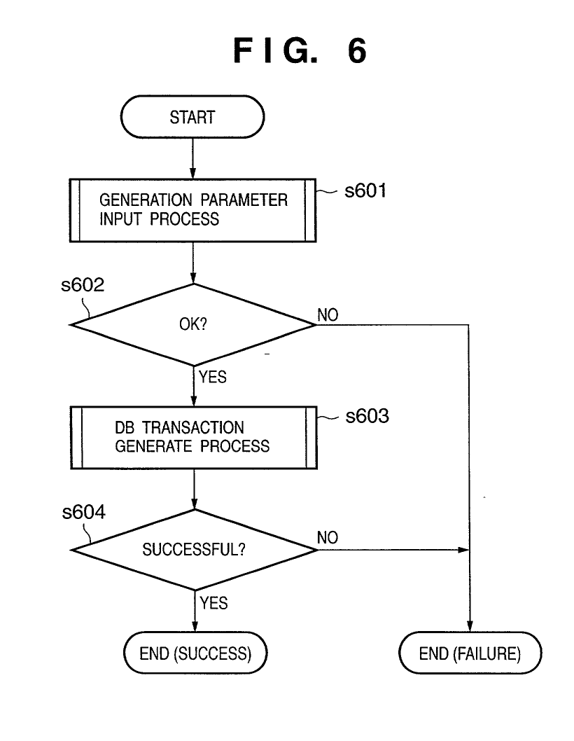

Details of the transaction generate process in step s406 will be described below using FIG. 6.

FIG. 6 is a flow chart showing details of the transaction generate process in step s406 of the first embodiment.

When the transaction generate process is launched, a generation parameter input process is executed in step s601 to display the transaction generate processing window described using FIG. 5, thus allowing the user to designate various parameters.

It is then checked in step s602 if the user has instructed generation of a transaction in the generation parameter input process. If transaction generation has been instructed (YES in step s602), the flow advances to step s603 to execute a DB transaction generate process, thus generating a transaction corresponding to various parameters designated by the user.

It is checked in step s604 if the DB transaction generate process has succeeded. If the DB transaction generate process has succeeded (YES in step s604), the processing ends as “success”.

On the other hand, if it is determined in step s604 that the DB transaction generate process has failed (NO in step s604), or if it is determined in step s602 that transaction generation has not been instructed (NO in step s602), the processing ends as “failure”.

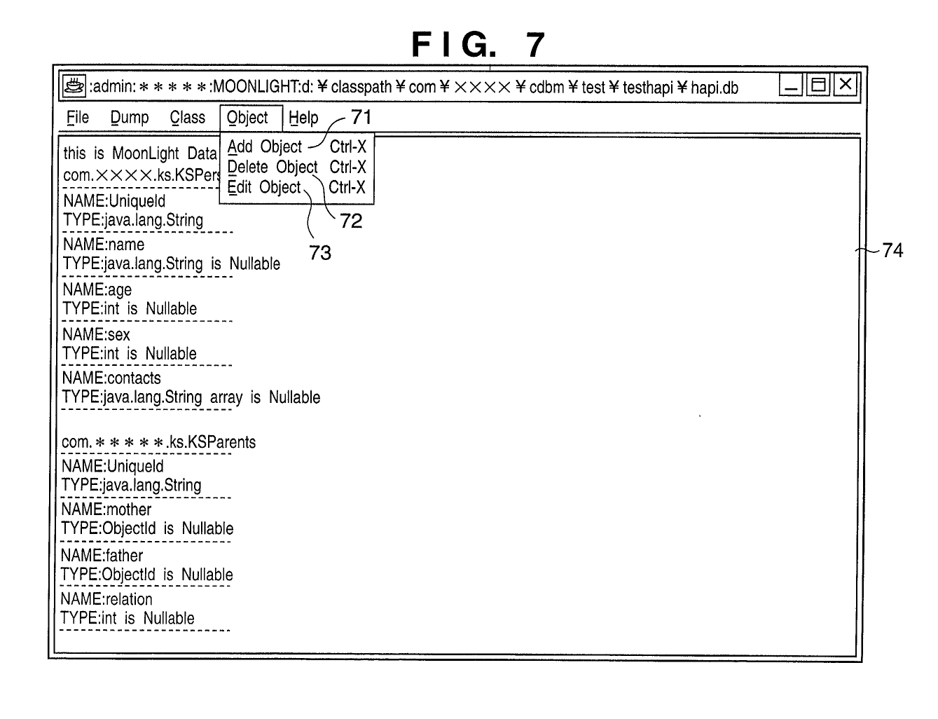

An example of the transaction processing window displayed in the transaction process in step s408 will be described below using FIG. 7.

FIG. 7 shows an example of the transaction processing window of the first embodiment.

Reference numeral 71 denotes a menu item for instructing addition of an object. Reference numeral 72 denotes a menu item for instructing deletion of an object. Reference numeral 73 denotes a menu item for instructing edit of an object.

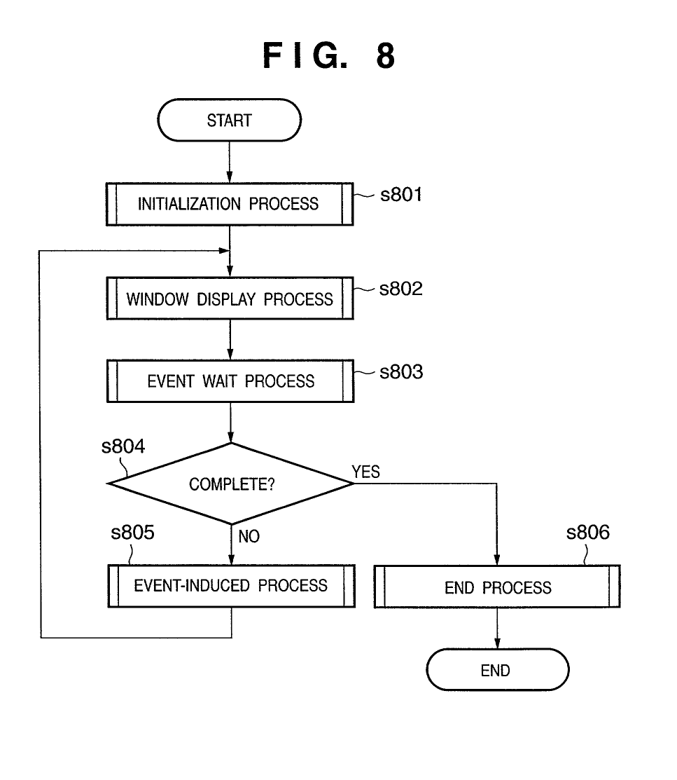

Details of the transaction process in step s408 will be described below using FIG. 8.

FIG. 8 is a flow chart showing details of the transaction process in step s408 of the first embodiment.

When the transaction process is launched, an initialization process is executed in step s801 to initialize various internal data.

In step s802, a window display process is executed to display the transaction processing window described using FIG. 7. In step s803, an event wait process is executed to wait for an event corresponding to user's operation.

It is checked in step s804 if an event generated in response to user's operation is an end instruction. If the event is an end instruction (YES in step s804), the flow advances to step s806 to execute an end process, thus ending the processing. On the other hand, if the event is not an end instruction (NO in step s804), the flow advances to step s805 to execute an event-induced process, i.e., to execute a process corresponding to the event. After that, the flow returns to step s802 to repeat the above process.

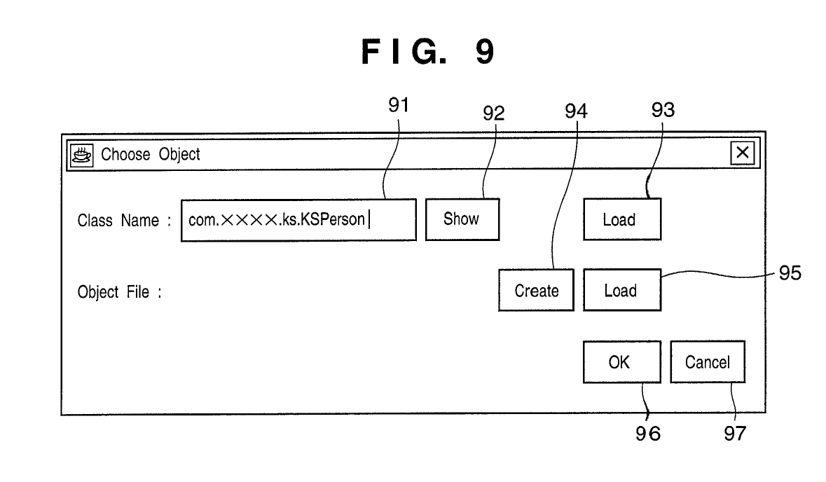

An example of an additional object select window displayed by an object select/add process corresponding to an object add instruction in the event-induced process in step s805 will be explained below using FIG. 9.

FIG. 9 shows an example of the additional object select window of the first embodiment.

Reference numeral 91 denotes an input area of a class flame. Reference numeral 92 denotes a button for displaying a class information dialog that displays information of a class designated by the class name input area. Reference numeral 93 denotes a button for displaying a class file select dialog, which is used to select and load a file that stores class information used when a class name to be input to the class name input area is unknown.

Reference numeral 94 denotes a button for generating an object corresponding to the class designated by the class name input area. Reference numeral 95 denotes a button for displaying an object file select dialog used to select/load an existing object file.

Reference numeral 96 denotes a button for instructing addition of an object generated or loaded by the corresponding button. Reference numeral 97 denotes a button for canceling addition of an object.

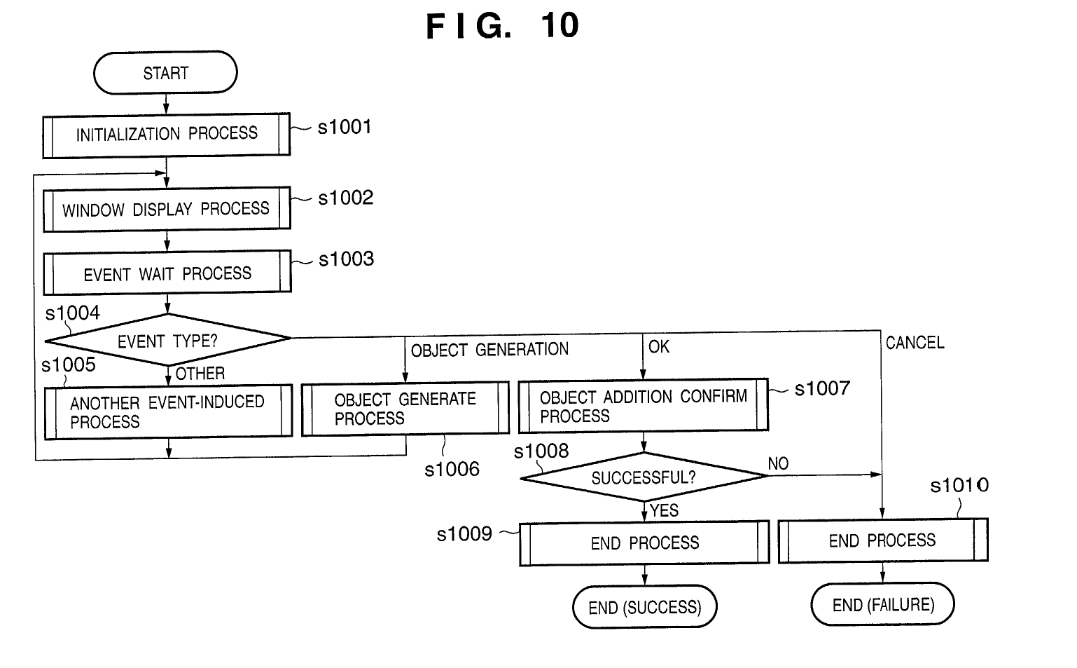

Details of the object select/add process corresponding to the object add instruction in the event-induced process in step s805 will be described below using FIG. 10.

FIG. 10 is a flow chart showing details of the object select/add process corresponding to the object add instruction in the event-induced process in the first embodiment.

When the object select/add process is launched, an initialization process is executed in step s1001 to initialize various internal data.

In step s1002, a window display process is executed to display the additional object select window described using FIG. 9. In step s1003, an event wait process is executed to wait for an event corresponding to user's operation.

In step s1004, the type of event generated in response to user's operation is determined, and the control branches to a corresponding process.

If the event type is an object generation instruction, the flow advances to step s1006 to execute an object generate process. After an object is generated, the flow returns to step s1002 to repeat the above process.

If the event type is an add instruction of the generated or loaded object, the flow advances to step s1007 to execute an object addition confirm process. After the object is added to the database, that change is confirmed. As a result, it is checked in step s1008 if a change in object has succeeded. If a change in object has succeeded (YES in step s1008), the flow advances to step s1009 to execute an end process, and the processing ends as “success”. On the other hand, if a change in object has failed (NO in step s1008), an end process is executed in step s1010, and the processing ends as “failure”.

If the event type is other than those described above, the flow advances to step s1005 to execute a process corresponding to another event by another event-induced process. After that, the flow returns to step s1002 to repeat the above process.

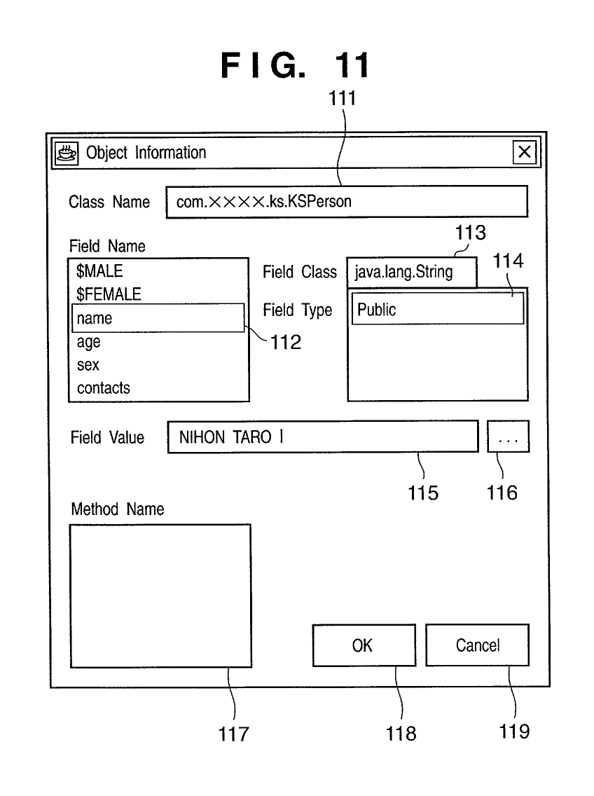

An example of an object edit window upon creation of a new object displayed in the object generate process in step s1006 will be described below using FIG. 11.

FIG. 11 shows an example of an object edit window upon creating a new object in the first embodiment.

Reference numeral 111 denotes an area indicating the class name of an object to be edited. Reference numeral 112 denotes an area indicating a list of field names that the object class has. Reference numeral 113 denotes an area indicating the class name of a field selected from the field name list. Reference numeral 114 denotes an area indicating an attribute of that field.

Reference numeral 115 denotes an input area of a value to be stored in that field. Reference numeral 116 denotes a button for displaying an object designation dialog used to designate an object which is hard to directly input to the input area. Reference numeral 117 denotes an area indicating a list of method names that the object class has.

Reference numeral 118 denotes a button used when the user instructs confirmation of the edit contents of the edited object. Reference numeral 119 denotes a button for canceling the edit contents of the object.

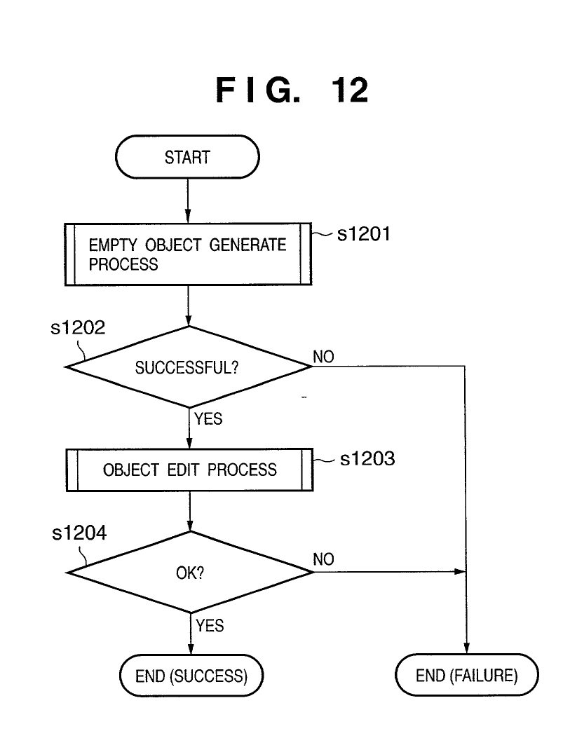

Details of the object generate process in step s1006 will be described below using FIG. 12.

FIG. 12 is a flow chart showing details of the object generate process in step s1006 of the first embodiment.

When the object generate process is launched, an empty object generate process is executed in step s1201 to generate a default instance corresponding to the designated class.

It is then checked in step s1202 if generation of a default instance has succeeded as a result of the empty object generate process. If generation of a default instance has succeeded (YES in step s1202), the flow advances to step s1203 to execute an object edit process, and the object edit window described using FIG. 11 is displayed to accept user's operation.

It is checked in step s1204 if confirmation of the edit contents of the object has been instructed as a result of the object edit process. If confirmation of the edit contents of the object has been instructed (YES in step s1204), the processing ends as “success”.

On the other hand, if it is determined in step s1204 that confirmation of the edit contents of the object has not been instructed (NO in step s1204) or if it is determined in step s1202 that generation of a default instance has failed (NO in step s1202), the processing ends as “failure”.

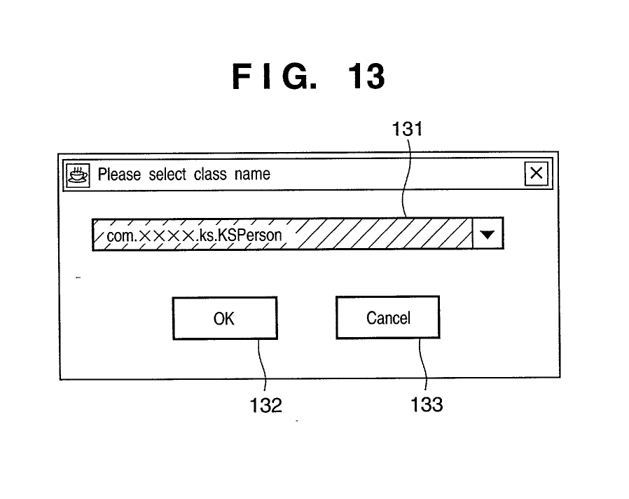

An example of a class select window displayed by the object select/edit process corresponding to the object edit instruction in the event-induced process in step s805 will, be described below using FIG. 13.

FIG. 13 shows an example of the class select window of the first embodiment.

Reference numeral 131 denotes a class name select list. Reference numeral 132 denotes a button for instructing edit of an object corresponding to the class selected from the list. Reference numeral 133 denotes a button for canceling edit of the object.

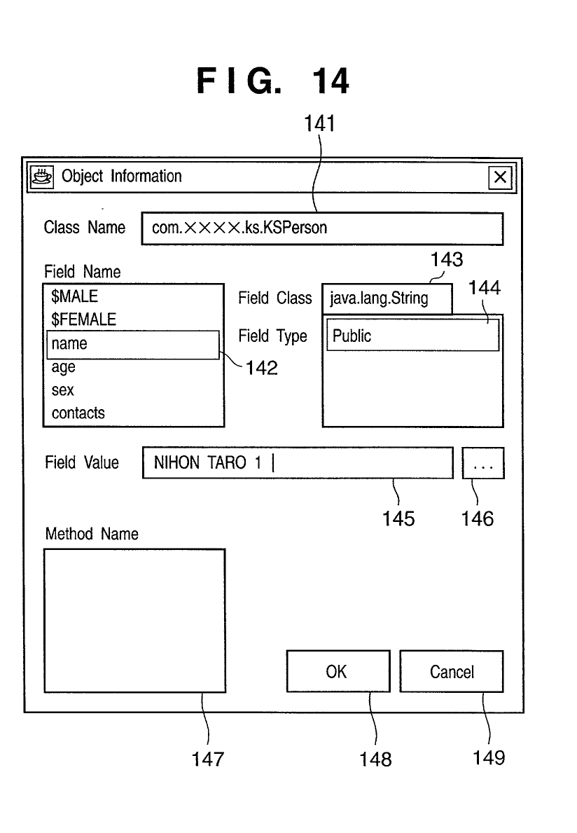

An example of an object edit window upon editing an existing object, which is displayed by the object select/edit process corresponding to the object edit instruction in the event-induced process in step s805 will be described below using FIG. 14.

FIG. 14 shows an example of the object edit window upon editing an existing object in the first embodiment.

FIG. 14 shows a state wherein the value of a field name “name” 142 has been changed from “Nippon Taro” in the new creation state shown in FIG. 11 to “Nippon Taro1”, as indicated by 145.

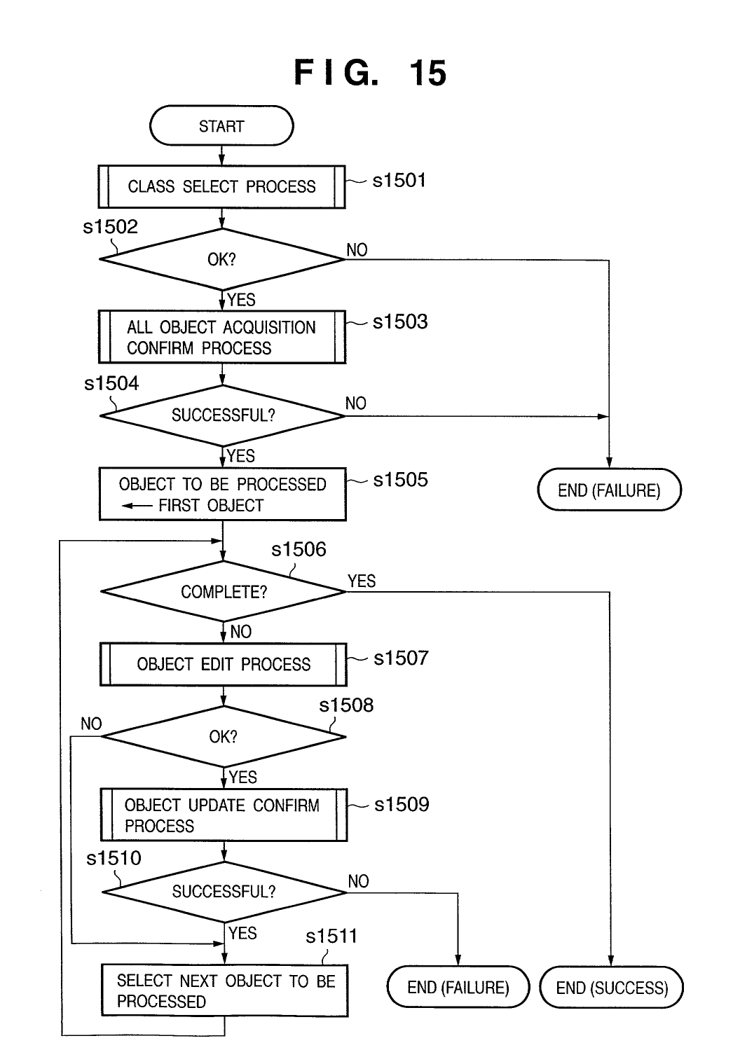

Details of the object select/edit process corresponding to the object edit instruction in the event-induced process in step s805 will be described below using FIG. 15.

FIG. 15 is a flow chart showing details of the object select/edit process of the first embodiment.

When the object select/edit process is launched, a class select process is executed in step s1501 to display the class select window described using FIG. 13, thus accepting user's choice.

It is checked in step s1502 if edit of objects corresponding to the class has been instructed as a result of the class select process. If edit of objects has not been instructed (NO in step s1502), the processing ends as “failure”. On the other hand, if edit of objects has been instructed (YES in step s1502), the flow advances to step s1503.

In step s1503, an all object acquisition confirm process is executed to acquire all objects corresponding to the selected class.

It is then checked in step s1504 if acquisition of objects has succeeded as a result of the all object acquisition confirm process. If acquisition of objects has failed (NO in step s1504), the processing ends as “failure”. On the other hand, if acquisition of objects has succeeded (YES in step s1504), the flow advances to step s1505.

In step s1505, an object to be processed is reset to the first one of all the acquired objects, and processes for individual objects are repeated in the subsequent steps.

It is checked in step s1506 if the processes for all objects to be processed are complete. If the processes for all objects to be processed are complete (YES in step s1506), the processing ends as “success”. On the other hand, if the processes for all objects to be processed are not complete (NO in step s1506), the flow advances to step s1507.

In step s1507, an object edit process is executed to display the object edit window described using FIG. 14, thus accepting user's operation.

It is checked in step s1508 if confirmation of the edit contents of the object has been instructed as a result of the object edit process. If confirmation of the edit contents of the object has not been instructed (NO in step s1508), the flow jumps to step s1511. On the other hand, if confirmation of the edit contents of the object has been instructed (YES in step s1508), the flow advances to step s1509.

In step s1509, an object update confirm process is executed to update data in the database by the confirmed edit contents, thus confirming the result.

It is then checked in step s1510 if update of data has succeeded as a result of the object update confirm process. If update of data has failed (NO in step s1510), the processing ends as “failure”. On the other hand, if update of data has succeeded (YES in step s1510), the flow advances to step s1511.

In step s1511, the next object is selected as the object to be processed, and the flow returns to step s1506 to repeat the process.

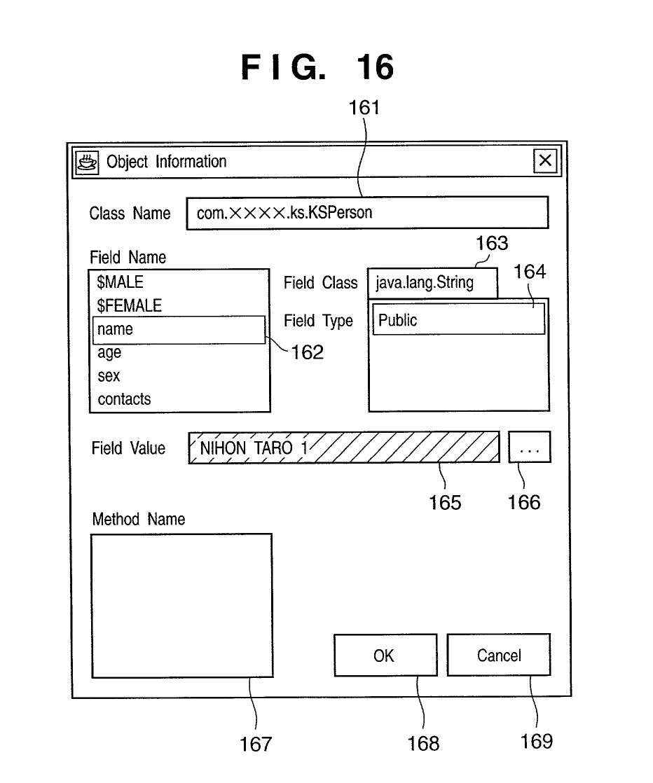

An example of an object reference window upon referring to an existing object, which is displayed by an object select/delete process corresponding to an object delete instruction in the event-induced process in step s805 will be described below using FIG. 16.

FIG. 16 shows an example of the object reference window upon referring to an existing object in the first embodiment.

Unlike in the new creation state in FIG. 11 or the edit state shown in FIG. 14, an input area 165 of the value stored in a field 162 is inactive, i.e., is displayed in gray, as shown in FIG. 16.

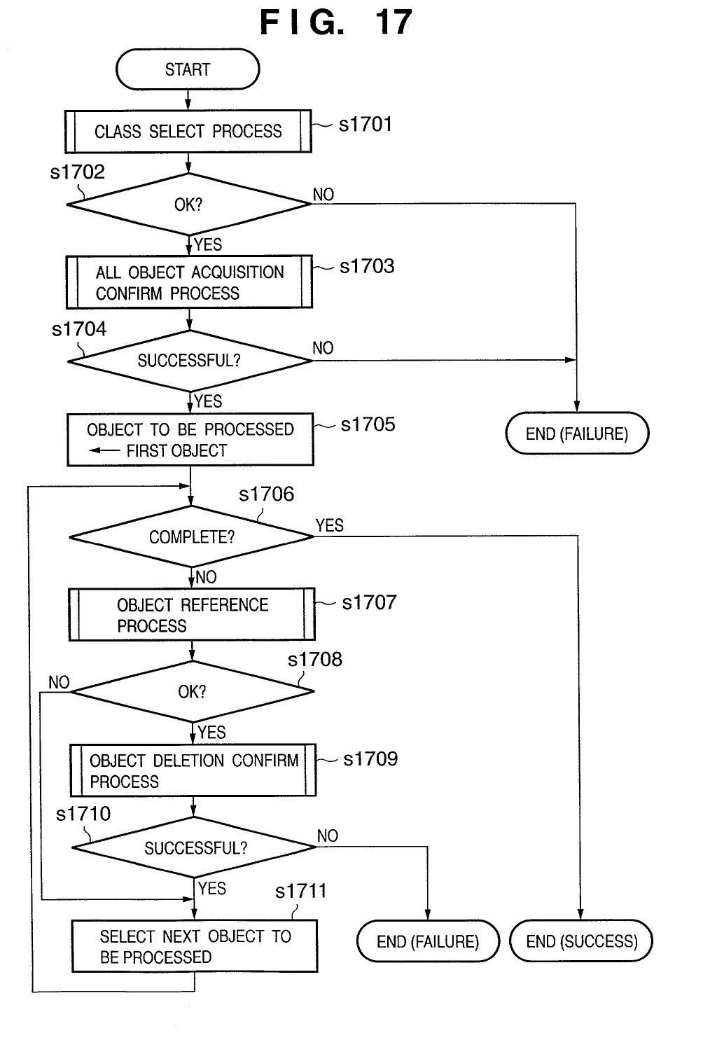

Details of the object select/delete process corresponding to the object delete instruction in the event-induced process in step s805 will be described below using FIG. 17.

FIG. 17 is a flow chart showing details of the object select/delete process of the first embodiment.

When the object select/delete process is launched, a class select process is executed in step s1701 to display the class select window described using FIG. 13, thus accepting user's choice.

It is checked in step s1702 if deletion of objects corresponding to the class has been instructed as a result of the class select process. If deletion of objects has not been instructed (NO in step s1702), the processing ends as “failure”. On the other hand, if deletion of objects has been instructed (YES in step s1702), the flow advances to step s1703.

In step s1703, an all object acquisition confirm process is executed to acquire all objects corresponding to the selected class.

It is then checked in step s1704 if acquisition of objects has succeeded as a result of the all object acquisition confirm process. If acquisition of objects has failed (NO in step s1704), the processing ends as “failure”. On the other hand, if acquisition of objects has succeeded (YES in step s1704), the flow advances to step s1705.

In step s1705, an object to be processed is reset to the first one of all the acquired objects, and processes for individual objects are repeated in the subsequent steps.

It is checked in step s1706 if the processes for all objects to be processed are complete. If the processes for all objects to be processed are complete (YES in step s1706), the processing ends as “success”. On the other hand, if the processes for all objects to be processed are not complete (NO in step s1706), the flow advances to step s1707.

In step s1707, an object edit process is executed to display the object reference window described using FIG. 16, thus accepting user's operation.

It is checked in step s1708 if deletion of the object has been instructed as a result of the object reference process. If deletion of the object has not been instructed (NO in step s1708), the flow jumps to step s1711. On the other hand, if deletion of the object has been instructed (YES in step s1708), the flow advances to step s1709.

In step s1709, an object deletion confirm process is executed to delete data in the database, thus confirming the result.

It is then checked in step s1710 if deletion of data has succeeded as a result of the object deletion confirm process. If deletion of data has failed (NO in step s1710), the processing ends as “failure”. On the other hand, if deletion of data has succeeded (YES in step s1710), the flow advances to step s1711.

In step s1711, the next object is selected as the object to be processed, and the flow returns to step s1706 to repeat the process.

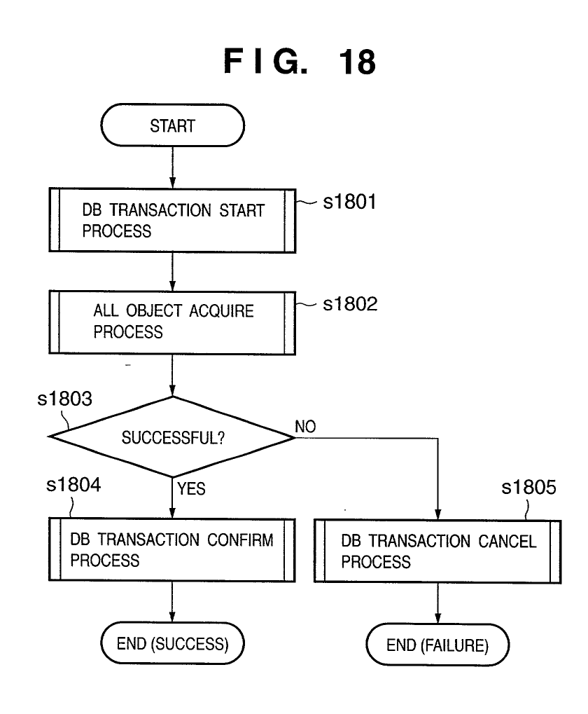

Details of the all object acquisition confirm process in steps s1503 and s1703 will be described using FIG. 18.

FIG. 18 is a flow chart showing details of the all object acquisition confirm process in steps s1503 and s1703 of the first embodiment.

When the all object acquisition confirm process is launched, a DB transaction start process is executed in step s1801 to declare the start of transaction. In step s1802, an all object acquire process is executed to acquire all objects corresponding to the designated class.

It is then checked in step s1803 if acquisition of all objects has succeeded as a result of the all object acquire process. If acquisition of all objects has succeeded (YES in step s1803), the flow advances to step s1804. On the other hand, acquisition of all objects has failed (NO in step s1803), the flow advances to step s1805.

In step s1804, a DB transaction confirm process is executed to confirm processes for the database executed so far, and the processing ends as “success”.

In step s1805, a DB transaction cancel process is executed to cancel processes for the database executed so far, and the processing ends as “failure”.

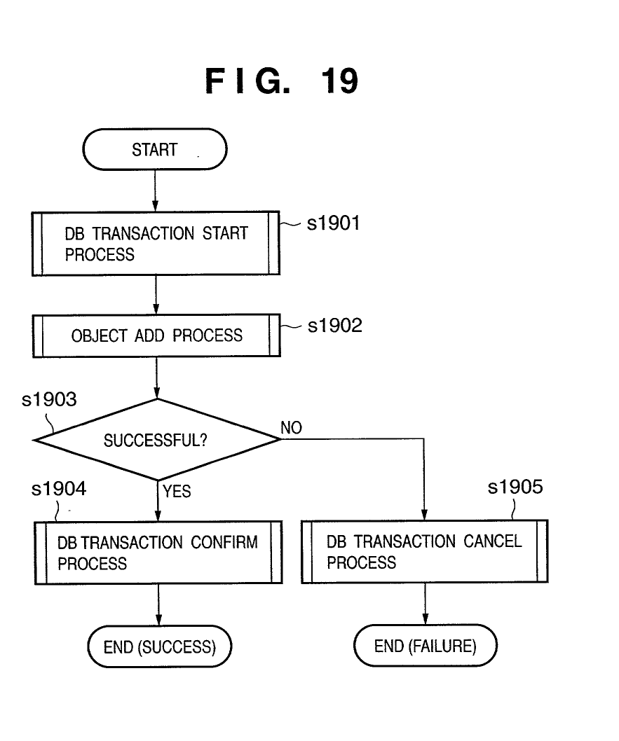

Details of the object addition confirm process in step s1007 will be described below using FIG. 19.

FIG. 19 is a flow chart showing details of the object addition confirm process in step s1007 of the first embodiment.

When the object addition confirm process is launched, a DB transaction start process is executed in step s1901 to declare the start of transaction. In step s1902, an object add process is executed to add the designated object to the database.

It is then checked in step s1903 if addition of the object has succeeded as a result of the object add process. If addition of the object has succeeded (YES in step s1903), the flow advances to step s1904. On the other hand, if addition of the object has failed (NO in step s1903), the flow advances to step s1905.

In step s1904, a DB transaction confirm process is executed to confirm processes for the database executed so far, and the processing ends as “success”.

In step s1905, a DB transaction cancel process is executed to cancel processes for the database executed so far, and the processing ends as “failure”.

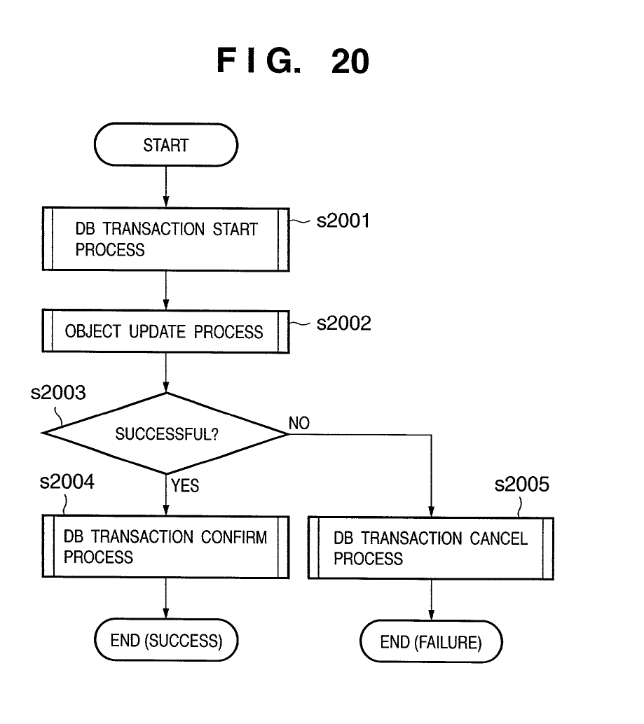

Details of the object update confirm process in step s1509 will be described below using FIG. 20.

FIG. 20 is a flow chart showing details of the object update confirm process in step s1509 of the first embodiment.

When the object update confirm process is launched, a DB transaction start process is executed in step s2001 to declare the start of transaction. In step s2002, an object update process is executed to update the database with the designated object.

It is then checked in step s2003 if update of the object has succeeded as a result of the object update process. If update of the object has succeeded (YES in step s2003), the flow advances to step s2004. On the other hand, if update of the object has failed (NO in step s2003), the flow advances to step s2005.

In step s2004, a DB transaction confirm process is executed to confirm processes for the database executed so far, and the processing ends as “success”.

In step s2005, a DB transaction cancel process is executed to cancel processes for the database executed so far, and the processing ends as “failure”.

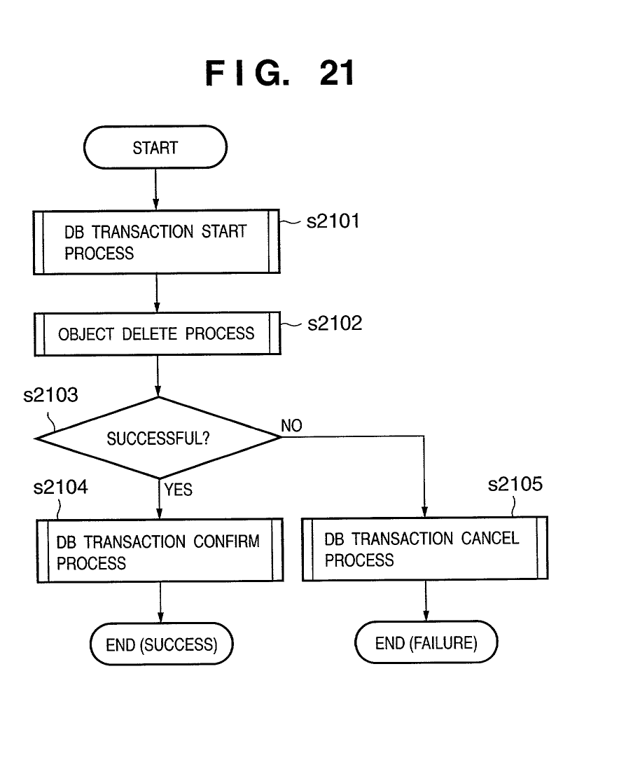

Details of the object deletion confirm process in step s1709 will be described below using FIG. 21.

FIG. 21 is a flow chart showing details of the object deletion confirm process in step s1709 of the first embodiment.

If the object deletion confirm process is launched, a DB transaction start process is executed in step s2101 to declare the start of transaction. In step s2102, an object delete process is executed to delete the designated object from the database.

It is then checked in step s2103 if deletion of the object has succeeded as a result of the object delete process. If deletion of the object has succeeded (YES in step s2103), the flow advances to step s2104. On the other hand, if deletion of the object has failed (NO in step s2103), the flow advances to step s2105.

In step s2104, a DB transaction confirm process is executed to confirm processes for the database executed so far, and the processing ends as “success”.

In step s2105, a DB transaction cancel process is executed to cancel processes for the database executed so far, and the processing ends as “failure”.

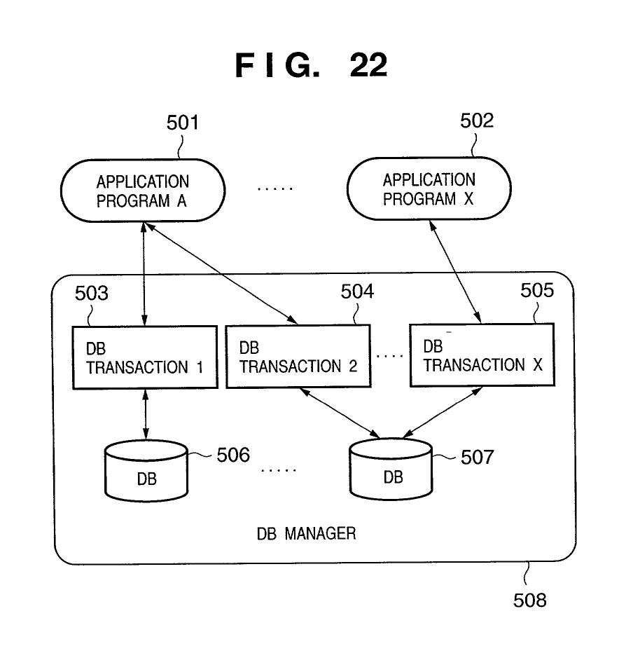

FIG. 22 is a diagram showing the functional arrangement of the information processing apparatus of the first embodiment.

A DB manager 508 generates/discards DB transactions 1 (503), 2 (504), . . . , X(505) that process a series of transactions between pertinent databases (DBs) 506 and 507 in response to requests from one or more application programs A (501), . . . , X (502).

In FIG. 22, two DB transactions 1 (503) and 2 (504) are generated in response to two requests from application program A (501), and are associated with the databases 506 and 507. DB transaction X (505), which is generated in response to a request from application program X (502), is associated with the database 507 which is the same as DB transaction 2 (504).

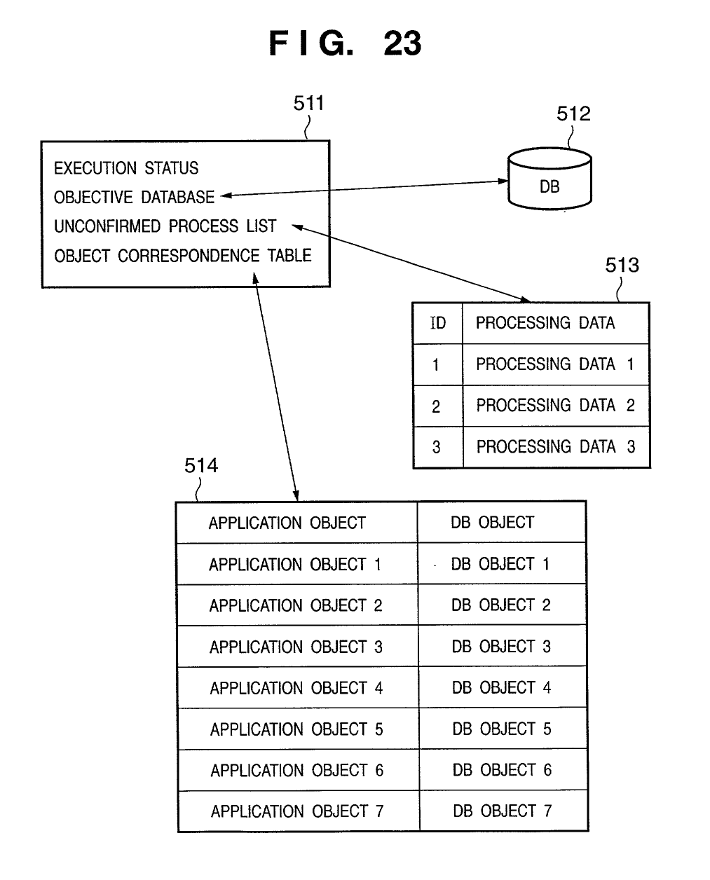

Internal data of a DB transaction will be explained below using FIG. 23.

FIG. 23 shows internal data of a DB transaction of the first embodiment.

The internal data of the DB transactions include execution status indicating if execution of a transaction is in progress, database information 512 of a transaction target, a list 513 of unconfirmed processes done during execution of the transaction, and an object correspondence table 514 that stores relationships (inter-object relation information) between application objects to be processed and DB objects after generation of the transaction, as indicated by 511.

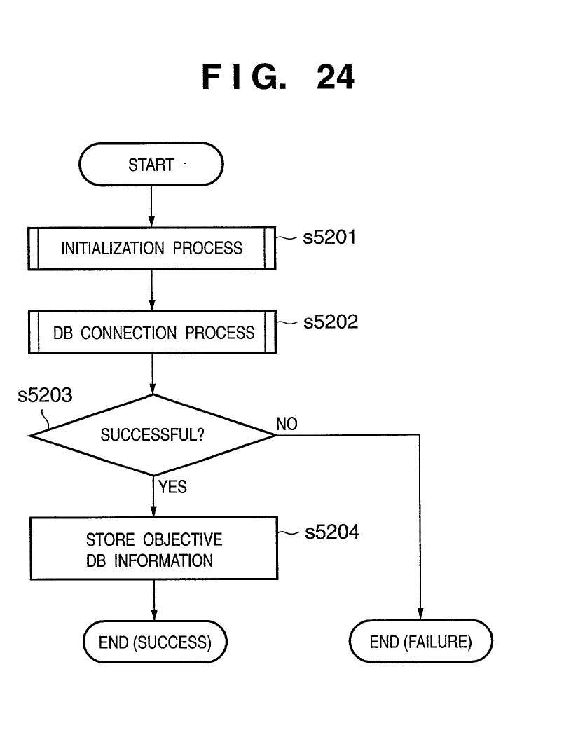

Details of the DB transaction generate process in step s603 will be described below using FIG. 24.

FIG. 24 is a flow chart showing details of the DB transaction generate process in step s603 of the first embodiment.

When the DB transaction generate process is launched, an initialization process is executed in step s5201 to initialize internal data of the DB transaction described using FIG. 23.

In step s5202, a DB connection process is executed to establish connection to a database under the designated condition.

It is checked in step s5203 if connection to a database has succeeded as a result of the DB connection process. If connection has failed (NO in step s5203), the processing ends as “failure”. If connection has succeeded (YES in step s5203), the flow advances to step s5204.

In step s5204, information that pertains to connection is stored in the internal data of the DB transaction, and the processing ends as “success”.

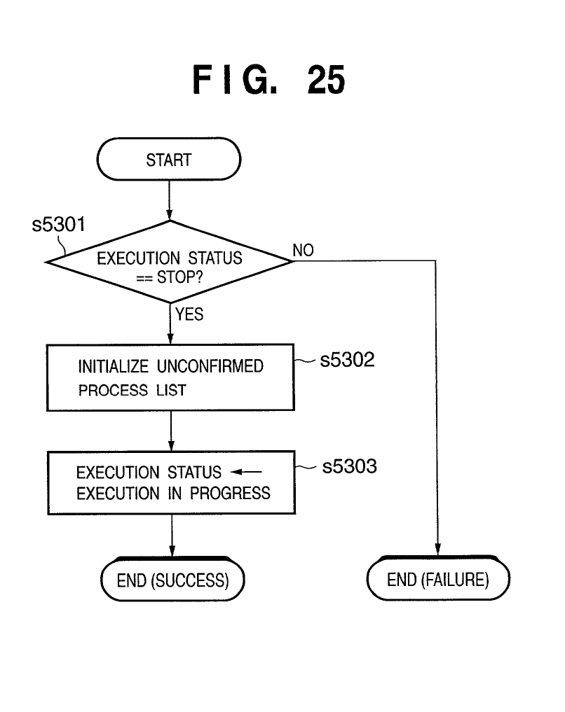

Details of the DB transaction start process in steps s1801, s1901, s2001, and s2101 in the all object acquisition confirm process in FIG. 18, the object addition confirm process in FIG. 19, the object update confirm process in FIG. 20, and the object deletion confirm process in FIG. 21 will be described below using FIG. 25.

FIG. 25 is a flow chart showing details of the DB transaction start process in steps s1801, s1901, s2001, and s2101 of the first embodiment.

When the DB transaction start process is launched, it is checked in step s5301 with reference to the execution status of the internal data of the DB transaction if the execution status is “stop”. If the execution status is not “stop” (NO in step s5301), the processing ends as “failure”. On the other hand, if the execution status is “stop” (YES in step s5301), the flow advances to step s5302.

In step s5302, the unconfirmed process list is initialized. In step s5303, the execution status is changed to “execution in progress”, and the processing ends as “success”.

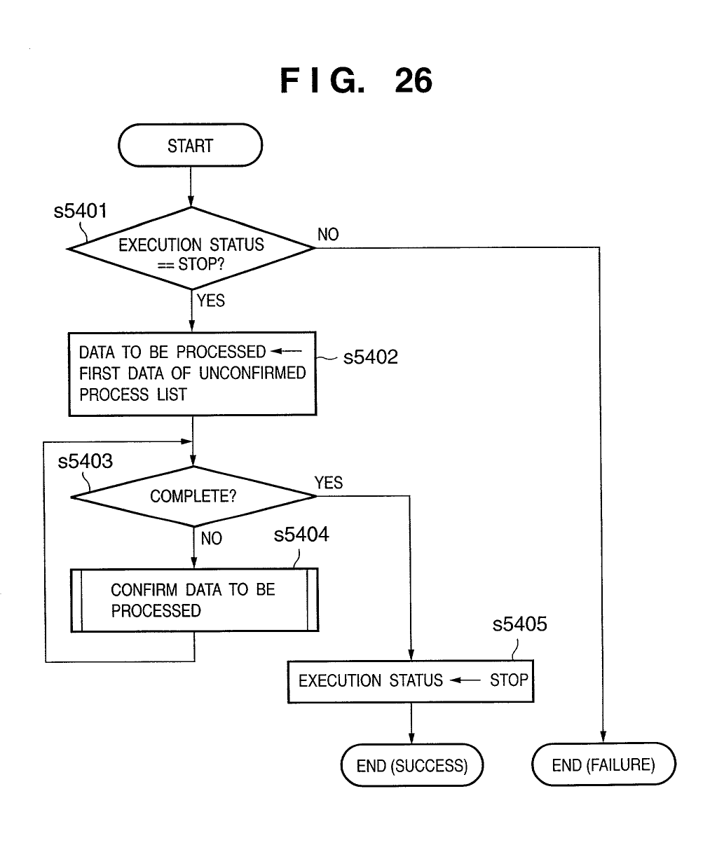

Details of the DB transaction confirm process in steps s1804, s1904, s2004, and s2104 in the all object acquisition confirm process in FIG. 18, the object addition confirm process in FIG. 19, the object update confirm process in FIG. 20, and the object deletion confirm process in FIG. 21 will be described below using FIG. 26.

FIG. 26 is a flow chart showing details of the DB transaction confirm process in steps s1804, s1904, s2004, and s2104 of the first embodiment.

When the DB transaction confirm process is launched, it is checked in step s5401 with reference to the execution status of the internal data of the DB transaction if the execution status is “execution in progress”. If the execution status is not “execution in progress” (NO in step s5401), the processing ends as “failure”. On the other hand, if the execution status is “execution in progress” (YES in step s5401), the flow advances to step s5402.

In step s5402, data to be processed is set at the head of the unconfirmed process list, and processes are repeated for all data to be processed in the subsequent steps.

It is checked in step s5403 if the processes for all data to be processed are complete. If the processes for all data to be processed are not complete (NO in step s5403), the flow advances to step s5404 to execute a data confirm process to confirm processing contents as the data to be processed in the database, and the flow returns to step s5403. On the other hand, if the processes for all data to be processed are complete (YES in step s5403), the flow advances to step s5405 to change the execution status to “stop”, and the processing ends as “success”.

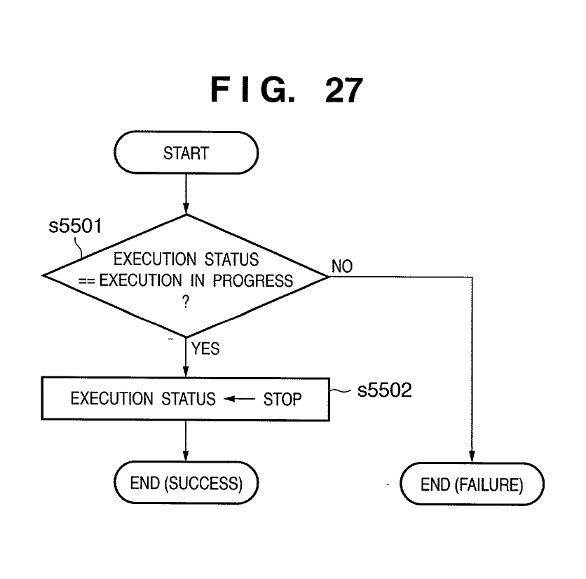

Details of the DB transaction cancel process in steps s1805, s1905, s2005, and s2105 in the all object acquisition confirm process in FIG. 18, the object addition confirm process in FIG. 19, the object update confirm process in FIG. 20, and the object deletion confirm process in FIG. 21 will be described below using FIG. 27.

FIG. 27 is a flow chart showing details of the DB transaction cancel process in steps s1805, s1905, s2005, and s2105 of the first embodiment.

When the DB transaction cancel process is launched, it is checked in step s5501 with reference to the execution status of the internal data of the DB transaction if the execution status is “execution in progress”. If the execution status is not “execution in progress” (NO in step s5501), the processing ends as “failure”. On the other hand, if the execution status is “execution in progress” (YES in step s5501), the flow advances to step s5502.

In step s5502, the execution status is changed to “stop”, and the processing ends as “success”.

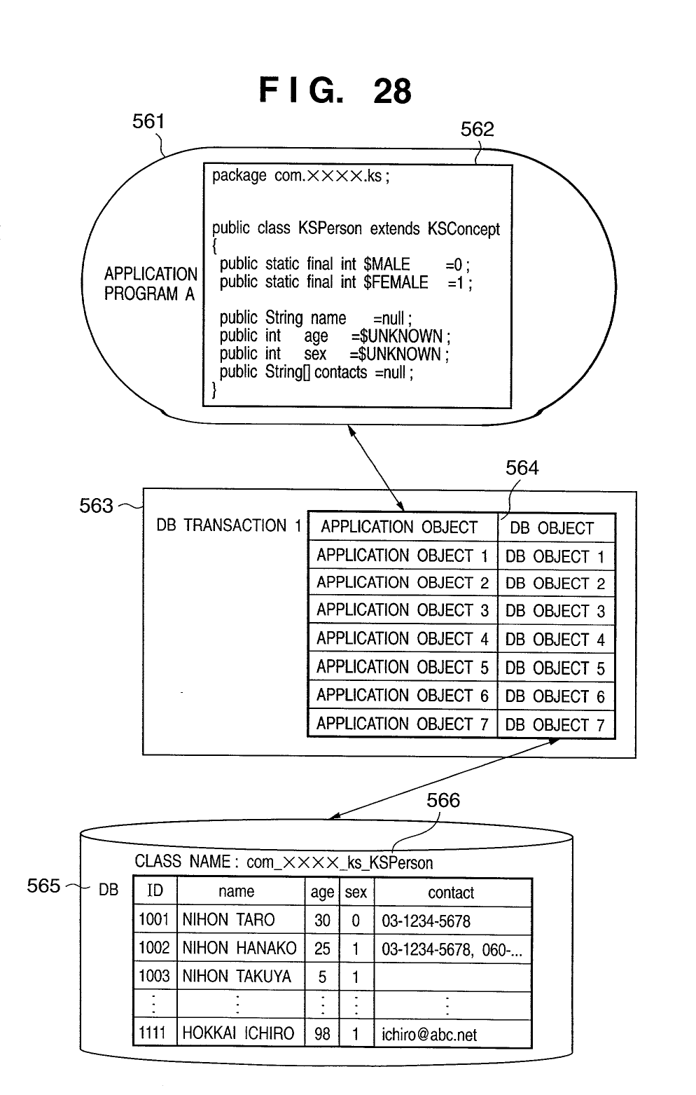

The relations among objects used in the information processing apparatus of the first embodiment will be described below using FIG. 28.

FIG. 28 shows the relations among objects used in the information processing apparatus of the first embodiment.

In FIG. 28, a database 565 is used to use an application object 562 generated or acquired by application program A (561) as permanent data.

In this case, application program A (561) accesses the database 565 not directly but via a DB transaction 563 generated after a connection condition to the database 565 is designated.

More specifically, the application object 562 generated by application program A (561) is internally converted into a DB object 566 by a service provided by the DB transaction 563, and the DB object 566 is stored in the database 565. At the same time, an object correspondence table 564 that stores the relation between the application object 562 and DB object 566 is updated.

Conversely, after the DB object 566 stored in the database 565 is internally converted into the application object 562 by a service provided by the DB transaction 563, the application object 562 can be processed. At the same time, the object correspondence table 564 that stores the relation between the application object 562 and DB object 566 is updated.

With the above process, application program A (561) can acquire, add, update, and delete data stored in the database 565 as the application object 562 irrespective of the object structure in the database 565.

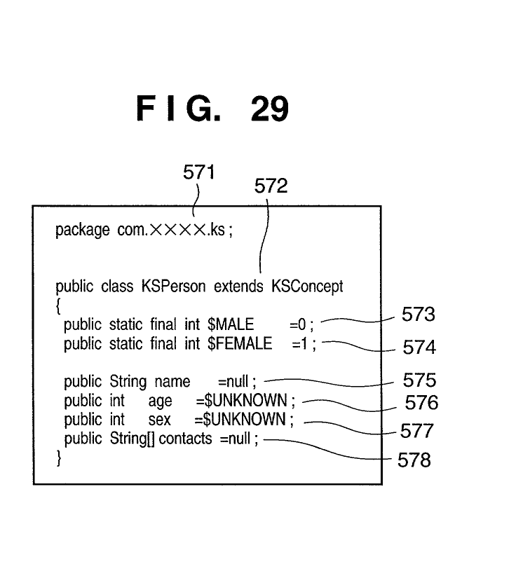

Programming codes of an application object used in the information processing apparatus of the first embodiment will be described below using FIG. 29.

FIG. 29 shows programming codes of an application object used in the information processing apparatus of the first embodiment.

Referring to FIG. 29, reference numeral 571 denotes a package name indicating a group of classes generated from programming codes. Reference numeral 572 denotes a class name in that package. In practice, the class name of a class generated from the programming codes is “com.xxxx.ks.KSPerson” as a combination with the package name.

Reference numerals 573 to 578 denote definitions and default values of fields of the class. For example, the definitions shown in FIG. 29 include six fields $MALE, $FEMALE, name, age, sex, and contacts which can be referred to from outside the class. Of these fields, $MALE and $FEMALE are defined to be non-rewritable.

Note that an application object of the information processing apparatus of the first embodiment is obtained by converting a class generated from the programming codes into an instance, and application object definition information that defines the application object can be acquired by exploiting a service of the application object.

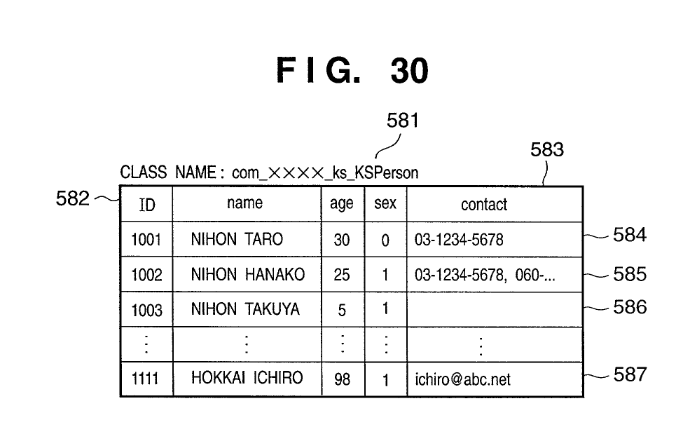

A list of database objects used in the information processing apparatus of the first embodiment will be described below using FIG. 30.

FIG. 30 shows a list of database objects of the first embodiment.

Note that each line of this list is database object definition information that defines a database object.

Referring to FIG. 30, reference numeral 581 denotes a class name in the database. Reference numeral 582 denotes an identification ID unique to each database object. Reference numeral 583 denotes a field name corresponding to each field of the application object. In FIG. 30, each object has four fields “name”, “age”, “sex”, and “contacts”.

Reference numerals 584 to 587 denote actual values of database objects.

Note that the class name in the database does not always match that of the application object, as shown in FIG. 30.

Also, not all field values of the application object are stored in the database object, as shown in FIG. 30. For example, even when the values of write-inhibited fields of those of the application object are stored in the database object, they cannot be written in the application object or are automatically initialized upon creation of a default instance of the application object. Hence, such field values need not be stored in the database object.

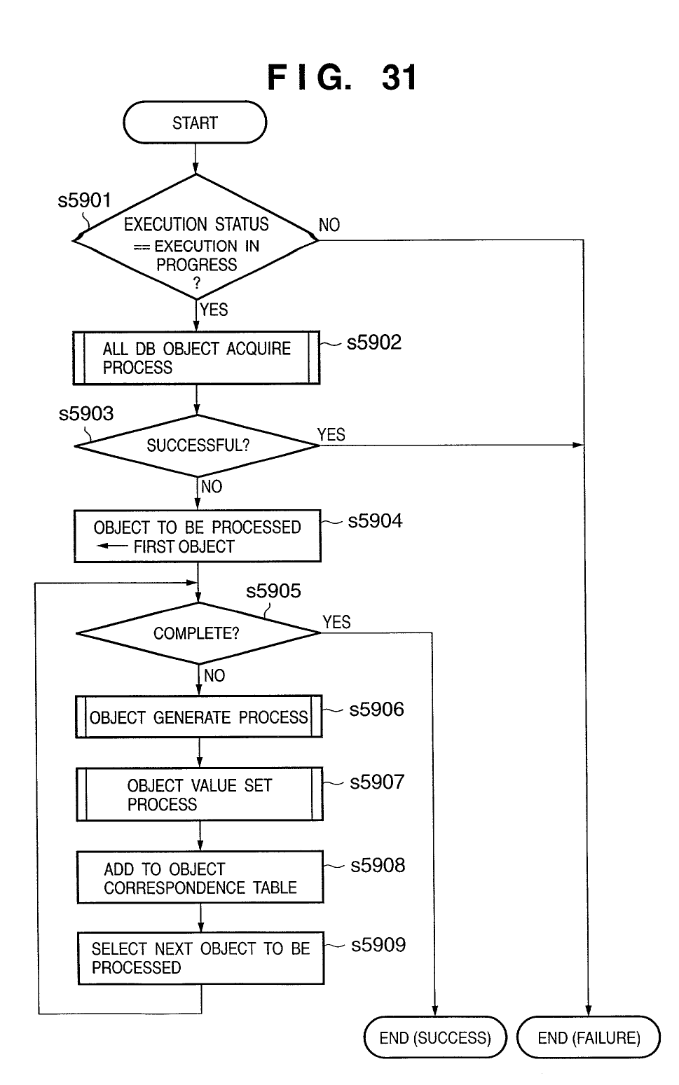

Details of the all object acquire process in step s1802 will be described below using FIG. 31.

FIG. 31 is a flow chart showing details of the all object acquire process of the first embodiment.

When the all object acquire process is launched, it is checked in step s5901 with reference to the execution status of the internal data of the DB transaction if the execution status is “execution in progress”. If the execution status is not “execution in progress” (NO in step s5901), the processing ends as “failure”. On the other hand, if the execution status is “execution in progress” (YES in step s5901), the flow advances to step s5902.

In step s5902, an all DB object acquire process is executed to acquire all objects in the database corresponding to the designated class.

It is checked in step s5903 if acquisition of all objects has succeeded as a result of the DB object acquire process. If acquisition of all objects has failed (NO in step s5903), the processing ends as “failure”. On the other hand, if acquisition of all objects has succeeded (YES in step s5903), the flow advances to step s5904.

In step s5904, the first one of the acquired objects of the database is set to be an object to be processed, and processes are repeated for all objects to be processed in the subsequent steps.

It is checked in step s5905 if the processes for all the objects to be processed are complete. If the processes for all the objects to be processed are complete (YES in step s5905), the processing ends as “success”. On the other hand, if the processes for all the objects to be processed are not complete (NO in step s5905), the flow advances to step s5906.

In step s5906, an object generate process is executed to generate a default instance of the designated class. In step s5907, an object value set process is executed to set values in the respective fields of the generated application object with reference to values of the database object to be processed. Furthermore, in step s5908 a combination of the generated application object and acquired database object is added to the object correspondence table. After that, the next object is selected as the object to be processed in step s5909, and the flow returns to step s5905 to repeat the process.

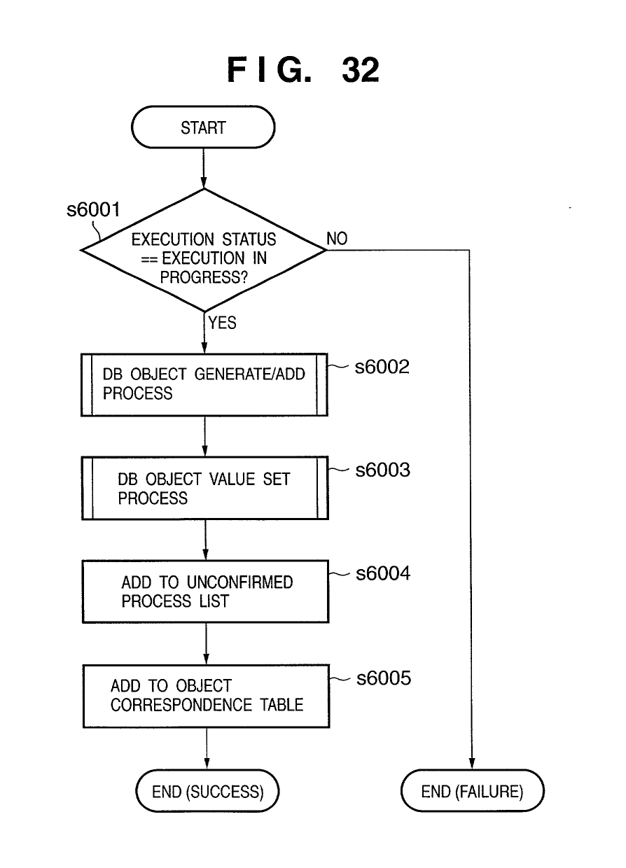

Details of the object add process in step s1902 will be described below using FIG. 32.

FIG. 32 is a flow chart showing details of the object add process in step s1902 of the first embodiment.

When the object add process is launched, it is checked in step s6001 with reference to the execution status of the internal data of the DB transaction if the execution status is “execution in progress”. If the execution status is not “execution in progress” (NO in step s6001), the processing ends as “failure”. On the other hand, if the execution status is “execution in progress” (YES in step s6001), the flow advances to step s6002.

In step s6002, a DB object generate/add process is executed to generate and add a database object of a class in the database corresponding to the class of a given application object.

In step s6003, a DB object value set process is executed to set values in the respective fields of the generated and added database object with reference to the values of the given application object.

After that, information corresponding to the above process is added to the unconfirmed process list in step s6004. In step s6005, a combination of the given application object and the generated and added database object is added to the object correspondence table, and the processing ends as “success”.

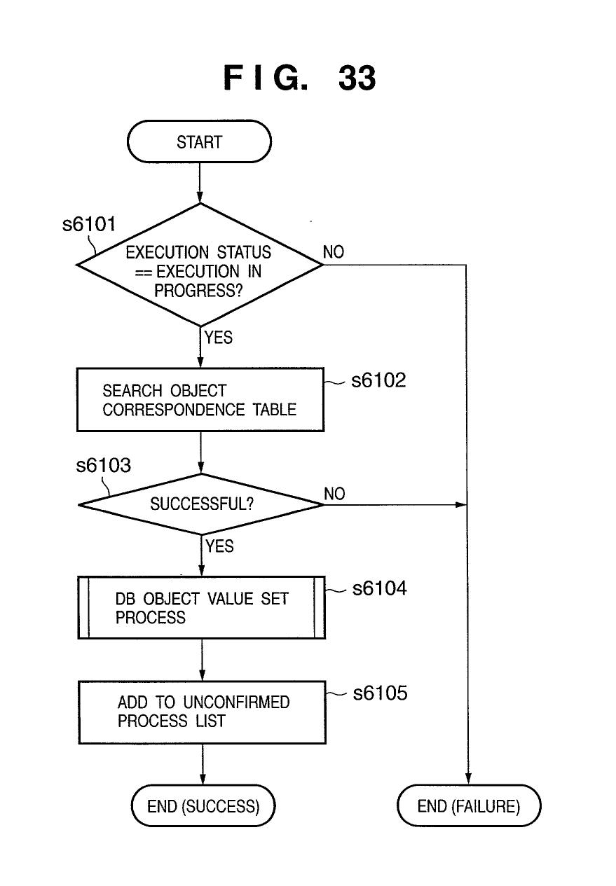

Details of the object update process in step s2002 will be described below using FIG. 33.

FIG. 33 is a flow chart showing details of the object update process in step s2002 of the first embodiment.

When the object update process is launched, it is checked in step s6101 with reference to the execution status of the internal data of the DB transaction if the execution status is “execution in progress”. If the execution status is not “execution in progress” (NO in step s6101), the processing ends as “failure”. On the other hand, if the execution status is “execution in progress” (YES in step s6101), the flow advances to step s6102.

In step s6102, the object correspondence table is searched for a database object corresponding to a given application object.

It is checked in step s6103 if the search has succeeded as a result of the search. If the search has failed (NO in step s6103), the processing ends as “failure”. On the other hand, if the search has succeeded (YES in step s6103), the flow advances to step s6104.

In step s6104, a DB object value set process is executed to set values in the fields of the database object found by search with reference to the values of the given application object.

After that, information corresponding to the above process is added to the aforementioned unconfirmed process list in step s6105, and the processing ends as “success”.

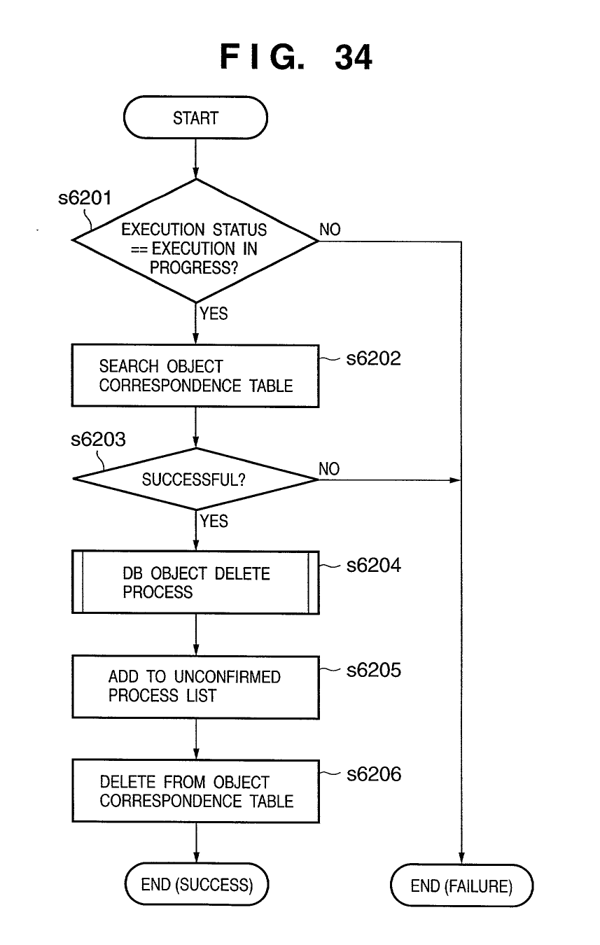

Details of the object delete process in step s2102 will be described below using FIG. 34.

FIG. 34 is a flow chart showing details of the object delete process in step s2102 of the first embodiment.

When the object delete process is launched, it is checked in step s6201 with reference to the execution status of the internal data of the DB transaction if the execution status is “execution in progress”. If the execution status is not “execution in progress” (NO in step s6201), the processing ends as “failure”. On the other hand, if the execution status is “execution in progress” (YES in step s6201), the flow advances to step s6202.

In step s6202, the object correspondence table is searched for a database object corresponding to a given application object.

It is checked in step s6203 if the search has succeeded as a result of the search. If the search has failed (NO in step s6203), the processing ends as “failure”. On the other hand, if the search has succeeded (YES in step s6203), the flow advances to step s6204.

In step s6204, a DB object delete process is executed to delete the database object found by search.

After that, information corresponding to the above process is added to the aforementioned unconfirmed process list in step s6205. In step s6206, a combination of the given application object and the deleted database object is deleted from the object correspondence table, and the processing ends as “success”.

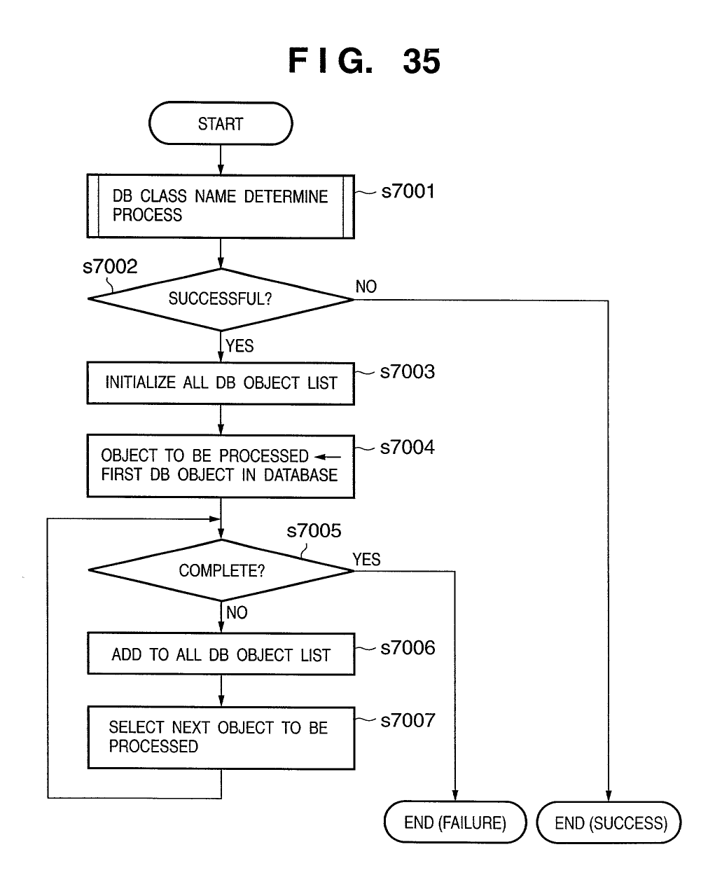

Details of the all DB object acquire process in step s5902 will be described below using FIG. 35.

FIG. 35 is a flow chart showing details of the all DB object acquire process in step s5902 of the first embodiment.

When the all DB object acquire process is launched, a DB class name determine process is executed in step s7001 to determine the database class name in the database corresponding to the application class name of a given application class.

When the class name cannot use “.” as in the database used in the first embodiment, a result obtained by substituting such character by that which can be used in the database (e.g., “_”) is used as the database class name. For example, a database class name “com_xxxx_ks_KSPerson” is determined from the application class name “com.xxxx.ks.KSPerson”.

It is checked in step s7002 if determination of the database class name has succeeded as a result of the DB class name determine process. If determination of the database class name has failed (NO in step s7002), the processing ends as “failure”. On the other hand, if determination of the database class name has succeeded (YES in step s7002), the flow advances to step s7003.

In step s7003, an all database object list for output is initialized. In step s7004, the first one of database objects corresponding to the database class in the database is set as an object to be processed, and processes are repeated for all database objects to be processed in the subsequent steps.

It is checked in step s7005 if the processes for all the database objects to be processed are complete. If the processes for all the database objects to be processed are complete (YES in step s7005), the processing ends as “success”. On the other hand, if the processes for all the database objects to be processed are not complete (NO in step s7005), the flow advances to step s7006.

In step s7006, the database object to be processed is added to the all database object list. After that, the next database object is selected as the object to be processed in step s7007, and the flow returns to step s7005 to repeat the process.

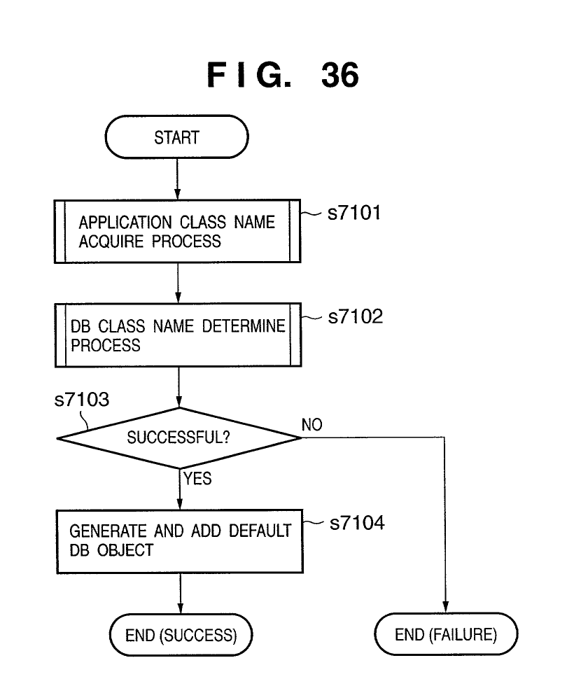

Details of the DB object generate/add process in step s6002 will be described below using FIG. 36.

FIG. 36 is a flow chart showing details of the DB object generate/add process in step s6002 of the first embodiment.

When the DB object generate/add process is launched, an application class name acquire process is executed in step s7101 to acquire the application class name of a given application object. In step s7102, a DB class name determine process is executed to determine the database class name in the database corresponding to the application class name.

It is checked in step s7103 if determination of the database class name has succeeded as a result of the DB class name determine process. If determination of the database class name has failed (NO in step s7103), the processing ends as “failure”. On the other hand, if determination of the database class name has succeeded (YES in step s7102), the flow advances to step s7104.

In step s7104, a default database object corresponding to the database class is generated, and the processing ends as “success”.

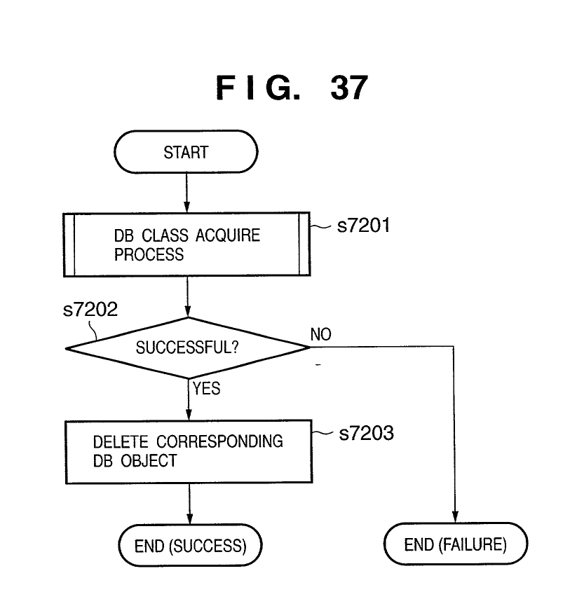

Details of the DB object delete process in step s6204 will be described below using FIG. 37.

FIG. 37 is a flow chart showing details of the DB object delete process in step s6204 of the first embodiment.

When the DB object delete process is launched, a DB class acquire process is executed in step s7201 to acquire a database class corresponding a given database object.

It is checked in step s7202 if acquisition of the database class has succeeded as a result of the DB class acquire process. If acquisition of the database class has failed (NO in step s7202), the processing ends as “failure”. On the other hand, if acquisition of the database class has succeeded (YES in step s7202), the flow advances to step s7203.

In step s7203, the given database object is deleted using a service of the database class, and the processing ends as “success”.

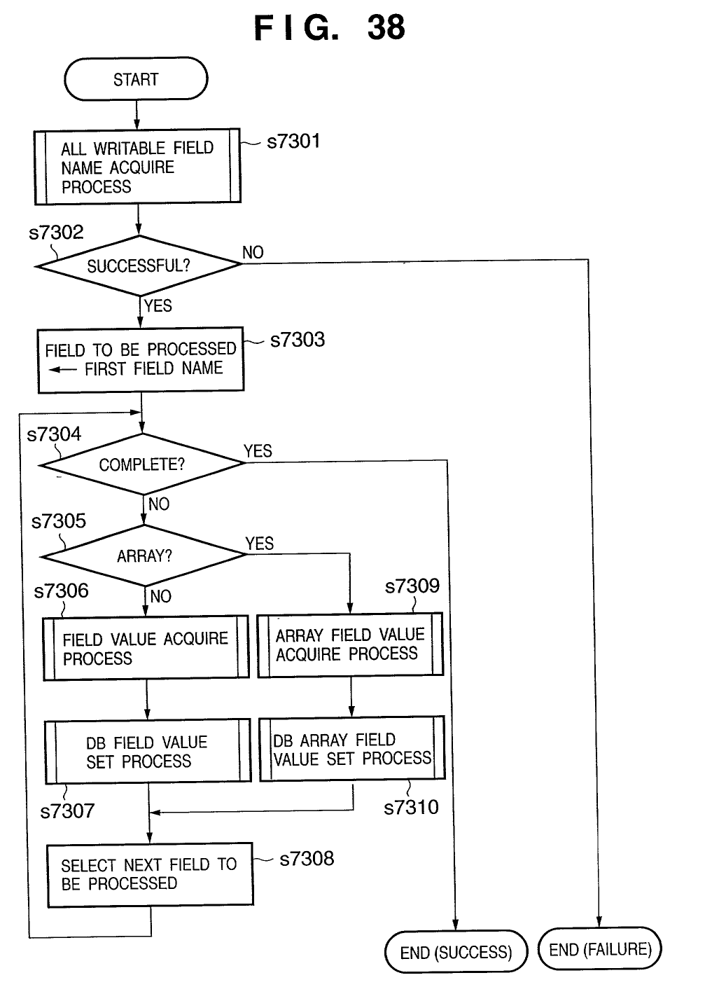

Details of the DB object value set process in steps s5907 and s6003 in the object add process in FIG. 31 and the object update process in FIG. 32 will be described below using FIG. 38.

FIG. 38 is a flow chart showing details of the DB object value set process in steps s5907 and s6003 of the first embodiment.

When the DB object value set process is launched, an all writable field name acquire process is executed in step s7301 to acquire all writable field names with reference to the field definitions of a given application object.

It is checked in step s7302 if acquisition of the field names has succeeded as a result of the all writable field name acquire process. If acquisition of the field names has failed (NO in step s7302), the processing ends as “failure”. On the other hand, if acquisition of the field names has succeeded (YES in step s7302), the flow advances to step s7303.

In step s7303, the first field in a list of all the acquired writable field names is set to be a field to be processed, and processes are repeated for all fields to be processed in the subsequent steps.

It is checked in step s7304 if the processes for all the fields to be processed are complete. If the processes for all the fields to be processed are complete (YES in step s7304), the processing ends as “success”. On the other hand, if the processes for all the fields to be processed are not complete (NO in step s7304), the flow advances to step s7305.

It is checked in step s7305 if the field to be processed is an array. If the field is not an array (NO in step s7305), the flow advances to step s7306.

In step s7306, a field value acquire process is executed to acquire a value corresponding to the field name of the field to be processed of the given application object. In step s7307, a DB field value set process is executed to store the value in the corresponding field of the database object. In step s7308, the next field is selected as the field to be processed, and the flow returns to step s7304 to repeat the process.

On the other hand, if it is determined in step s7305 that the field to be processed is an array (YES in step s7305), the flow advances to step s7309.

In step s7309, an array field value acquire process is executed to acquire a value corresponding to the field name of the field to be processed of the given application object. In step s7310, a DB array field value set process is executed to store the value in the corresponding field of the database object. In step s7308, the next field is selected as the field to be processed, and the flow returns to step s7304 to repeat the process.

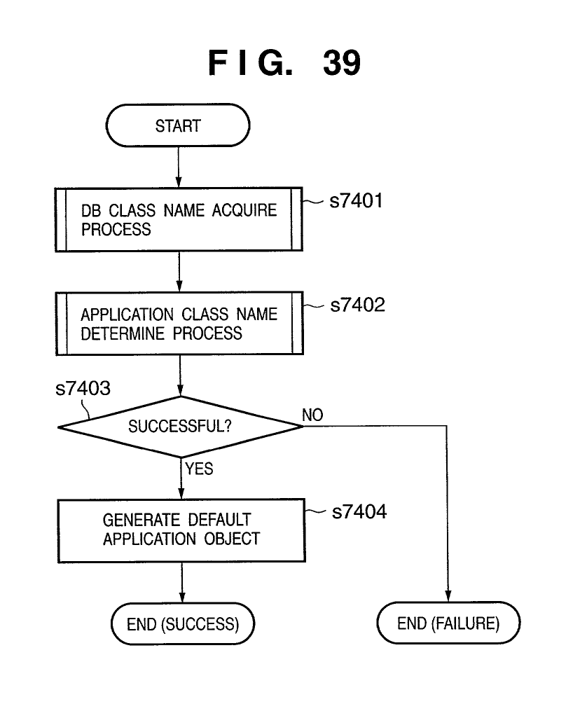

Details of the object generate process in step s5906 will be described below using FIG. 39.

FIG. 39 is a flow chart showing details of the object generate process in step s5906 of the first embodiment.

When the object generate process is launched, a DB class name acquire process is executed in step s7401 to acquire the database class name of a given database object. In step s7402, an application class name determine process is executed to determine an application class name corresponding to the database class name.

It is checked in step s7403 if determination of the application class name has succeeded as a result of the application class name determine process. If determination of the application class name has failed (NO in step s7403), the processing ends as “failure”. On the other hand, if determination of the application class name has succeeded (YES in step s7403), the flow advances to step s7404.

In step s7404, a default application object corresponding to the application class is generated, and the processing ends as “success”.

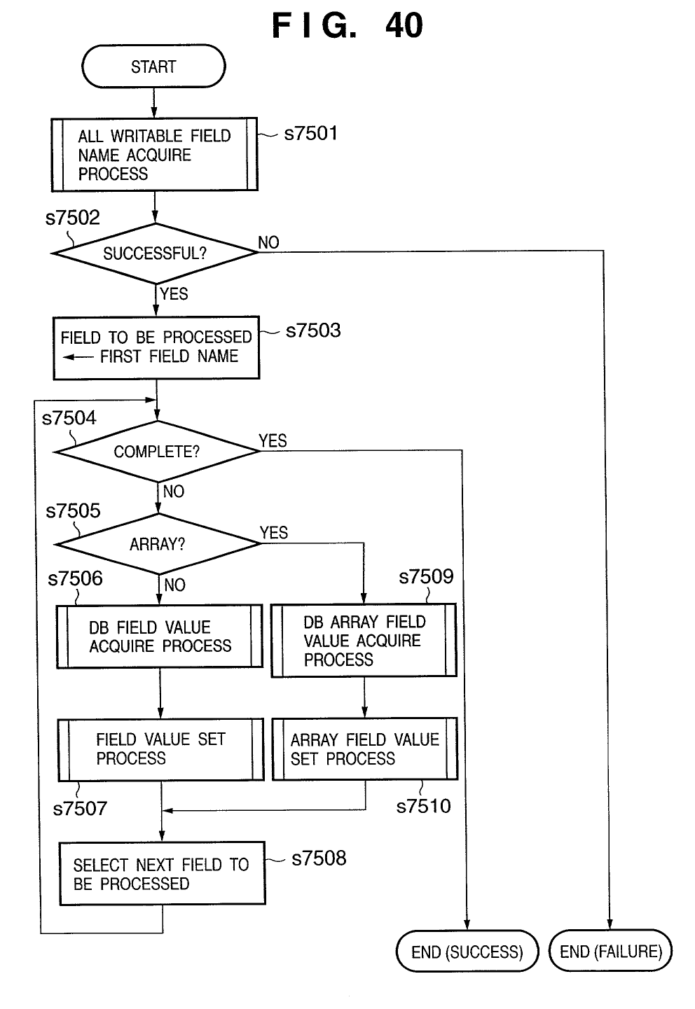

Details of the object value set process in step s5907 will be described below using FIG. 40.

FIG. 40 is a flow chart showing details of the object value set process in step s5907 of the first embodiment.

When the object value set process is launched, an all writable field name acquire process is executed in step s7501 to acquire all writable field names with reference field definitions of a given application object.

It is checked in step s7502 if acquisition of the field names has succeeded as a result of the all writable field name acquire process. If acquisition of the field names has failed (NO in step s7502), the processing ends as “failure”. On the other hand, if acquisition of the field names has succeeded (YES in step s7502), the flow advances to step s7503.

In step s7503, the first field in a list of all the acquired writable field names is set to be a field to be processed, and processes are repeated for all fields to be processed in the subsequent steps.

It is checked in step s7504 if the processes for all the fields to be processed are complete. If the processes for all the fields to be processed are complete (YES in step s7504), the processing ends as “success”. On the other hand, if the processes for all the fields to be processed are not complete (NO in step s7504), the flow advances to step s7505.

It is checked in step s7505 if the field to be processed is an array. If the field is not an array (NO in step s7505), the flow advances to step s7506.

In step s7506, a DB field value acquire process is executed to acquire a value corresponding to the field name of the field to be processed of the given database object. In step s7507, a field value set process is executed to store the value in the corresponding field of the application object. In step s7508, the next field is selected as the field to be processed, and the flow returns to step s7504 to repeat the process.

On the other hand, if it is determined in step s7505 that the field is an array (YES in step s7505), the flow advances to step s7509.

In step s7509, a DB array field value acquire process is executed to acquire a value corresponding to the field name of the field to be processed of the given database object. In step s7510, an array field value set process is executed to store the value in the corresponding field of the application object. In step s7508, the next field is selected as the field to be processed, and the flow returns to step s7504 to repeat the process.

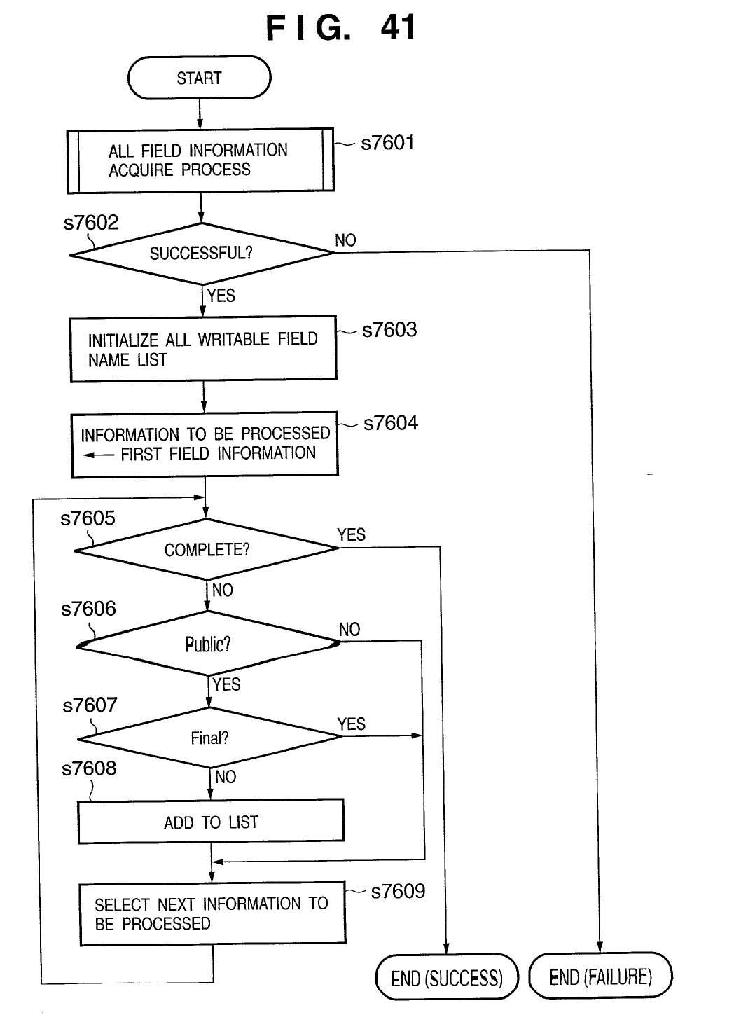

Details of the all writable field name acquire process in steps s7301 and s7501 in the DB object value set process in FIG. 38 and the object value set process in FIG. 40 will be described below using FIG. 41.

FIG. 41 is a flow chart showing details of the all writable field name acquire process in steps s7301 and s7501 of the first embodiment.

When the all writable field name acquire process is launched, an all field information acquire process is executed in step s7601 to acquire each field information of a given application object.

It is checked in step s7602 if acquisition of field information has succeeded as a result of the all field information acquire process. If acquisition of field information has failed (NO in step s7602), the processing ends as “failure”. On the other hand, if acquisition of field information has succeeded (YES in step s7602), the flow advances to step s7603.

In step s7603, an all writable field name list for output is initialized. In step s7604, the first one of all the pieces of acquired field information is set to be field information to be processed, and processes are repeated for all pieces of field information to be processed in the subsequent steps.

It is checked in step s7605 if the processes for all the pieces of field information to be processed are complete. If the processes for all the pieces of field information to be processed are complete (YES in step s7605), the processing ends as “success”. On the other hand, if the processes for all the pieces of field information to be processed are not complete (NO in step s7605), the flow advances to step s7606.

It is checked in step s7606 if the field attribute of the field information is “Public”. If the field attribute is not “Public” (NO in step s7606), the flow jumps to step s7609. On the other hand, if the field attribute is “Public” (YES in step s7606), the flow advances to step s7607.

It is checked in step s7607 if the field attribute of the field information is “Final”. If the field attribute is “Final” (YES in step s7607), the flow jumps to step s7609. On the other hand, if the field attribute is not “Final” (NO in step s7607), the flow advances to step s7608.

In step s7608, the field name of the field information to be processed is added to the all writable field name list. After that, the next field information is selected as the field information to be processed in step s7609, and the flow returns to step s7605 to repeat the process.

As described above, according to the first embodiment, application object definition information that defines an application object, which is referred to by an application program, is acquired with respect to a database that stores permanent data, and the database is manipulated using that application object and the acquired application object definition information.

In this way, the database can be exploited to process permanent data without learning any coding sequences unique to a database module and complicated know-how, and the developer can concentrate on the development of a unique business logic, thus greatly improving the development efficiency.

<Second Embodiment>

The second embodiment will explain an arrangement that can solve the conventional problems to be described below.

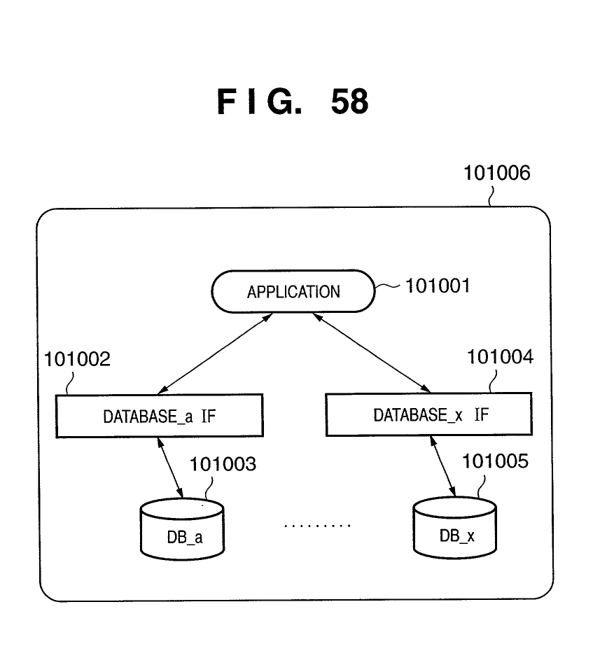

FIG. 58 shows an example of an application program in which a plurality of databases with different interfaces are embedded using the prior art.

In order to access databases a 101003 and x 101005 which are present on the same device 101006 as an application program 101001, a database a interface 101002 and database x interface 101004 that implement interfaces corresponding to these databases are embedded.

For this reason, an application developer must learn about these interfaces before implementation, resulting in development efficiency drop and quality drop.

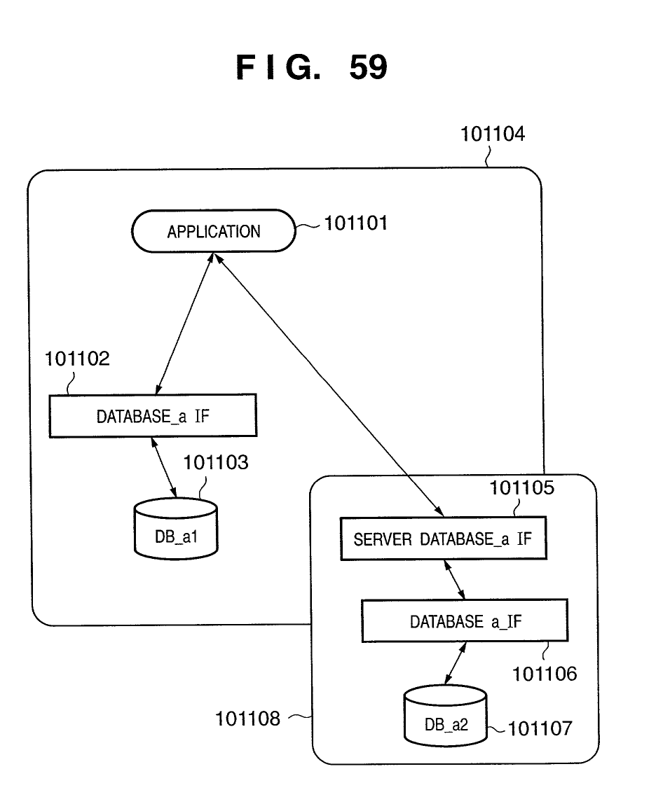

FIG. 59 shows an example of an application program in which a plurality of databases using identical interfaces, which are present on different devices, are embedded using the prior art.

In order to access a database a 101103 present on the same device 101194 as an application program 101101, and a database a 101107 present on a different device 101108, a database a interface 101102 and server database a interface 101105 that implement interfaces corresponding to a local and server are embedded.

For this reason, an application developer must learn about these interfaces before implementation, resulting in development efficiency drop and quality drop.

As described above, in the prior art, the developer must learn about different interfaces depending on a difference in type of database and difference in database location (local or server) before implementation, resulting in development efficiency drop and quality drop.

To solve this problem, the following arrangement is available.

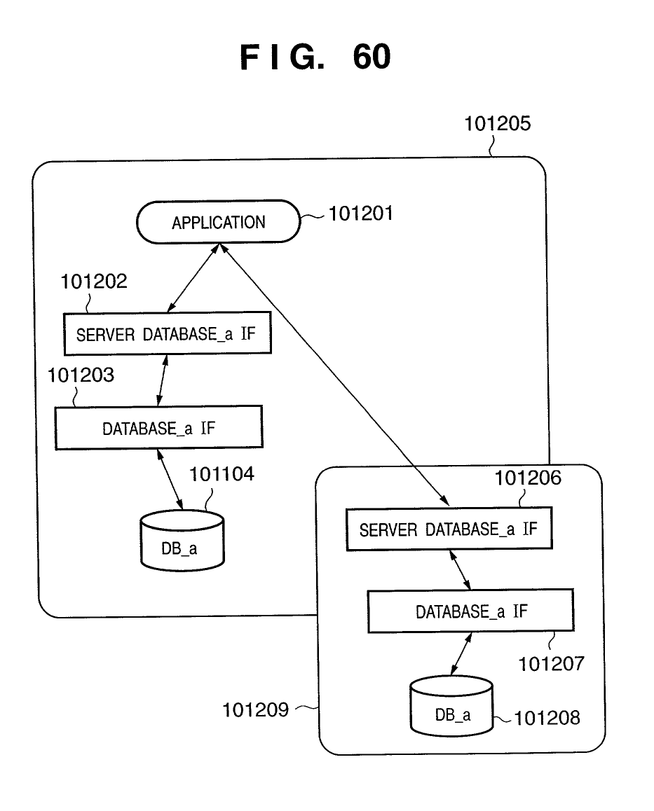

FIG. 60 shows an example of an application program in which a plurality of databases using identical interfaces, which are present on different devices, are embedded so as to solve the conventional problems.

In order to access a database a 101204 present on the same device 101205 as an application program 101201, and a database a 101208 present on a different device 101209, server database a interfaces 101202 and 101206 that implement interfaces corresponding to a server are embedded.

For this reason, an application developer can implement by learning about the server database a interfaces 101202 and 101206 as only one type of interface. However, since a server interface is used even for a local database, an overhead cannot be avoided.

As described above, even when the above method is used, a difference in type of database and difference in database location (local or server) cannot be absorbed without generating any extra overhead with respect to a local database.

Details of an arrangement of the second embodiment which can solve the conventional problems will be described below.

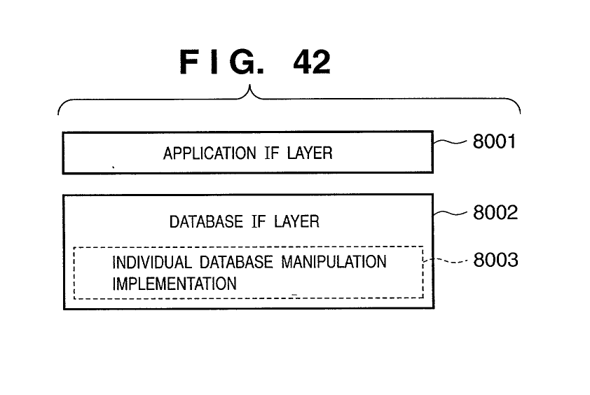

FIG. 42 is a diagram showing hierarchically structured database manipulation means of an information processing apparatus of the second embodiment.

The database manipulation means of the second embodiment is formed by three components, i.e., an application IF (interface) layer 8001, database IF (interface) layer 8002, and individual database manipulation implementation 8003.

The application IF layer 8001 mediates to absorb differences among various data structures used in an application program and database, and differences in method. More specifically, the application IF layer 8001 converts application and database objects with one another, and wraps a database method in a format required by the application program.

The database IF layer 8002 provides an upper class or interface of various database manipulations, and also a method common to various databases. In this way, the method common to all databases can be implemented, and common processes independent from individual databases need not be individually implemented.

The individual database manipulation implementation 8003 can implement various manipulations of individual databases by expanding an upper class or interface provided by the database IF layer.

Since the database manipulation means has the aforementioned hierarchical structure, an application developer can use different databases without using individual methods. For individual database providers, a provided database can be embedded without modifying an existing application.

Furthermore, for application developers with different requirements, specialized functions can be implemented by developing a dedicated application IF layer.

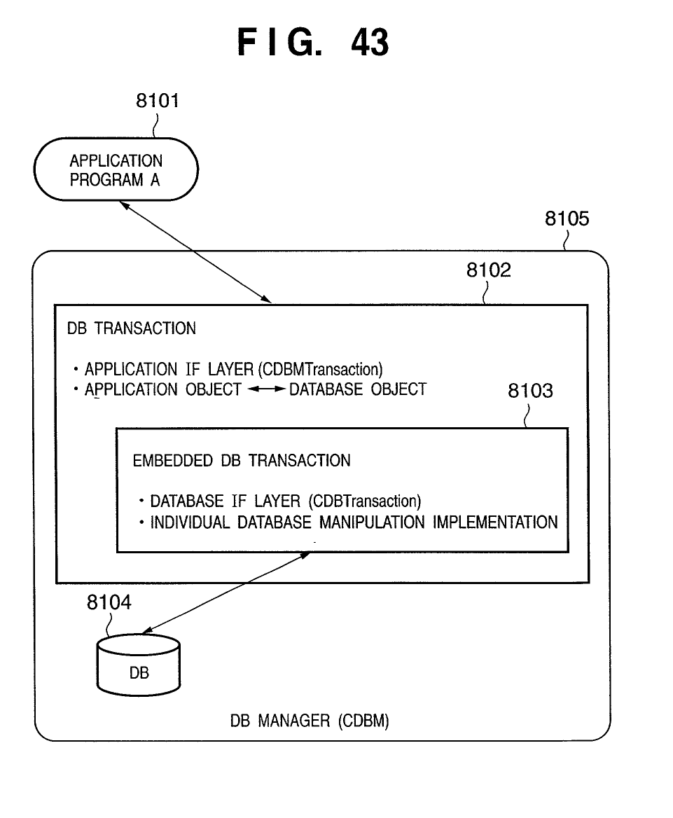

A hierarchical DB transaction structure of the second embodiment will be described below using FIG. 43.

FIG. 43 shows a hierarchical DB transaction structure of the second embodiment.

A DB manager 8105 of the second embodiment generates/discards a DB transaction 8102 that processes a series of transactions with a database 8104 in response to a request from application program A (8101).

Note that the DB transaction 8102 is formed by an application interface layer that exchanges information with application program A (8101), and a database interface layer dependent on an embedded DB transaction 8103 of each database.

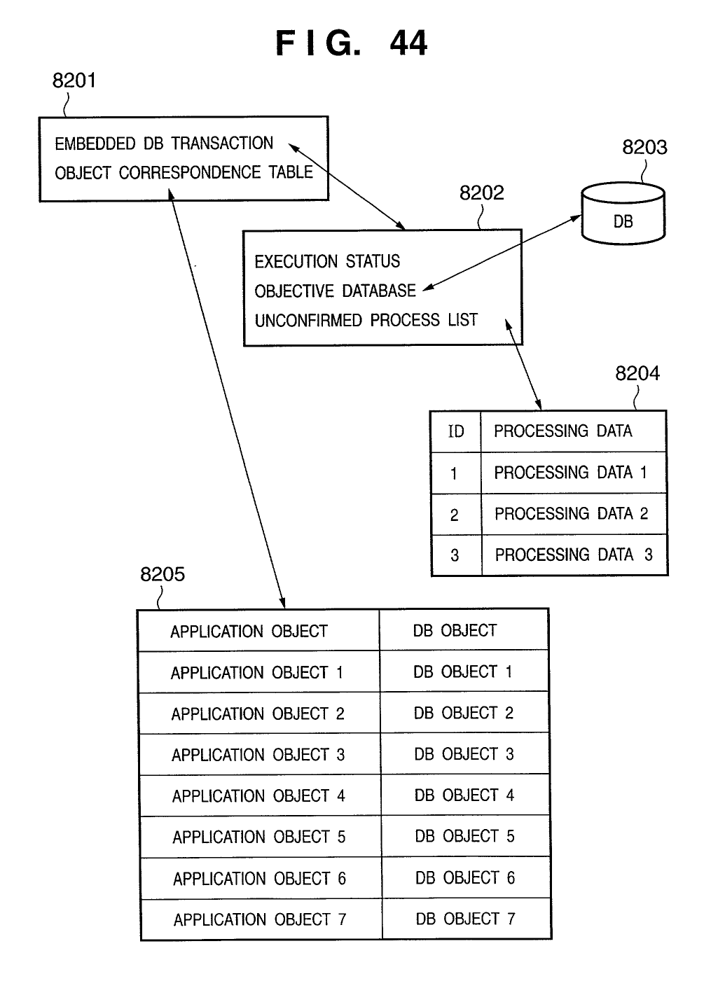

Internal data of the hierarchical DB transaction will be described below using FIG. 44.

FIG. 44 shows internal data of the hierarchical DB transaction of the second embodiment.

The hierarchical DB transaction has information 8202 of an embedded DB transaction which is installed actually, and internal data of an object correspondence data table 8205 for storing relationships between application objects to be processed and DB objects after generation of the transaction, as indicated by 8201.

The information 8202 of the embedded DB transaction has execution status indicating if execution of the transaction is in progress, information 8203 of a database as a transaction target, and a list 8204 of unconfirmed processes executed during execution of the transaction.

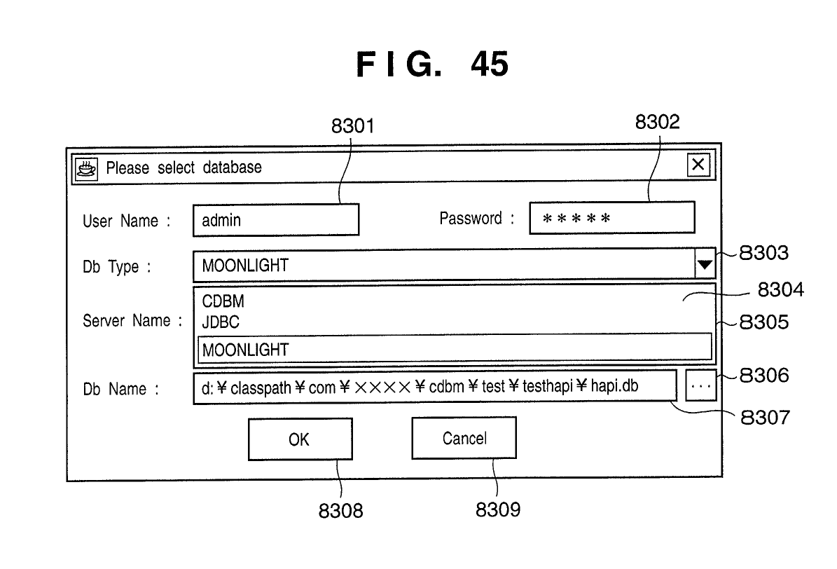

A transaction generation window upon selecting the type of database on the transaction generation window shown in FIG. 5 above will be described below using FIG. 45.

FIG. 45 shows an example of a transaction generation window upon selecting the type of database in the second embodiment.

Reference numeral 8303 denotes a combo box for designating the type of database. With this combo box, the type of arbitrary database can be selected.

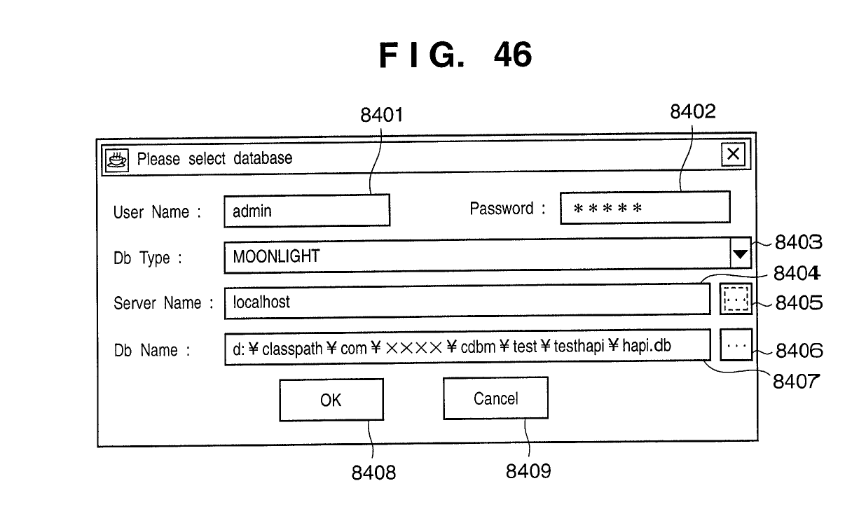

A transaction generation window upon inputting a server name on the transaction generation window shown in FIG. 5 above will be described below using FIG. 46.

FIG. 46 shows an example of a transaction generation window upon inputting a server name in the second embodiment.

Reference numeral 8404 denotes an input area of a server name that provides a connection service to a database. With this input area, an arbitrary server name or nothing can be designated.

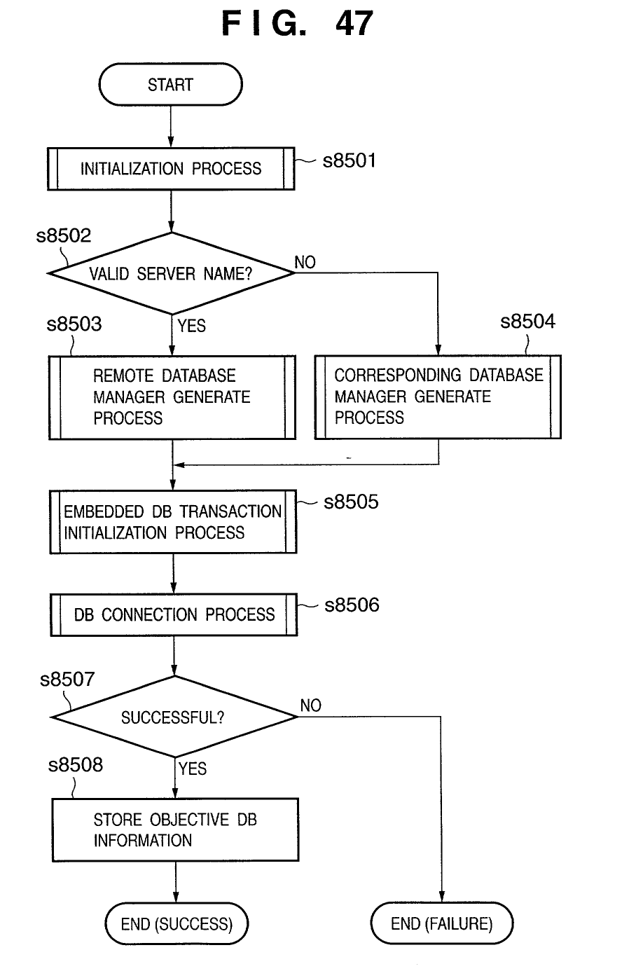

Details of a DB transaction generate process in step s603 of the second embodiment will be described below using FIG. 47.

FIG. 47 is a flow chart showing details of a DB transaction generate process in step s603 of the second embodiment.

When the DB transaction generate process is launched, an initialization process is executed in step s8501 to initialize internal data of the hierarchical DB transaction described using FIG. 44. It is then checked in step s8502 if the server name designated on the transaction generation window described using FIG. 46 is valid. If the server name is valid (YES in step s8502), the flow advances to step s8503 to execute a remote database manager generate process, thus generating a database manager for establishing connection to a server designated by the server name. On the other hand, if the server name is not valid (NO in step s8502), the flow advances to step s8504 to execute a corresponding database manager generate process, thus generating a database manager of a database designated by the transaction generation window described using FIG. 45.

In step s8505, an embedded DB transaction initialization process provided by the generated database manager is executed to initialize internal data of the embedded DB transaction described using FIG. 44.

In step s8506, a DB connection process provided by the generated database manager is executed to establish connection to a database under the designated condition.

It is checked in step s8507 if connection to the database has succeeded as a result of the DB connection process. If connection to the database has failed (NO in step s8507), the processing ends as “failure”. On the other hand, if connection to the database has succeeded (YES in step s8507), the flow advances to step s8508.

In step s8508, information that pertains to connection is stored in the internal data of the embedded DB transaction, and the processing ends as “success”.

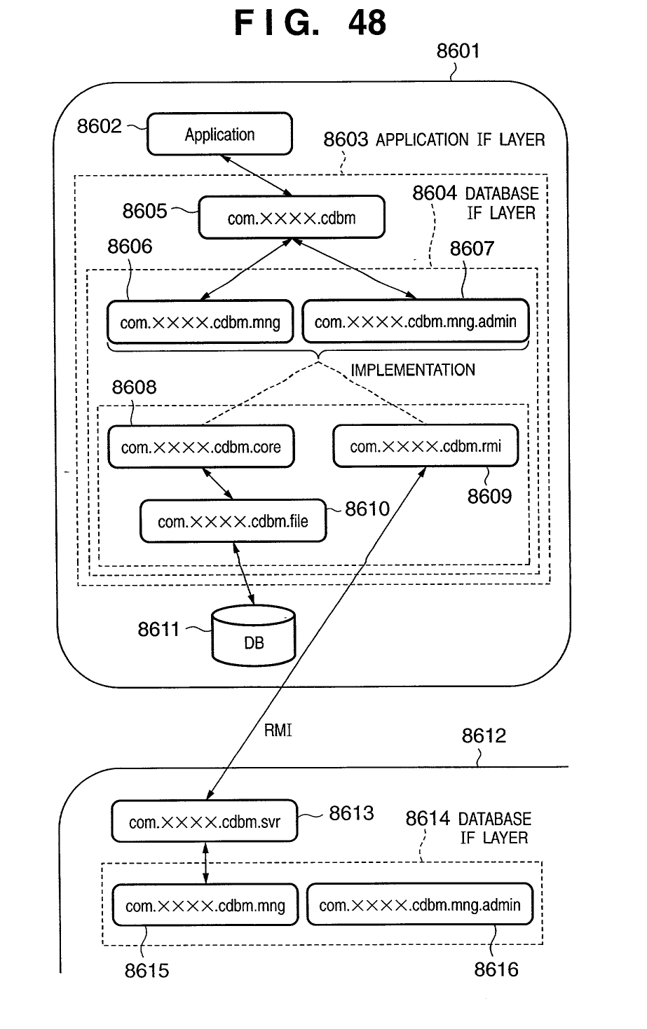

The relationship between packages as groups of some purposes described in the paragraph of the hierarchical DB transaction structure will be described below using FIG. 48.

FIG. 48 shows an example of the relationship between packages as groups of some purposes of the hierarchical DB transaction structure of the second embodiment.

Referring to FIG. 48, reference numerals 8601 and 8612 denote groups of systems, devices, processes, and the like in which the second embodiment runs, and which can exchange objects with each other using a protocol such as RMI or the like.

An application program 8602 can access a database 8611 via a package com.xxxx.cdbm 8605 that implements an application IF layer 8603 present on the single device 8601.

The application IF layer 8603 is implemented using packages com.xxxx.cdbm.mng 8606 and com.xxxx.cdbm.mng.admin 8607 of a database IF layer 8604.

Note that implementations unique to each database are made by packages com.xxxx.cdbm.core 8608 and com.xxxx.cdbm.rmi 8609 obtained by expanding the interface or class of the database IF layer 8604. Also, a package com.xxxx.cdbm.file 8610 hides the physical structure of the database 8611 used by the package 8608.

In order to access a database present on a different device, a package com.xxxx.cdbm.svr 8613 of another device is used via a protocol such as RMI or the like embedded in the package 8609. Note that the package 8613 and subsequent packages can be freely embedded. In FIG. 48, packages com.xxxx.cdbm.mng 8615 and com.xxxx.cdbm.mng.admin 8616 of a database IF layer 8614 are used as in the aforementioned arrangement.

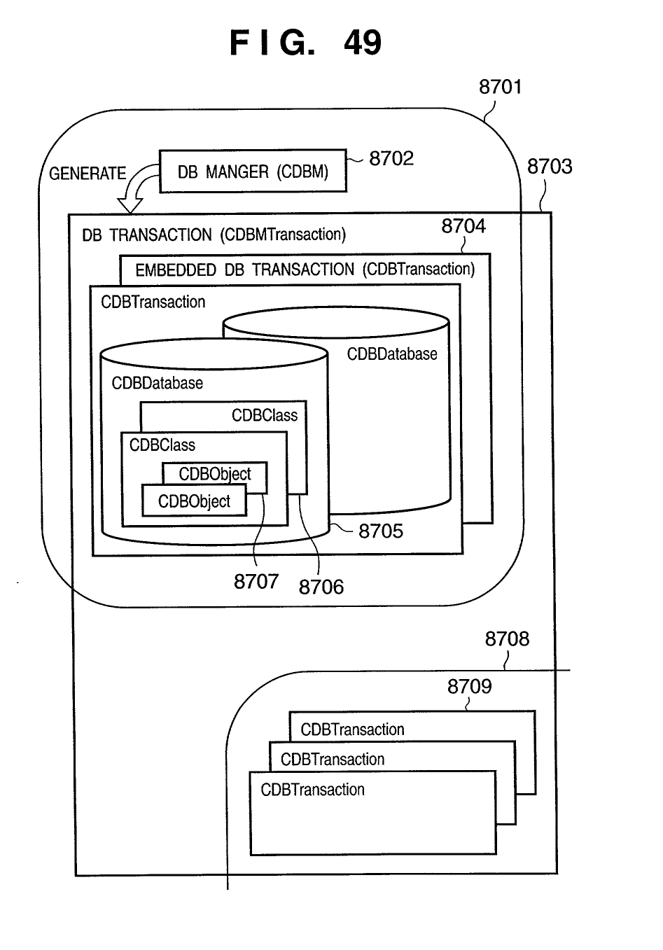

The relationship between classes explained in the hierarchical DB transaction structure will be described below using FIG. 49.

FIG. 49 shows an example of the relationship between classes in the hierarchical DB transaction structure of the second embodiment.

Referring to FIG. 49, reference numerals 8701 and 8708 denote groups of systems, devices, processes, and the like in which the second embodiment runs, and which can exchange objects with each other using a protocol such as RMI or the like.

An application generates a DB transaction class CDBMTransaction 8703 using a DB manager class CDBM 8702 present on the same device 8701 so as to access a database.

The DB transaction class CDBMTransaction 8703 includes an embedded DB transaction class CDBTransaction 8704 corresponding to the designated database.

The embedded DB transaction class CDBTransaction 8704 includes a database class CDBDatabase 8705 corresponding to the designated database.

The database class CDBDatabase 8705 includes a database definition class CDBClass 8706 corresponding to the definition of stored data.

The database definition class CDBClass 8706 includes a database object class CDBObject 8707 corresponding to stored data.

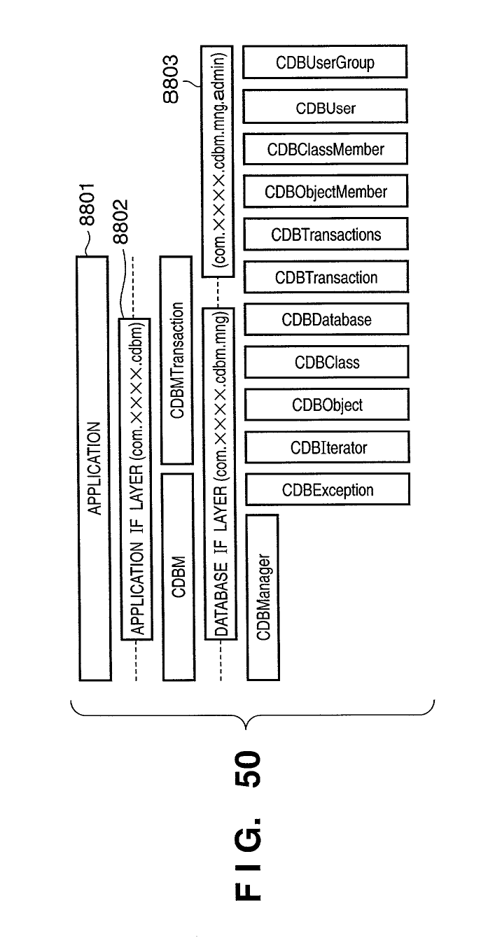

A basic class layer explained in the hierarchical DB transaction structure will be described below using FIG. 50.

FIG. 50 shows an example of a basic class layer of the hierarchical DB transaction structure of the second embodiment.

Referring to FIG. 50, an application 8801 accesses a database using a service provided by an application IF layer com.xxxx.cdbm 8802.

Each class of the application IF layer com.xxxx.cdbm 8802 is processed using services provided by database IF layers com.xxxx.cdbm.mng and com.xxxx.cdbm.mng.admin 8803.

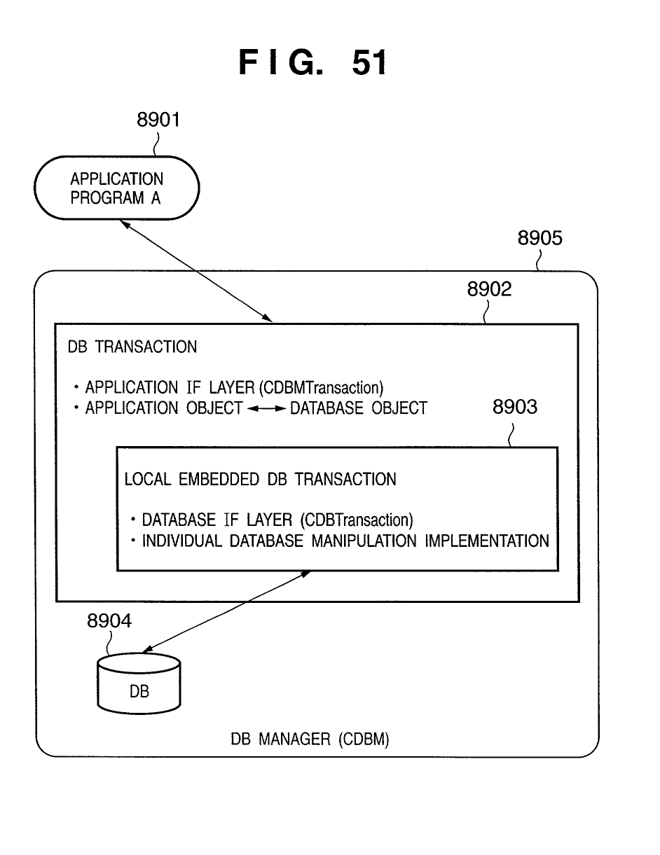

Of the hierarchical DB transaction structure, a hierarchical DB transaction structure used when a database is present on the same device as an application program will be described below using FIG. 51.

FIG. 51 shows an example of a hierarchical transaction structure when a database is present on the same device as an application program in the second embodiment.

A DB manager 8905 of the second embodiment generates/discards a DB transaction 8902 that processes a series of transactions with a database 8904 in response to a request from application program A (8901).

Note that the DB transaction 8902 is formed by an application interface layer that exchanges information with application program A (8901), and a database interface layer dependent on a local embedded DB transaction 8903 of the database present on the same device.

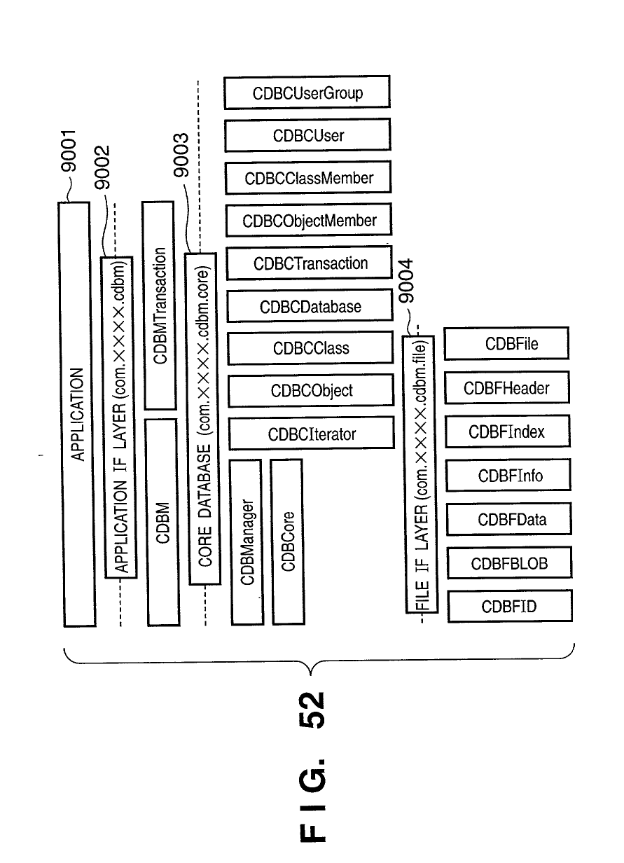

A basic class layer upon expanding the basic class layer to a local database will be explained using FIG. 52.

FIG. 52 shows an example of a basic class layer upon expansion to a local database in the second embodiment.

Referring to FIG. 52, an application 9001 accesses a database using a service provided by an application IF layer com.xxxx.cdbm 9002.

Each class of the application IF layer com.xxxx.cdbm 9002 is processed using services provided by the database IF layers com.xxxx.cdbm.mng and com.xxxx.cdbm.mng.admin explained in FIG. 50. Note that these layers are implemented by a core database com.xxxx.cdbm.core 9003. That is, the core database com.xxxx.cdbm.core 9003 is implemented by expanding interfaces and classes provided by the database IF layers com.xxxx.cdbm.mng and com.xxxx.cdbm.mng.admin explained in FIG. 50.

The core database com.xxxx.cdbm.core 9003 is implemented using a file IF layer com.xxxx.cdbm.file 9004 that hides the physical structure of the database.

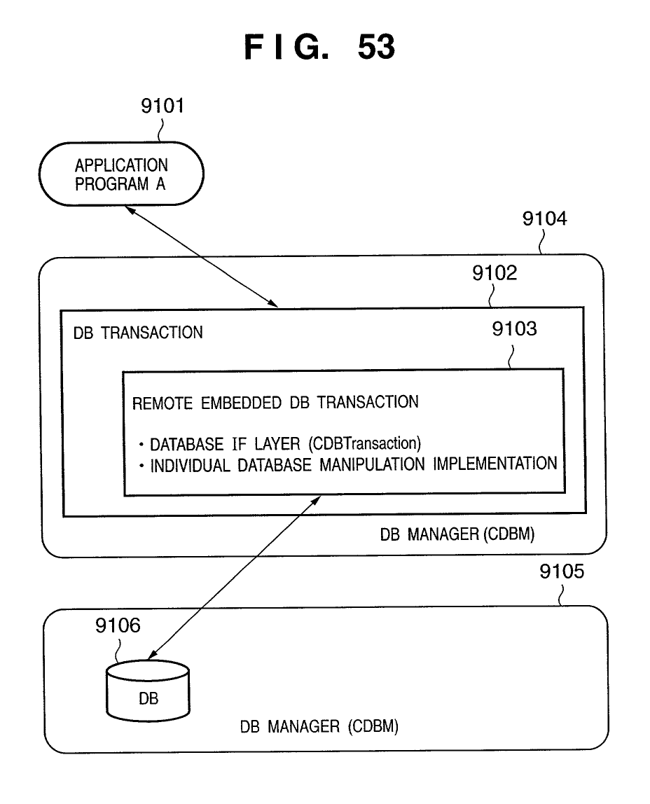

Of the hierarchical DB transaction structure, a hierarchical DB transaction structure used when a database is present on a device different from an application program will be described below using FIG. 53.

FIG. 53 shows an example of a hierarchical transaction structure when a database is present on a device different from an application program in the second embodiment.

A DB manager 9104 of the second embodiment generates/discards a DB transaction 9102 that processes a series of transactions with a database 9106 in response to a request from application program A (9101).

Note that the DB transaction 9102 is formed by an application interface layer that exchanges information with application program A (9101), and a database interface layer dependent on a remote embedded DB transaction 9103 with a database present on a different device 9105.

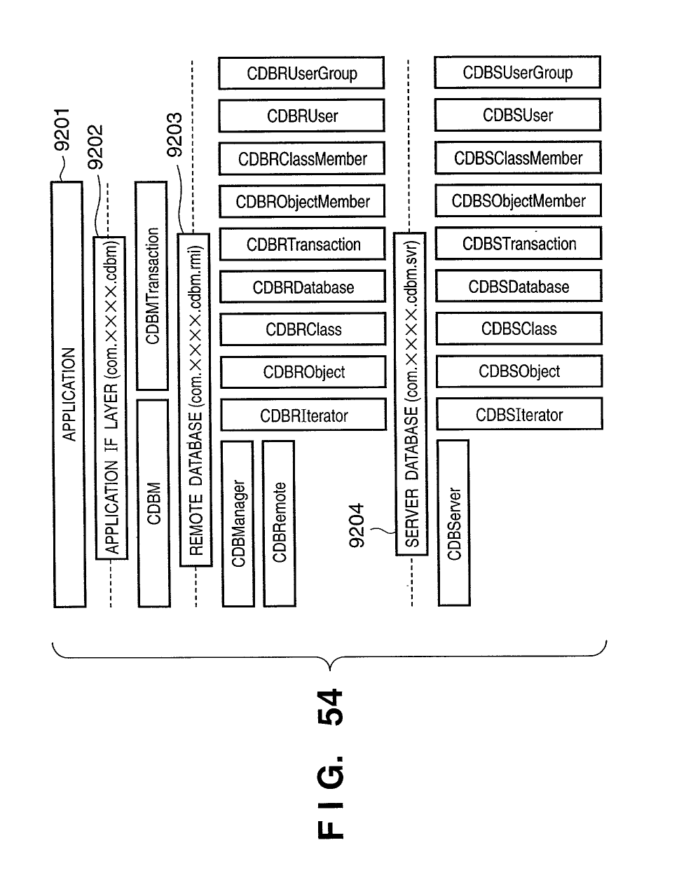

A basic class layer upon expanding the basic class layer to a remote database will be explained below using FIG. 54.

FIG. 54 shows an example of a basic class layer upon expansion to a remote database in the second embodiment.

Referring to FIG. 54, an application 9201 accesses a database using a service provided by an application IF layer com.xxxx.cdbm 9202.

Each class of the application IF layer A com.xxxx.cdbm 9202 is processed using services provided by the database IF layers com.xxxx.cdbm.mng and com.xxxx.cdbm.mng.admin explained in FIG. 50. Note that these layers are implemented by a remote database com.xxxx.cdbm.rmi 9203. That is, the remote database com.xxxx.cdbm.rmi 9203 is implemented by expanding interfaces and classes provided by the database IF layers com.xxxx.cdbm.mng and com.xxxx.cdbm.mng.admin explained in FIG. 50.

Note that the remote database com.xxxx.cdbm.rmi 9203 is implemented using a server database com.xxxx.cdbm.svr 9204 that provides a remote interface used to access a database on a different device.

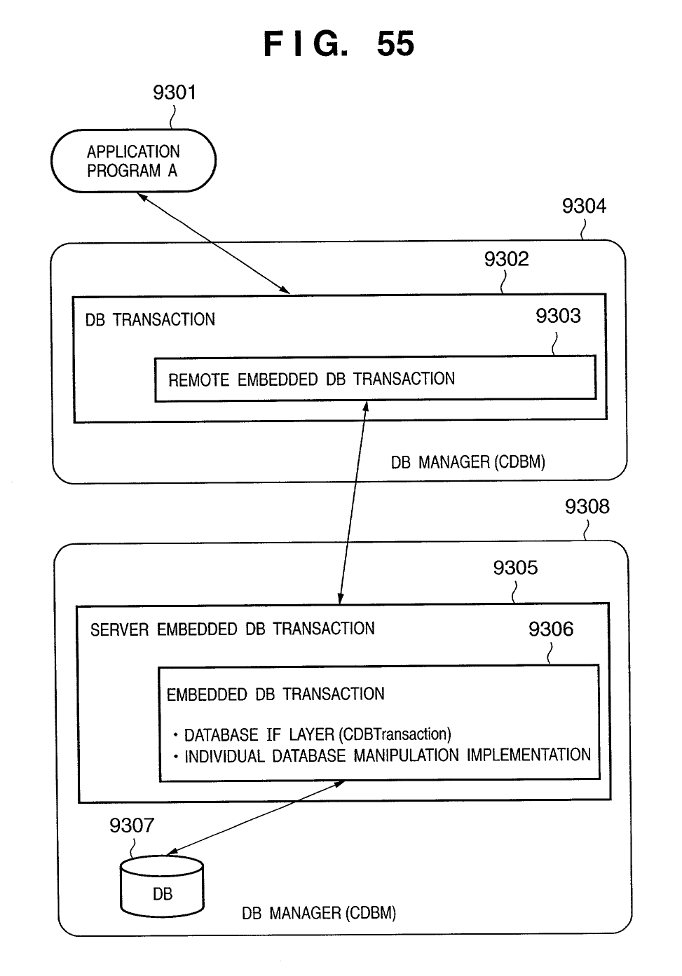

Of the hierarchical DB transaction structure, a hierarchical DB transaction structure used when a database service is provided to an application program on a different device will be described below using FIG. 55.

FIG. 55 shows an example of a hierarchical transaction structure when a database service is provided to an application program on a different device in the second embodiment.

A DB manager 9304 of the second embodiment generates/discards a DB transaction 9302 that processes a series of transactions with a database 9306 in response to a request from application program A (9301).

Note that the DB transaction 9302 is formed by an application interface layer that exchanges information with application program A (9301), and a remote database interface layer dependent on a remote embedded DB transaction 9303 with a database present on a different device 9308.

On the other hand, a DB manager 9308 that provides a database service provides a server embedded DB transaction 9305 that expands a database IF layer dependent on an embedded DB transaction 9306 of the database 9307 so as to allow a different device to use that layer.

As described above, the application hides a remote interface with a database present on a different device using the remote embedded DB transaction 9303, and the database can expand a local service using the server embedded DB transaction 9305 so that the service can be used by a different device.

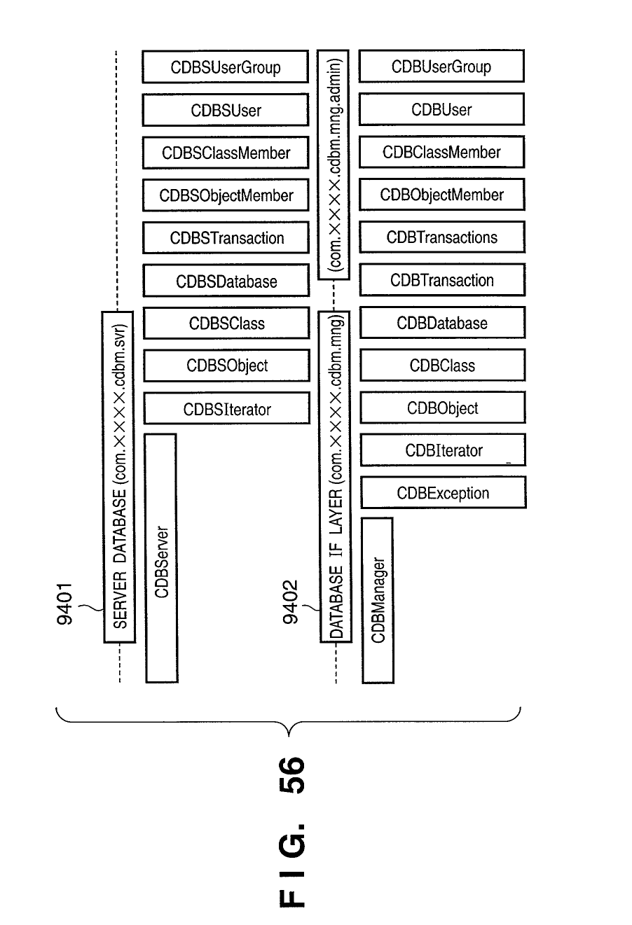

A basic class layer upon expanding a remote interface to allow a different device to use a database IF layer of the basic class layer will be explained below using FIG. 56.

FIG. 56 shows an example of a basic class layer upon expanding a remote interface to allow a different device to use a database IF layer in the second embodiment.

Referring to FIG. 56, a server database 8401 expands a remote interface so that a different device can access a database IF layer 9402.

As described above, since the second embodiment comprises a database that stores permanent data, an application interface for interpreting and processing operations by an application program, a database interface for interpreting and processing operations common to databases, and an individual database for executing database-dependent processes, a difference in type of database and difference in database location (local or server) can be absorbed without generating any extra overhead for a local database. In this manner, a database can be used to handle permanent data without any knowledge about individual interfaces, and a developer can concentrate on the development of a unique business logic, thus greatly improving the development efficiency.

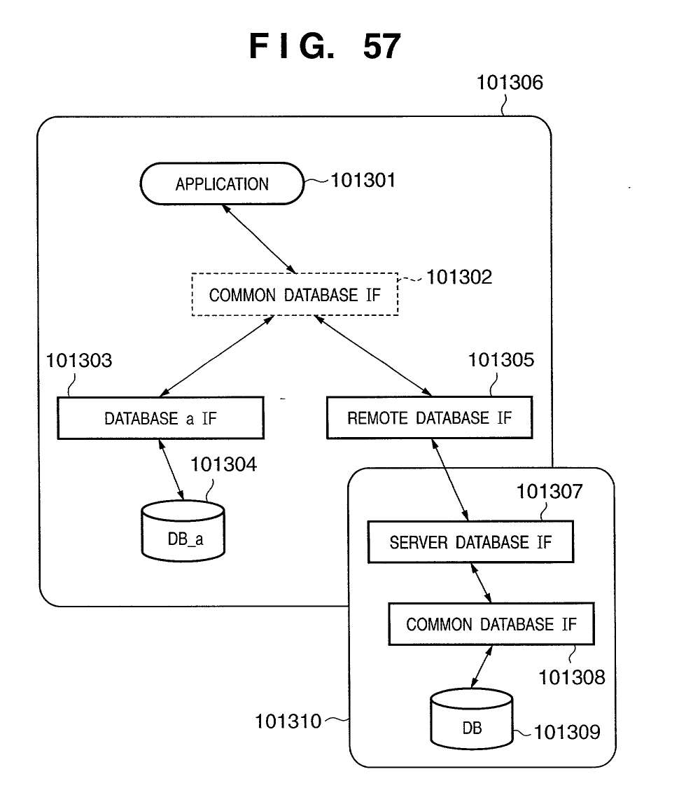

FIG. 57 shows an example of an application program in which a plurality of databases that use different interfaces, which are present on different devices, are embedded using the second embodiment.

In order to access a database a 101304 present on the same device 101306 as an application program 101301, and a database a 101309 present on a different device 101310, a common database interface 101302 is embedded. However, in practice, such access is implemented by a database a interface 101303 and remote database interface 101305 obtained by expanding the interface and class provided by the common database interface 101302, and access to a database on a different device is implemented via the remote database interface 101305 and a server database interface 101307.

For this reason, an application developer can implement a plurality of databases of different interfaces by learning about only the common database interface 101302 as one interface, and an extra overhead for a local database can be avoided.

<Third Embodiment>

The third and fourth embodiments will explain an arrangement for solving conventional problems to be described below.

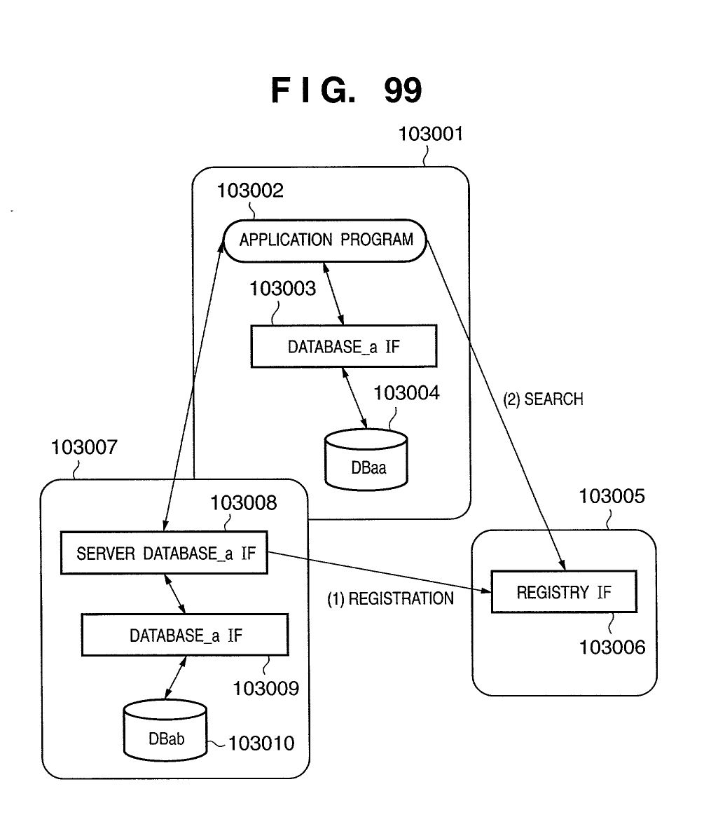

FIG. 99 shows an example of an application program in which a plurality of databases having identical interfaces, which are present on different devices, are embedded using the prior art.

In order to access a database aa 103004 present on the same device 103001 as an application program 103002, and a database ab 103010 present on a different device 103007, a database a interface 103003 and server database a interface 103008 which implement interfaces corresponding to a local and server are embedded.

At this time, the application program 103002 must acquire and implement the server database a interface 103008 obtained by expanding inter-device communication means from an objective database interface a 103009 present on a different device using a registry interface 103006 of a device 103005.

For this reason, an application developer must know about a (2) search method using the registry interface 103006, and an implementation method of a server database interface different from a local. Conversely, a database interface provider must know about a (1) registration method to the registry interface 103006, and an implementation method for expanding an inter-device communication means.

As described above, in the prior art, since a method of manipulating a database present on a given device is different from that for manipulating a database present on another device, knowledge for implementing inter-device communications is required in addition to knowledge unique to the databases.

To solve this problem, Japanese Patent Laid-Open No. 11-203259 discloses a method for handling an object present on a server equivalently to that on a local. With this method, an application developer can use a method having the same name provided by a local object. However, its entity is an object which hides an inter-device communication means having a method of the same name and is different from the above object. For this reason, when the application developer implements an object achieved by Japanese Patent Laid-Open No. 11-203259, an overhead for inter-device communication cannot avoided even for a local object.

To solve the above problem, since the application developer must implement an object implemented by Japanese Patent Laid-Open No. 11-203259, and a source object while consciously making distinction between them, the original problems posed due to different manipulation methods of a database present on a given device and that present on another device cannot be solved.

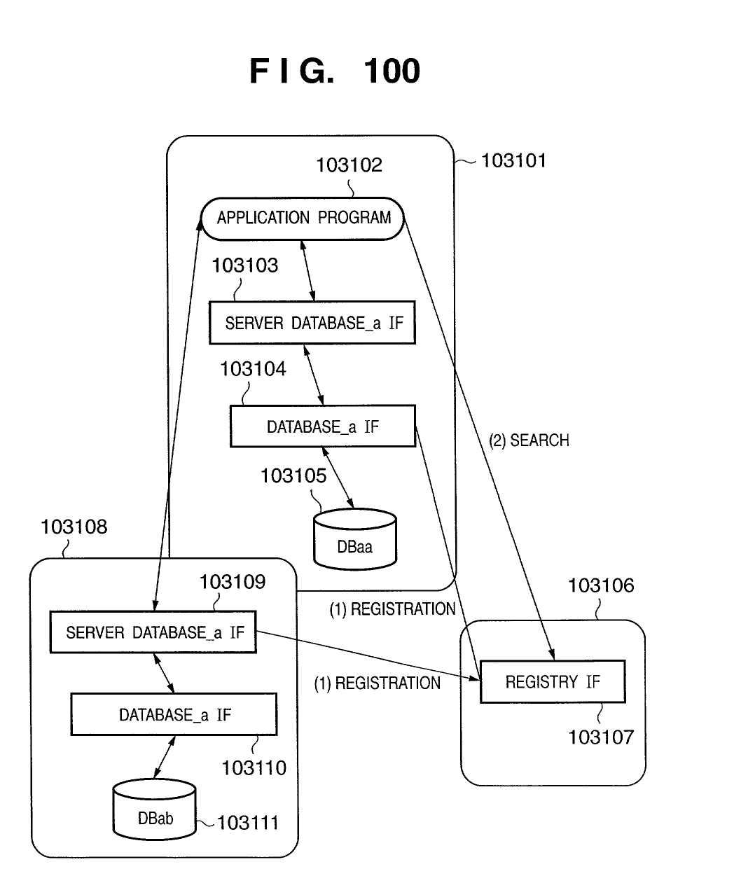

FIG. 100 shows an example of an application program in which a plurality of databases having identical interfaces, which are present on different devices, are embedded using the prior art. In this example, a server database interface is expanded so that a local database can be handled equivalently to a server.

In order to access a database aa 103105 present on the same device 103101 as an application program 103102, and a database ab 103111 present on a different device, server database a interfaces 103103 and 103109 that implement interfaces corresponding to a server are embedded.

At this time, the application program 103102 must acquire and implement the server database a interfaces 103103 and 103109 obtained by expanding inter-device communication means from objective database interfaces a 103104 and 103110 present on different devices using a registry interface 103107 of a device 103106.

For this reason, if an application developer need only know about the (2) search method using the registry interface 103107, he or she need only implement identical server database interfaces. However, the same overhead as that on a different device cannot avoided for a local database. Conversely, a database interface provider must similarly know about the (1) registration method to the registry interface 103006, and the implementation method for expanding an inter-device communication means.

The third and fourth embodiments have as their object to obviate the need for acquisition of knowledge unique to databases and knowledge about implementation of inter-device communications for an application developer in consideration of these problems, since a common method of manipulating a database present on a given device and that present on another device is used without generating any overhead for inter-device communications in the single device. Also, the object of these embodiments is to obviate the need for acquisition of knowledge required upon expanding inter-device communication means for a database interface provider.

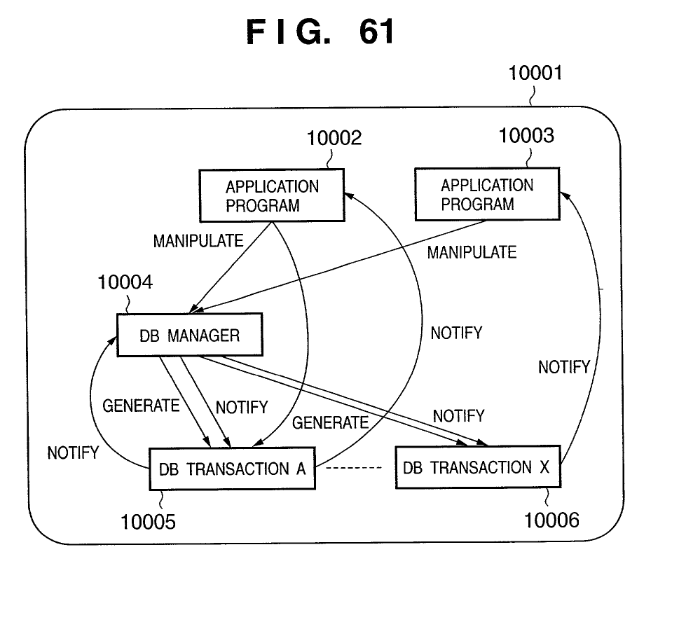

FIG. 61 shows the flow of notify information upon, e.g., a change in database in the third embodiment.

Referring to FIG. 61, a DB transaction A 10005 is generated using a DB manager 10004 which is present on the same device 10001 as an application program 10002. Likewise, a DB transaction X 10006 is generated by an application program 10003.

Upon a change that has taken place as a result of the process done by the DB transaction A 10005, notify information is sent to the DB manager 10004. The DB manager 10004 sends the received notify information to the DB transactions A 10005 and X 10006 under its management. Upon receiving the notify information, the DB transactions A 10005 and X 10006 respectively send the notify information to the application programs 10002 and X 10003.

With this flow, the application programs which received the notify information execute appropriate processes such as re-display processes of database information and the like as needed.

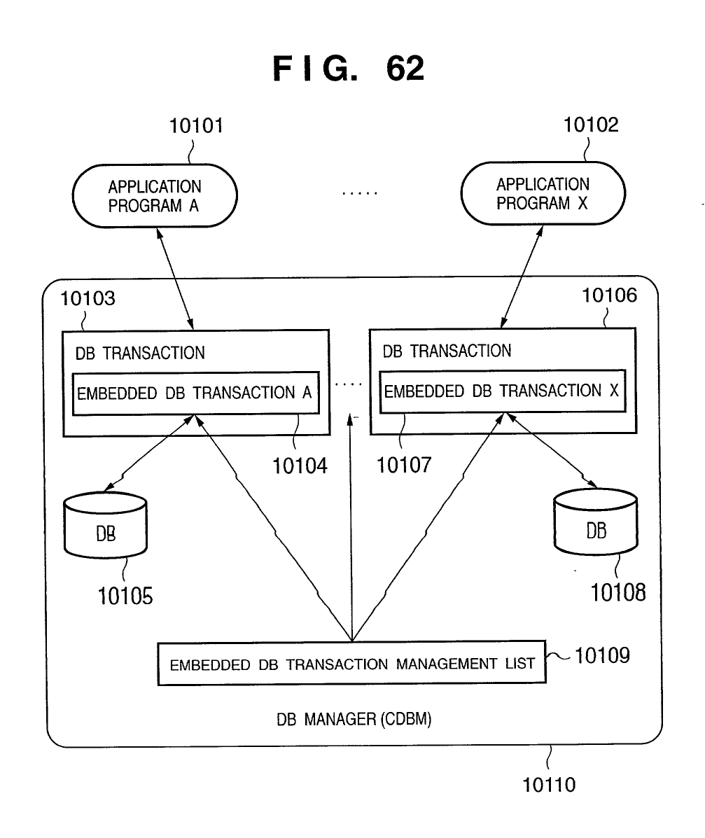

A hierarchical DB transaction structure of the third embodiment will be described below using FIG. 62. In the hierarchical DB transaction structure of the third embodiment, a concept called an embedded DB transaction management list is introduced to the hierarchical DB transaction structure of the second embodiment.

FIG. 62 shows a hierarchical DB transaction structure of the information processing apparatus of the third embodiment.

A DB manager 10110 of the third embodiment generates/discards a DB transaction 10103 that processes a series of transactions with a database 10105 in response to a request from application program A (10101). Note that the DB transaction 10103 is formed by an application interface layer that exchanges information with application program A (10101), and an embedded DB transaction A (10104) as a database interface layer dependent on implementation of an individual database. Likewise, a DB transaction 10106 and embedded DB transaction X (10107) that process a series of transactions with a database 10108 in response to a request from application program X (10102) are generated.

The generated embedded DB transactions are stored in and managed by an embedded DB transaction management list 10109.

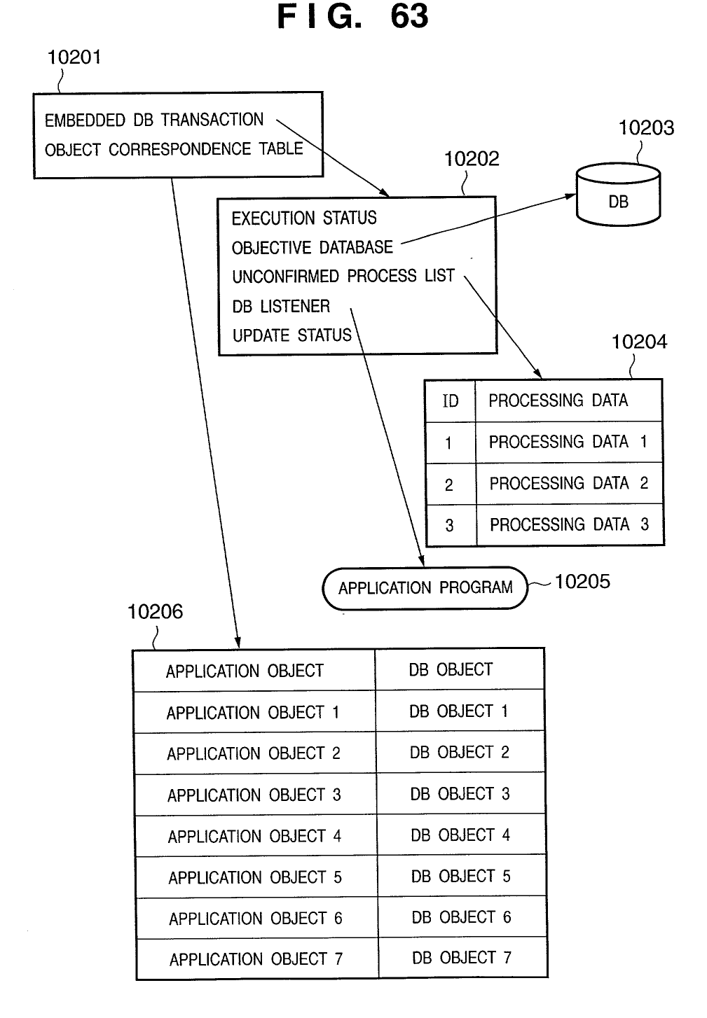

Internal data of a hierarchical DB transaction will be explained below using FIG. 63.

FIG. 63 shows internal data of a hierarchical DB transaction of the third embodiment.

The hierarchical DB transaction has information 10202 of an embedded DB transaction which is installed actually, and internal data of an object correspondence table 10206 for storing relationships between application objects to be processed and DB objects after generation of the transaction, as indicated by 10201.

The information 10202 of the embedded DB transaction has execution status indicating if execution of the transaction is in progress, information 10203 of a database as a transaction target, a list 10204 of unconfirmed processes which are executed during execution of the transaction, a DB listener having information of a notify destination (e.g., an application program 10205) of a change in database, and update status for holding status indicating a change in database.

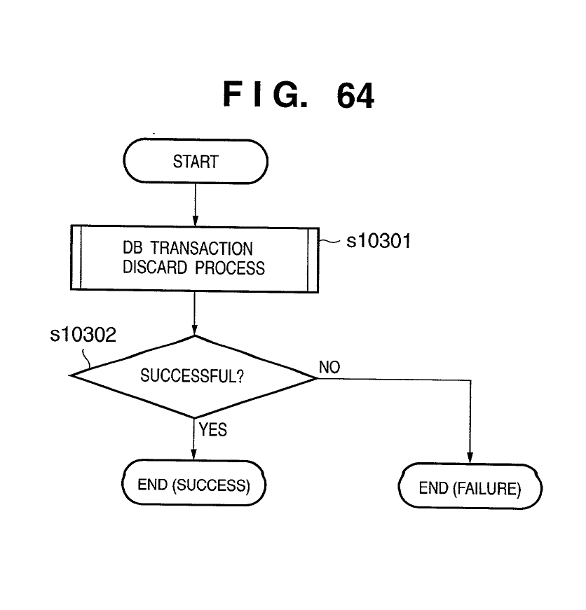

Details of the transaction discard process in step s409 in the third embodiment will be described below using FIG. 64.

FIG. 64 is a flow chart showing details of the transaction discard process in step s409 in the third embodiment.

When the transaction discard process is launched, a DB transaction discard process is executed in step s10301 to discard a corresponding DB transaction.

It is then checked in step s10302 if the discard process of the DB transaction has succeeded as a result of the DB transaction discard process. If the discard process of the DB transaction has succeeded (YES in step s10302), the processing ends as “success”. On the other hand, if the discard process of the DB transaction has failed (NO in step s10302), the processing ends as “failure”.

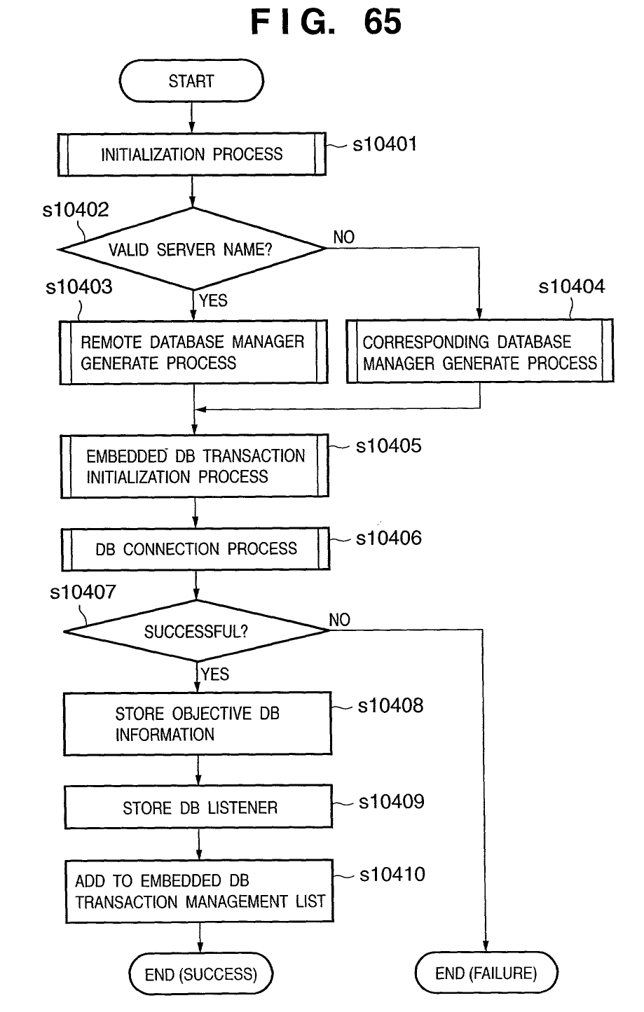

Details of the DB transaction generate process in step s603 in the third embodiment will be described below using FIG. 65.

FIG. 65 is a flow chart showing details of the DB transaction generate process in the third embodiment.

When the DB transaction generate process is launched, an initialization process is executed in step s10401 to initialize internal data of the hierarchical DB transaction that has been explained using FIG. 63. It is then checked in step s10402 if the server name designated on the transaction generation window described using FIG. 46 is valid. If the server name is valid (YES in step s10402), the flow advances to step s10403 to execute a remote database manager generate process, thus generating a database manager used to establish connection to a server designated by the server name. On the other hand, if the server name is not valid (NO in step s10402), the flow advances to step s10404 to execute a corresponding database manager generate process, thus generating a database manager of a database designated on the transaction generation window described using FIG. 45.

An embedded DB transaction initialization process provided by the generated database manager is executed in step s10405 to initialize internal data of the embedded DB transaction described using FIG. 63.

In step s10406, a DB connection process provided by the generated database manager is executed to establish connection to a database under the designated condition.

It is checked in step s10407 if connection to the database has succeeded as a result of the DB connection process. If connection to the database has failed (NO in step s10407), the processing ends as “failure”. On the other hand, if connection to the database has succeeded (YES in step s10407), the flow advances to step s10408.

In step s10408, information that pertains to connection is stored in the internal data of the embedded DB transaction. In step s10409, a given database change notify destination is stored in the DB listener. In step s10410, the generated embedded DB transaction is stored in the embedded DB transaction management list, and the processing ends as “success”.

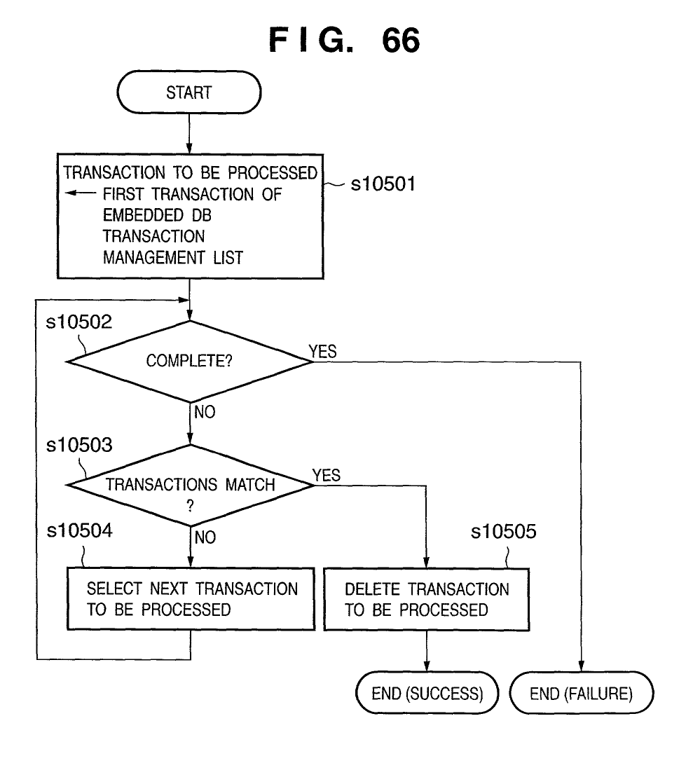

The DB transaction discard process in step s10301 will be described below using FIG. 66.

FIG. 66 is a flow chart showing details of the DB transaction discard process in step s10301 in the third embodiment.

When the DB transaction discard process is launched, the first transaction in the embedded DB transaction management list is set as a transaction to be processed in step S10501, and processes are repeated for all embedded DB transactions to be processed in the subsequent steps.

It is then checked in step s10502 if the processes for all the embedded DB transactions are complete. If the processes for all the embedded DB transactions are complete (YES in step s10502), the processing ends as “failure”. On the other hand, if the processes for all the embedded DB transactions to be processed are not complete (NO in step s10502), the flow advances to step s10503.

It is checked in step s10503 if the embedded DB transaction to be processed matches an embedded DB transaction to be discarded. If the embedded DB transaction to be processed matches an embedded DB transaction to be discarded (YES in step s10503), the flow advances to step s10505 to delete the embedded DB transaction to be processed from the embedded DB transaction management list, and the processing ends as “success”.

On the other hand, if it is determined in step s10503 that the embedded DB transaction to be processed does not match an embedded DB transaction to be discarded (NO in step s10503), the flow advances to step s10504 to select the next embedded DB transaction as the transaction to be processed, and the flow returns to step s10502 to repeat the above process.

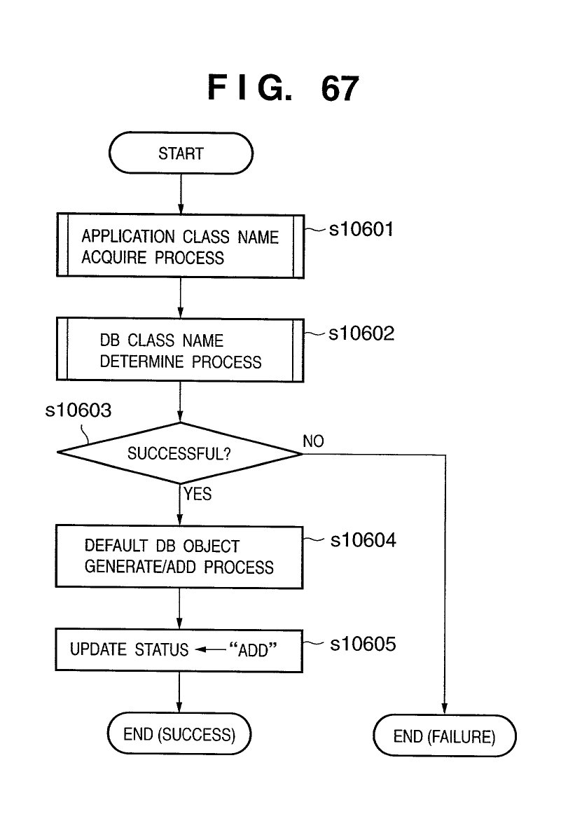

Details of the DB object generate/add process in step s6002 in the third embodiment will be described below using FIG. 67.

FIG. 67 is a flow chart showing details of the DB object generate/add process in step s6002 in the third embodiment.

When the DB object generate/add process is launched, an application class name acquire process is executed in step s10601 to acquire an application class name of a given application object. In step s10602, a DB class name determine process is executed to determine a database class name in a database corresponding to the application class name.

It is checked in step s10603 if determination of the database class name has succeeded as a result of the DB class name determine process. If determination of the database class name has failed (NO in step s10603), the processing ends as “failure”.

On the other hand, if determination of the database class name has succeeded (YES in step s10603), the flow advances to step s10604.

In step s10604, a default database object corresponding to the database class is generated. In step s10605, an “add” flag indicating that data has been added is appended to upstate status, and the processing ends as “success”.

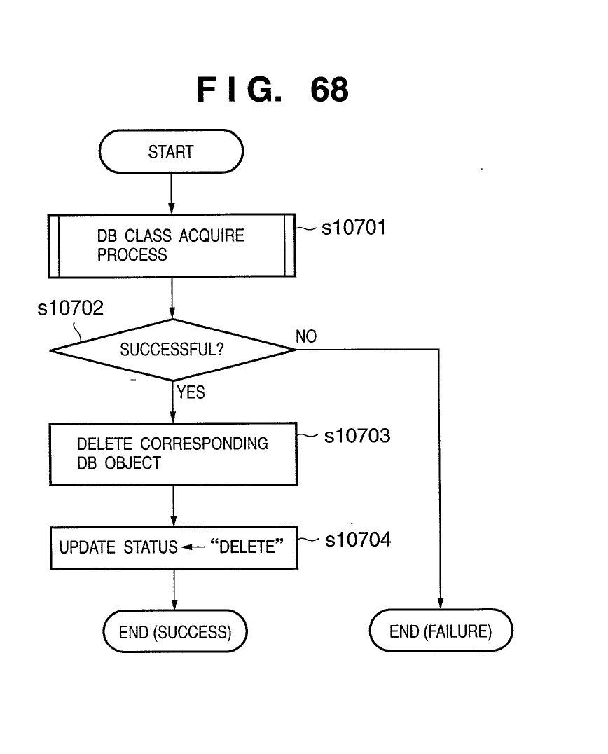

Details of the DB object delete process in step s6204 will be described below using FIG. 68.

FIG. 68 is a flow chart showing details of the DB object delete process of the third embodiment.

When the DB object delete process is launched, a DB class acquire process is executed in step s10701 to acquire a database class corresponding a given database object.

It is checked in step s10702 if acquisition of the database class has succeeded as a result of the DB class acquire process. If acquisition of the database class has failed (NO in step s10702), the processing ends as “failure”. On the other hand, if acquisition of the database class has succeeded (YES in step s10702), the flow advances to step s10703.

In step s10703, the given database object is deleted using a service of the database class. A “delete” flag indicating that data has been deleted is appended to update status in step s10704, and the processing ends as “success”.

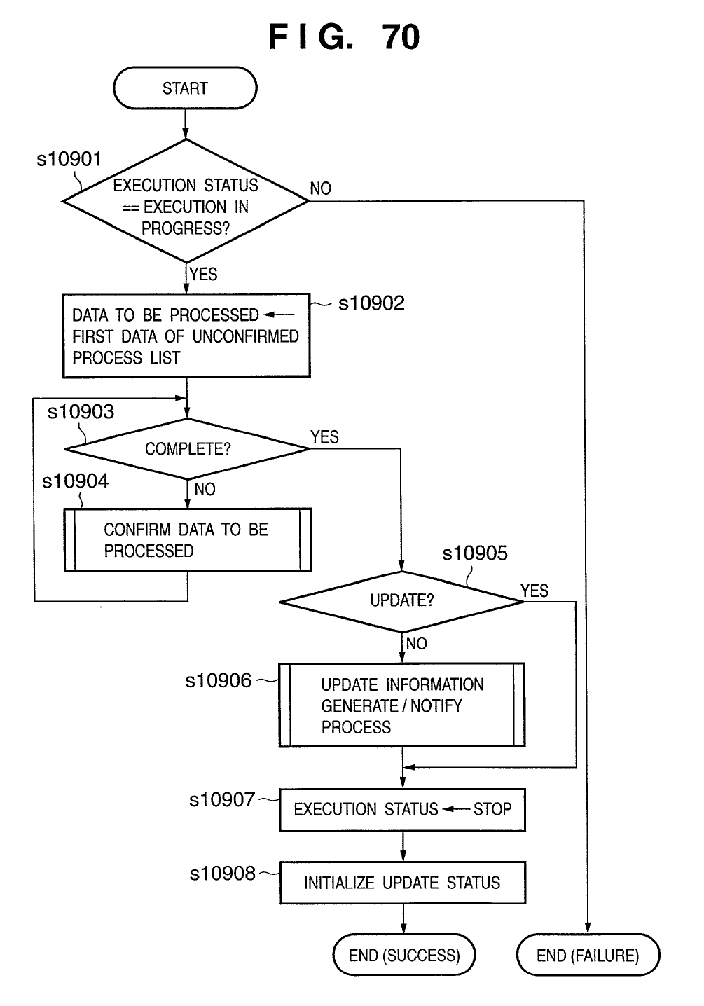

Details of the DB object value set process in steps s5907 and s6003 in the third embodiment of the object add process in FIG. 31 and the object update process in FIG. 32 will be described below using FIG. 69.

FIG. 69 is a flow chart showing details of the DB object value set process in steps s5907 and s6003 of the third embodiment.

When the DB object value set process is launched, an all writable field name acquire process is executed in step s10801 to acquire all writable field names with reference to the field definitions of a given application object.

It is checked in step s10802 if acquisition of the field names has succeeded as a result of the all writable field name acquire process. If acquisition of the field names has failed (NO in step s10802), the processing ends as “failure”. On the other hand, if acquisition of the field names has succeeded (YES in step s10802), the flow advances to step s10803.

In step s10803, the first field in a list of all the acquired writable field names is set to be a field to be processed, and processes are repeated for all fields to be processed in the subsequent steps.

It is checked in step s10804 if the processes for all the fields to be processed are complete. If the processes for all the fields to be processed are complete (YES in step s10804), the flow advances to step s10811 to append an “update” flag indicating that data has been updated to update status, and the processing ends as “success”. On the other hand, if the processes for all the fields to be processed are not complete (NO in step s10804), the flow advances to step s10805.

It is checked in step s10805 if the field to be processed is an array. If the field is not an array (NO in step s10805), the flow advances to step s10806.

In step s10806, a field value acquire process is executed to acquire a value corresponding to the field name of the field to be processed of the given application object. In step s10807, a DB field value set process is executed to store the value in the corresponding field of the database object. In step s10808, the next field is selected as the field to be processed, and the flow returns to step s10804 to repeat the process.

On the other hand, if it is determined in step s10805 that the field to be processed is an array (YES in step s10805), the flow advances to step s10809.

In step s10809, an array field value acquire process is executed to acquire a value corresponding to the field name of the field to be processed of the given application object. In step s10810, a DB array field value set process is executed to store the value in the corresponding field of the database object. In step s10808, the next field is selected as the field to be processed, and the flow returns to step s10804 to repeat the process.

Details of the DB transaction confirm process in steps s1804, s1904, s2004, and s2104 in the third embodiment of the all object acquisition confirm process in FIG. 18, the object addition confirm process in FIG. 19, the object update confirm process in FIG. 20, and the object deletion confirm process in FIG. 21 will be described below using FIG. 70.

FIG. 70 is a flow chart showing details of the DB transaction confirm process in steps s1804, s1904, s2004, and s2104 of the third embodiment.

When the DB transaction confirm process is launched, it is checked in step s10901 with reference to the execution status of the internal data of the hierarchical DB transaction described using FIG. 63 if the execution status is “execution in progress”. If the execution status is not “execution in progress” (NO in step s10901), the processing ends as “failure”. On the other hand, if the execution status is “execution in progress” (YES in step s10901), the flow advances to step s10902.

In step s10902, data to be processed is set at the head of the unconfirmed process list, and processes are repeated for all data to be processed in the subsequent steps.

It is checked in step s10903 if the processes for all data to be processed are complete. If the processes for all data to be processed are not complete (NO in step s10903), the flow advances to step s10904 to execute a data confirm process to confirm processing contents as the data to be processed in the database, and the flow returns to step s10903.

On the other hand, if the processes for all data to be processed are complete (YES in step s10903), the flow advances to step s10905.

It is checked in step s10905 with reference to the update status if the data to be processed has been updated. If the data to be processed has been updated (YES in step s10905), the flow jumps to step s10907. On the other hand, if the data to be processed has not been updated (NO in step s10905), the flow advances to step s10906.

In step s10906, an update information generate/notify process is executed to send update information to the corresponding database.

After that, the execution status is changed to “stop” in step s10907. In step s10908, the update status is initialized, and the processing ends as success.

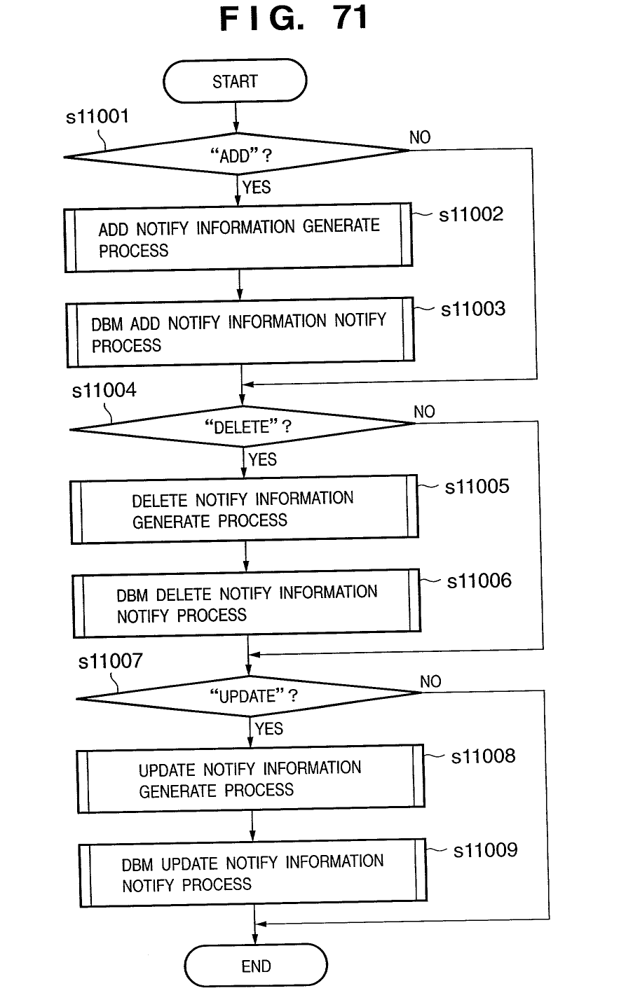

Details of the update information generate/notify process in step s10906 will be described below using FIG. 71.

FIG. 71 is a flow chart showing details of the update information generate/notify process in step s10906 of the third embodiment.

When the update information generate/notify process is launched, it is checked in step s11001 with reference to the update status of the internal data of the hierarchical DB transaction explained using FIG. 63 if the update status is “add”. If the upstate status is not “add” (NO in step s11001), the flow jumps to step s11004. On the other hand, the upstate status is “add” (YES in step s11001), the flow advances to step s11002.

In step s11002, an add notify information generate process is executed to generate add notify information to be sent. In step s11003, a DBM add notify information notify process is executed to send the generated add notify information to the corresponding database.

It is checked in step s11004 with reference to the update status of the internal data of the hierarchical DB transaction explained using FIG. 63 if the update status is “delete”. If the update status is not “delete” (NO in step s11004), the flow jumps to step s11007. On the other hand, if the update status is “delete” (YES in step s11004), the flow advances to step s11005.

In step s11005, a delete notify information generate process is executed to generate delete notify information to be sent. In step s11006, a DBM delete notify information notify process is executed to send the generated delete notify information to the corresponding database.

It is checked in step s11007 with reference to the update status of the internal data of the hierarchical DB transaction explained using FIG. 63 if the update status is “update”. If the update status is not “update” (NO in step s11007), the processing ends. On the other hand, if the update status is “update” (YES in step s11007), the flow advances to step s11008.

In step s11008, an update notify information generate process is executed to generate update notify information to be sent. In step s11009, a DBM update notify information notify process is executed to send the generated update notify information to the corresponding database.

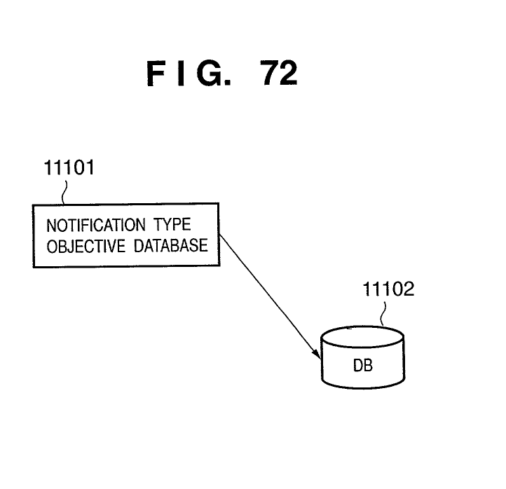

Notify information generated by the update notify information generate process in step s11008 will be explained below using FIG. 72.

FIG. 72 shows an example of notify information generated by the update notify information generate process in step s11008 of the third embodiment.

Notify information 11101 has a notify type indicating the type of notify information, and-an objective database 11102 indicating the corresponding database.

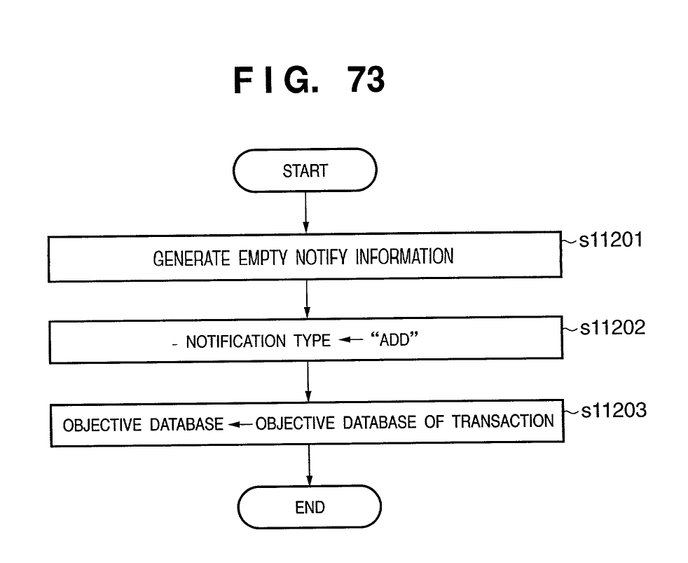

Details of the add notify information generate process in step s11002 will be described below using FIG. 73.

FIG. 73 is a flow chart showing details of the add notify information generate process in step s11002 of the third embodiment.

When the add notify information generate process is launched, the aforementioned notify information is generated in step s11201. In step s11202, an “add” flag indicating that data has been added to the database is set in the notify type of the notify information. In step s11203, an objective database of the transaction itself is set in the objective database of the notify information, thus ending the processing.

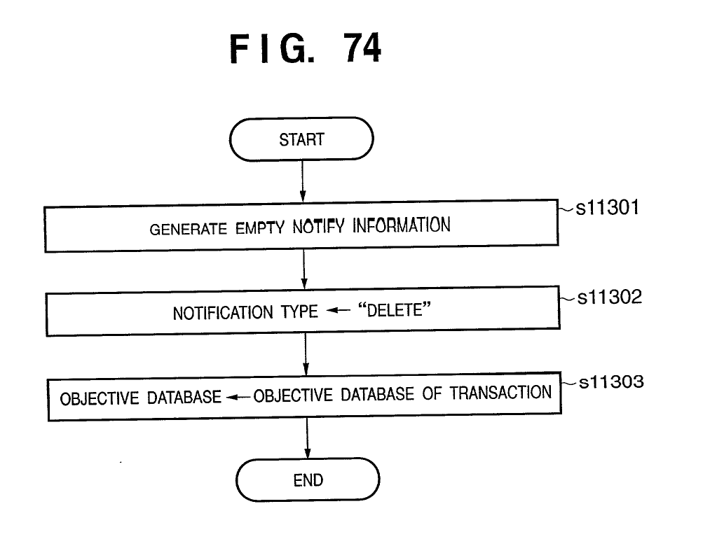

Details of the delete notify information generate process in step s11005 will be described below using FIG. 74.

FIG. 74 is a flow chart showing details of the delete notify information generate process in step s11005 of the third embodiment.

When the delete notify information generate process is launched, the aforementioned notify information is generated in step s11301. In step s11302, a “delete” flag indicating that data has been deleted from the database is set in the notify type of the notify information. In step s11303, an objective database of the transaction itself is set in the objective database of the notify information, thus ending the processing.

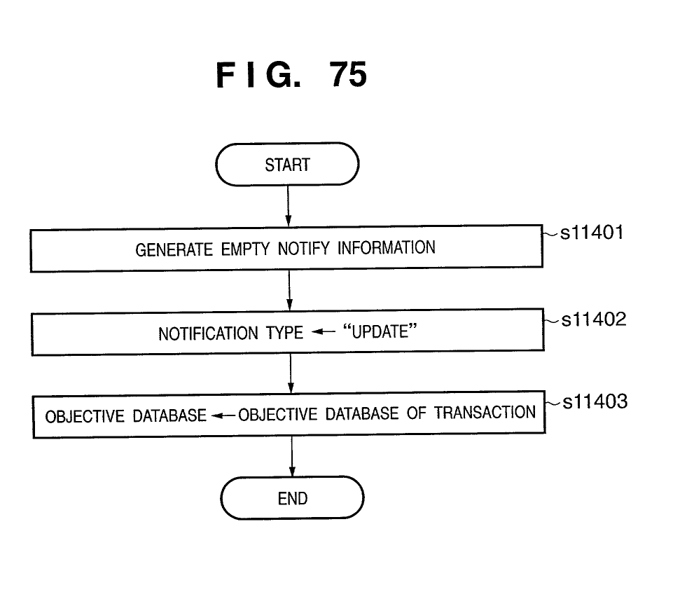

Details of the update notify information generate process in step s11008 will be described below using FIG. 75.

FIG. 75 is a flow chart showing details of the update notify information generate process in step s11008 of the third embodiment.

When the update notify information generate process is launched, the aforementioned notify information is generated in step s11401. In step s11402, an “update” flag indicating that data of the database has been updated is set in the notify type of the notify information. In step s11403, an objective database of the transaction itself is set in the objective database of the notify information, thus ending the processing.

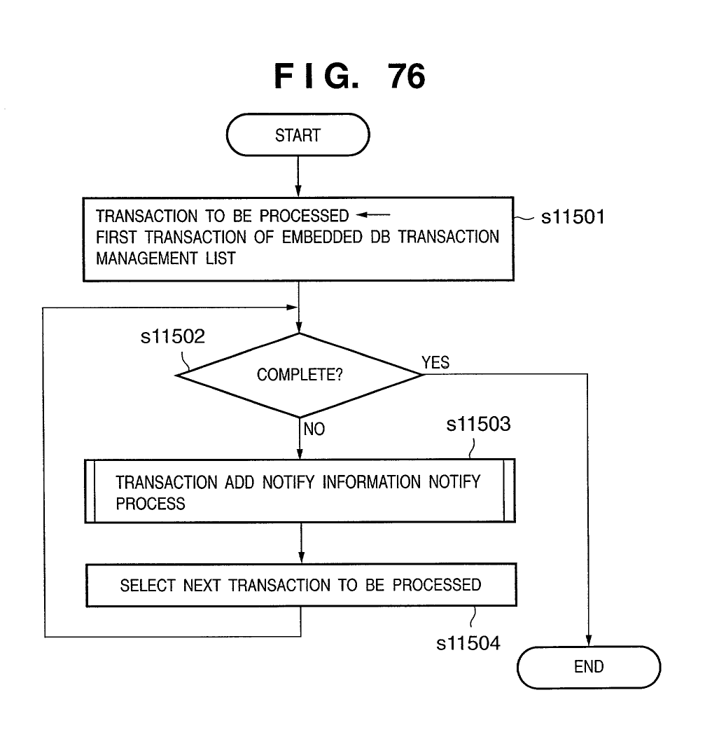

The DBM add notify information notify process in step s11003 will be described below using FIG. 76.

FIG. 76 is a flow chart showing details of the DBM add notify information notify process in step s11003 of the third embodiment.

When the DBM add notify information notify process is launched, the first transaction in the embedded DB transaction management list of the DBM itself is set as a transaction to be processed in step s11501, and processes are repeated for all transactions to be processed in the subsequent steps.

It is checked in step s11502 if the processes for all the transactions to be processed are complete. If the processes for all the transactions to be processed are complete (YES in step S11502), the processing ends. On the other hand, if the processes for all the transactions to be processed are not complete (NO in step s11502), the flow advances to step s11503.

In step s11503, a transaction add notify information notify process provided by the transaction to be processed is executed to send the notify information to the corresponding database. In step s11504, the next transaction is selected as the transaction to be processed, and the flow returns to step s11502 to repeat the process.

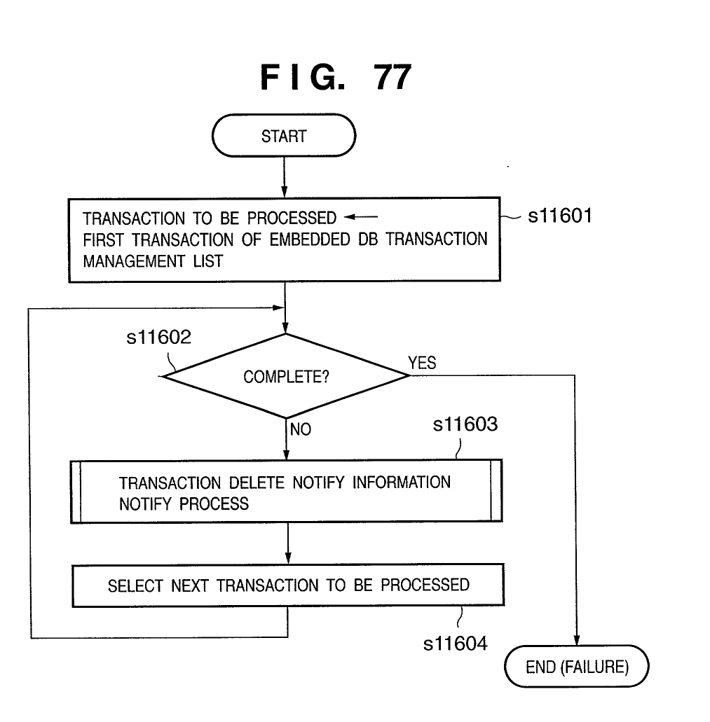

The DBM delete notify information notify process in step s11006 will be described below using FIG. 77.

FIG. 77 is a flow chart showing details of the DBM delete notify information notify process in step s11006 of the third embodiment.

When the DBM delete notify information notify process is launched, the first transaction in the embedded DB transaction management list of the DBM itself is set as a transaction to be processed in step s11601, and processes are repeated for all transactions to be processed in the subsequent steps.

It is checked in step s11602 if the processes for all the transactions to be processed are complete. If the processes for all the transactions to be processed are complete (YES in step S11602), the processing ends. On the other hand, if the processes for all the transactions to be processed are not complete (NO in step s11602), the flow advances to step s11603.

In step s11603, a transaction delete notify information notify process provided by the transaction to be processed is executed to send the notify information to the corresponding database. In step s11604, the next transaction is selected as the transaction to be processed, and the flow returns to step s11602 to repeat the process.

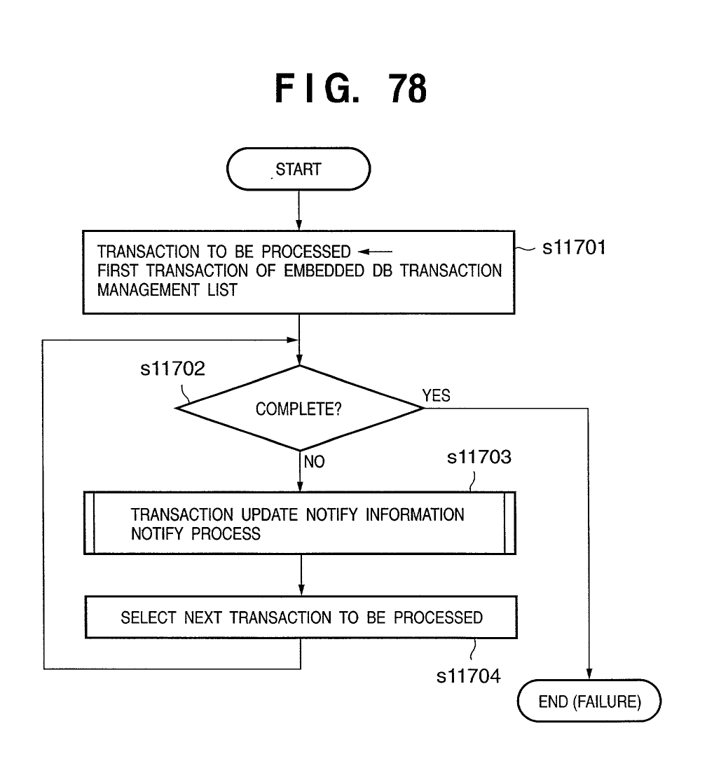

The DBM update notify information notify process in step s11009 will be described below using FIG. 78.

FIG. 78 is a flow chart showing details of the DBM update notify information notify process in step s11009 of the third embodiment.

When the DBM update notify information notify process is launched, the first transaction in the embedded DB transaction management list of the DBM itself is set as a transaction to be processed in step s11701, and processes are repeated for all transactions to be processed in the subsequent steps.

It is checked in step s11702 if the processes for all the transactions to be processed are complete. If the processes for all the transactions to be processed are complete (YES in step S11702), the processing ends. On the other hand, if the processes for all the transactions to be processed are not complete (NO in step s11702), the flow advances to step s11703.

In step s11703, a transaction update notify information notify process provided by the transaction to be processed is executed to send the notify information to the corresponding database. In step s11704, the next transaction is selected as the transaction to be processed, and the flow returns to step s11702 to repeat the process.

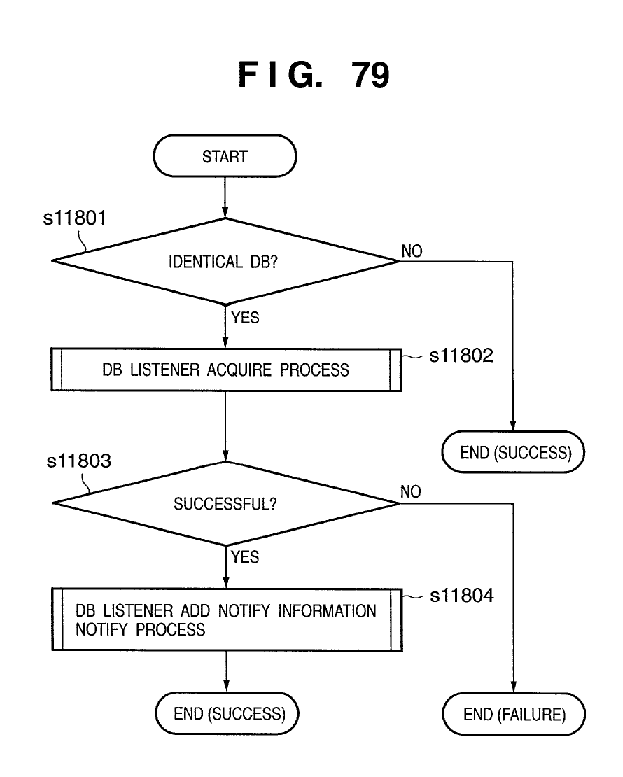

Details of the transaction add notify information notify process in step s11503 will be described below using FIG. 79.

FIG. 79 is a flow chart showing details of the transaction add notify information notify process in step s11503 of the third embodiment.

When the transaction add notify information notify process is launched, it is checked in step s11801 if the objective database of the notify information matches that of the transaction itself. If the objective database of the notify information does not match that of the transaction itself (NO in step s11801), since the information need not be sent, the processing ends as “success”. On the other hand, if the objective database of the notify information matches that of the transaction itself (YES in step s1801), the flow advances to step s11802.

In step s11802, a DB listener acquire process is executed to acquire the previously registered database change notify destination.

It is checked in step s11803 if acquisition of the database change notify destination has succeeded. If acquisition of the database change notify destination has failed (NO in step s11803), since the information cannot be sent, the processing ends as “failure”. On the other hand, if acquisition of the database change notify destination has succeeded (YES in step s11803), the flow advances to step s11804.

In step s11804, a DB listener add notify information notify process provided by the database change notify destination is executed to send the notify information to the corresponding database, and the processing ends as “success”.

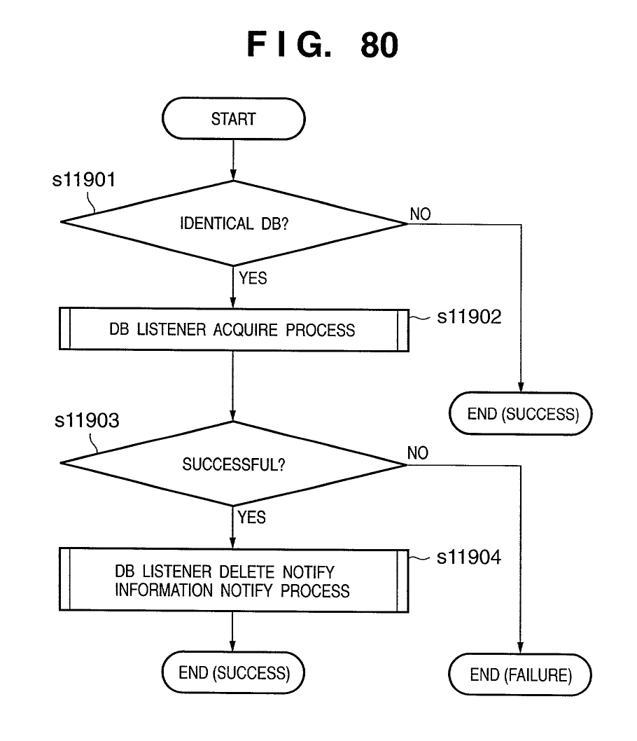

Details of the transaction delete notify information notify process in step s11603 will be described below using FIG. 80.

FIG. 80 is a flow chart showing details of the transaction delete notify information notify process in step s11603 of the third embodiment.

When the transaction delete notify information notify process is launched, it is checked in step s11901 if the objective database of the notify information matches that of the transaction itself. If the objective database of the notify information does not match that of the transaction itself (NO in step s11901), since the information need not be sent, the processing ends as “success”. On the other hand, if the objective database of the notify information matches that of the transaction itself (YES in step s11901), the flow advances to step s11902.

In step s11902, a DB listener acquire process is executed to acquire the previously registered database change notify destination.

It is checked in step s11903 if acquisition of the database change notify destination has succeeded. If acquisition of the database change notify destination has failed (NO in step s11903), since the information cannot be sent, the processing ends as “failure”. On the other hand, if acquisition of the database change notify destination has succeeded (YES in step s11903), the flow advances to step s11904.

In step s11904, a DB listener delete notify information notify process provided by the database change notify destination is executed to send the notify information to the corresponding database, and the processing ends as “success”.

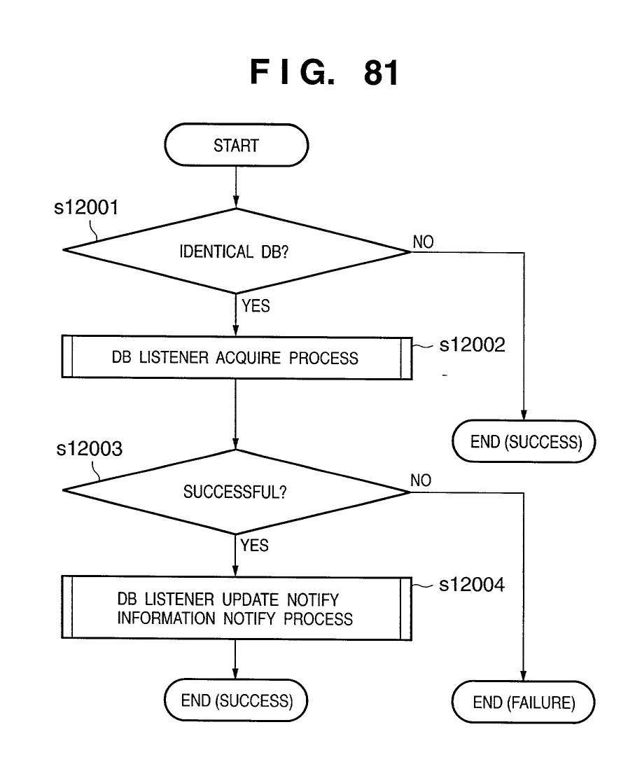

Details of the transaction update notify information notify process in step s11703 will be described below using FIG. 81.

FIG. 81 is a flow chart showing details of the transaction update notify information notify process in step s11703 of the third embodiment.

When the transaction update notify information notify process is launched, it is checked in step s12001 if the objective database of the notify information matches that of the transaction itself. If the objective database of the notify information does not match that of the transaction itself (NO in step s12001), since the information need not be sent, the processing ends as “success”. On the other hand, if the objective database of the notify information matches that of the transaction itself (YES in step s12001), the flow advances to step s12002.

In step s12002, a DB listener acquire process is executed to acquire the previously registered database change notify destination. It is checked in step s12003 if acquisition of the database change notify destination has succeeded. If acquisition of the database change notify destination has failed (NO in step s12003), since the information cannot be sent, the processing ends as “failure”. On the other hand, if acquisition of the database change notify destination has succeeded (YES in step s12003), the flow advances to step s12004.

In step s12004, a DB listener update notify information notify process provided by the database change notify destination is executed to send the notify information to the corresponding database, and the processing ends as “success”.

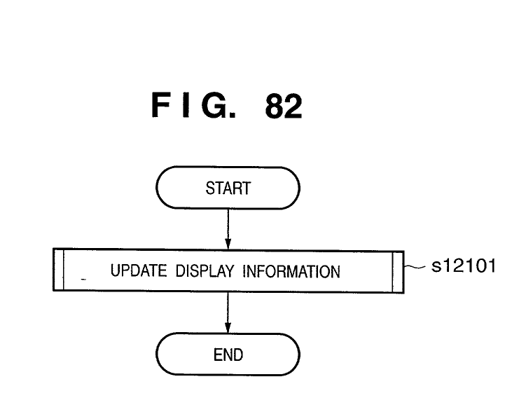

Details of the DB listener add notify information notify process in step s11804 will be described below using FIG. 82.

FIG. 82 is a flow chart showing details of the DB listener add notify information notify process in step s11804 of the third embodiment.

When the DB listener add notify information notify process is launched, a display information update process is executed in step s12101 to update the currently displayed information in correspondence with the notify information and re-map new information.

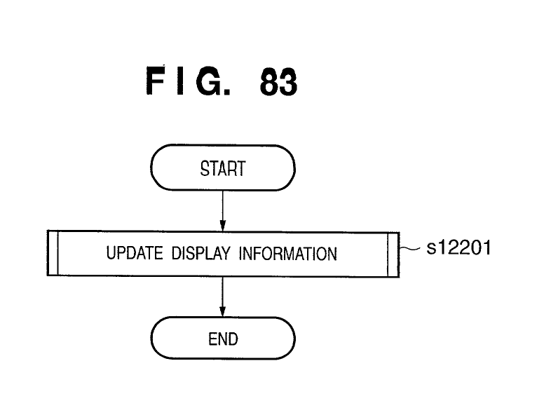

Details of the DB listener delete notify information notify process in step s11904 will be described below using FIG. 83.

FIG. 83 is a flow chart showing details of the DB listener delete notify information notify process in step s11904 of the third embodiment.

When the DB listener delete notify information notify process is launched, a display information update process is executed in step s12201 to update the currently displayed information in correspondence with the notify information and re-map new information.

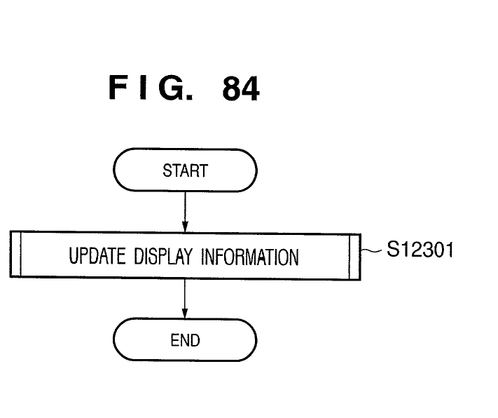

Details of the DB listener update notify information notify process in step s12004 will be described below using FIG. 84.

FIG. 84 is a flow chart showing details of the DB listener update notify information notify process in step s12004 of the third embodiment.

When the DB listener update notify information notify process is launched, a display information update process is executed in step s12301 to update the currently displayed information in correspondence with the notify information and re-map new information.

As described above, according to the third embodiment, a notify destination which is to be notified of a change in database is registered in correspondence with a database that stores permanent data, thus managing a series of a plurality of database transactions for the database. When a database that a transaction itself handles has changed, a management destination which manages the database transaction is notified of that change. When the management destination notifies the change in database, a plurality of database transactions managed by the database itself are notified of the change contents. In addition, the corresponding registered notify destination is notified of the change contents.

In this manner, an associated application program is notified of the change in database, and can execute an appropriate process. Also, an application can detect a change in objective database without any limitations such as denial of access to data during access of another application program, and can execute an appropriate process such as a re-map process while avoiding inadvertent errors. In this way, appropriate processes can be implemented.

<Fourth Embodiment>

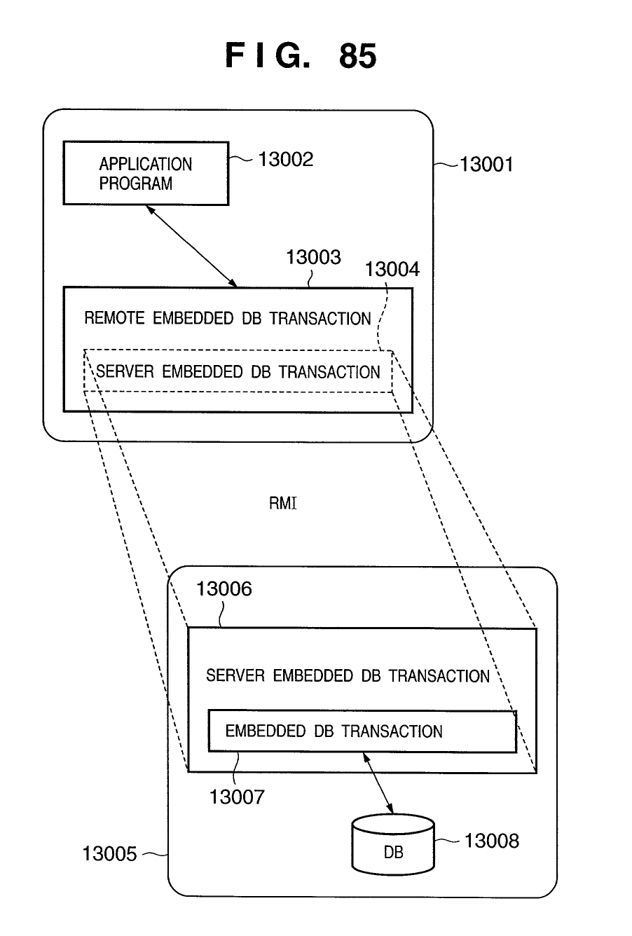

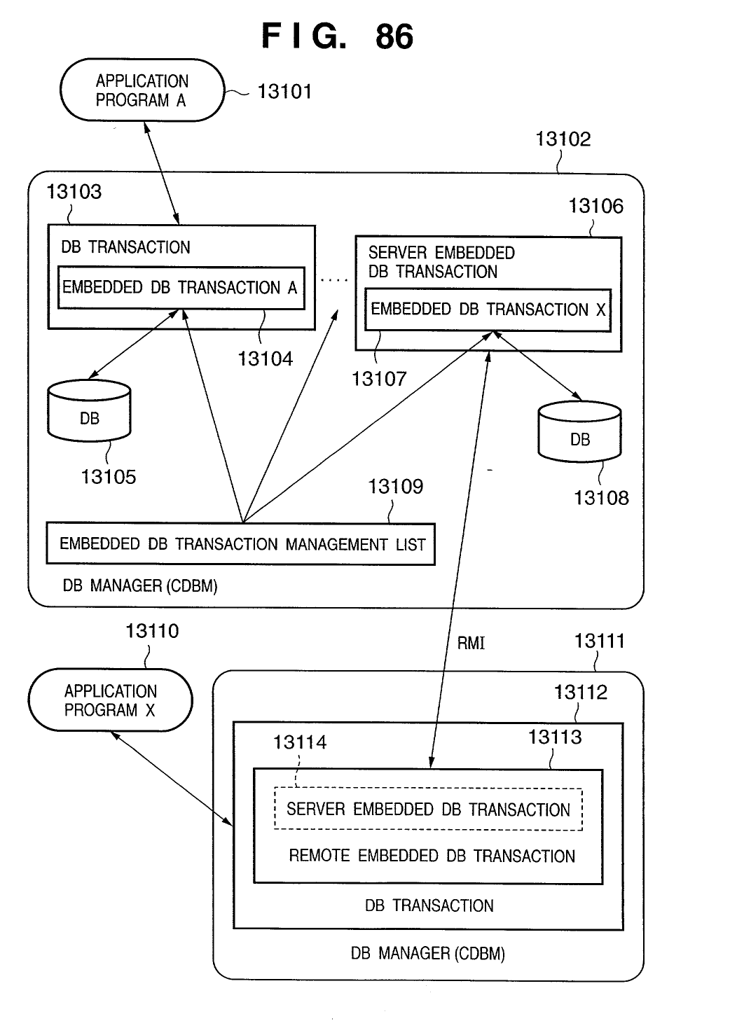

FIG. 85 shows the functional arrangement of an information processing apparatus of the fourth embodiment.

FIG. 85 illustrates a server & remote arrangement upon accessing databases present on different devices. An arrangement upon accessing a database 13008 which is present on a device 13005 different from an application program 13002 will be explained.

An embedded DB transaction 13007 that accesses the database 13008 which is present on the device 13005 cannot directly provide any service to the application program 13002 since it does not have any inter-device communication means. Hence, by expanding the embedded DB transaction 13007 by a server embedded DB transaction 13006 having inter-device communication means, a service can be provided to the application program 13002. (In the state in FIG. 85, a server embedded DB transaction 13004 uses the server embedded DB transaction 13006 on the device 13001.)

However, in order to use the server embedded DB transaction 13004 as it is, the application program 13002 must be implemented to be different from a local database, resulting in a complicated arrangement. Hence, by expanding the server embedded DB transaction 13004 by a remote embedded DB transaction 13003, the application program 13002 can access in the same manner as a local database.

A hierarchical DB transaction structure of the fourth embodiment will be described below using FIG. 86.

FIG. 86 shows a hierarchical DB transaction structure of the fourth embodiment.

A DB manager 13102 of the fourth embodiment generates/discards a DB transaction 13103 that processes a series of transactions with a database 13105 in response to a request from application program A (13101). Note that the DB transaction 13103 is formed by an application interface layer that exchanges information with application program A (13101), and embedded DB transaction A (13104) as a database interface layer dependent on implementations of an individual database.

A DB manager 13111 generates a DB transaction 13112 in response to a request from application program X (13110) executed by a device different from the above device. Note that the DB transaction 13112 has remote embedded DB transaction X (13113), which hides exchanges with server embedded DB transaction X (13106) obtained by expanding inter-device communication means, in an embedded DB transaction X (13107) which processes a series of transactions with the database 13108.

The generated embedded DB transactions are stored in and managed by an embedded DB transaction management list 13109. However, since the server embedded DB transaction 13106 and remote embedded DB transaction 13113 are obtained by merely expanding inter-device communication means, they cannot be stored in and managed by the embedded DB transaction management list 13109.

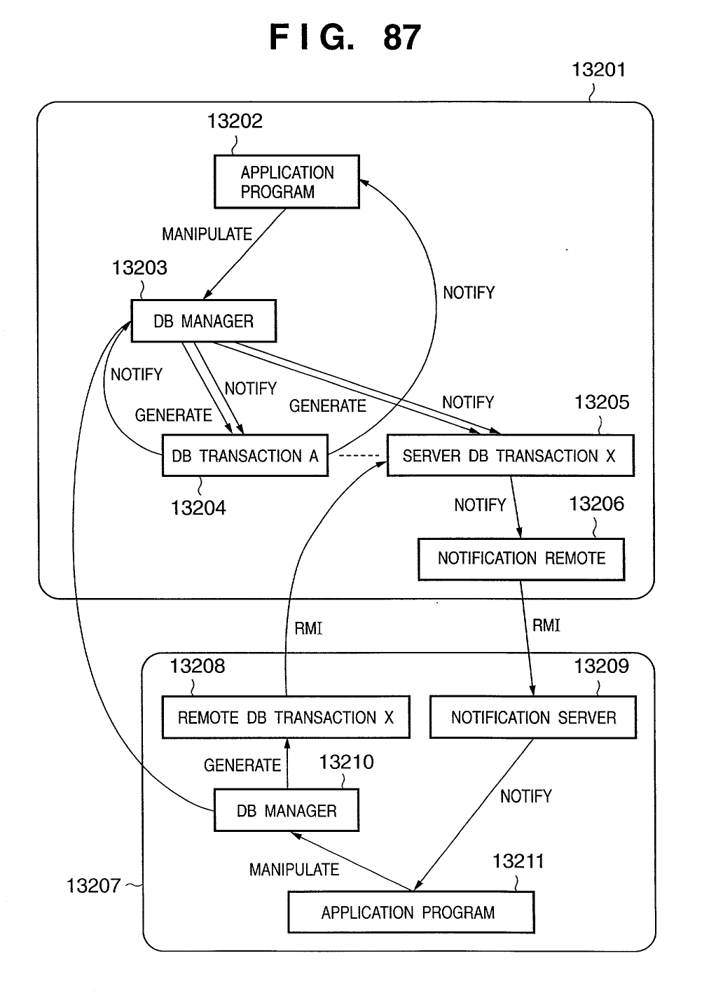

The flow of notify information in the server & remote arrangement upon, e.g., a change in database in the fourth embodiment will be described below using FIG. 87.

FIG. 87 shows the flow of notify information in the server & remote arrangement upon, e.g., a change in database in the fourth embodiment.

Referring to FIG. 87, DB transaction A (13204) is generated using a DB manager 13203 which is present on the same device 13201 as an application program 13202.

Also, remote DB transaction X (13208) and a notification server 13209 are generated using a DB manager 13210 which is present on the same device 13207 as an application program 13211. In order to make inter-device communications, server DB transaction X (13205) and a notification remote 13206 are generated using the DB manager 13203 which is present on the different device 13201.

Upon a change that has taken place as a result of the process done by DB transaction A (13204), notify information is sent to the DB manager 13203. The DB manager 13203 sends the received notify information to DB transaction A (13204) and server DB transaction X (13205) under its management. Upon receiving the notify information, DB transaction A (13204) sends notify information to the application program 13202.

On the other hand, server DB transaction X (13205) makes inter-device communications via the notification remote 13206 to send notify information to the application program 13211 via the notification server 13209 on the different device 13207.

With this flow, notify information can be sent to the application program present on the different device, and the application programs which received the notify information execute appropriate processes such as re-display processes of database information and the like according to their decisions.

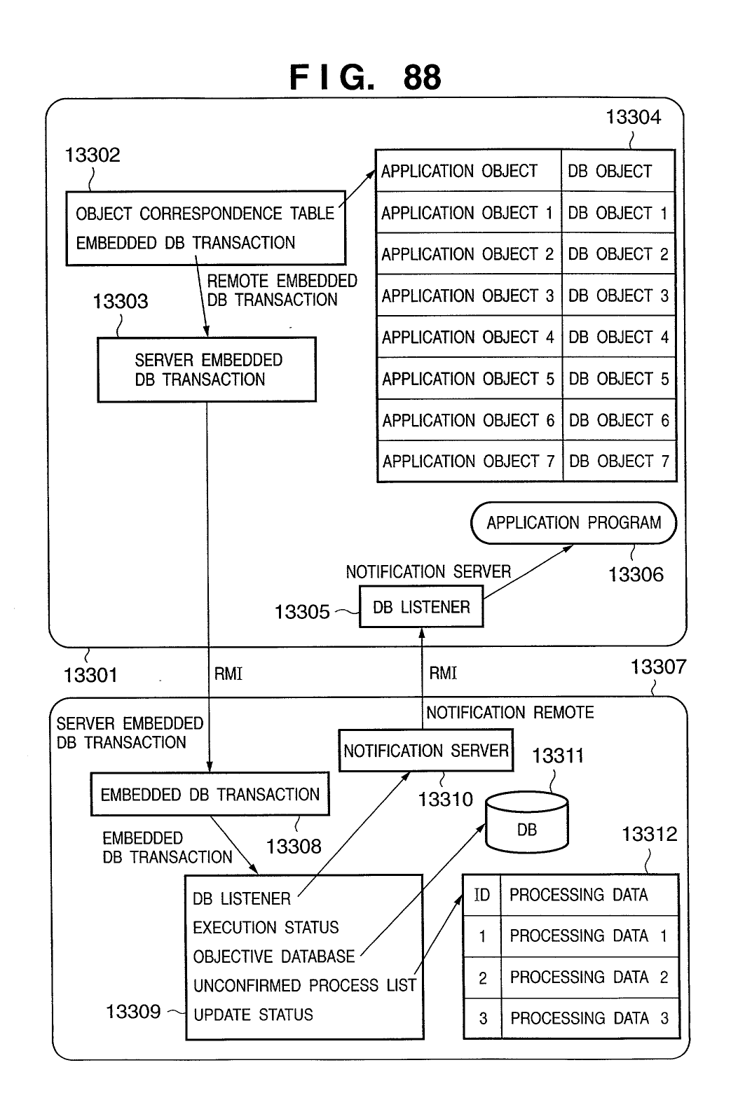

Internal data of the hierarchical DB transaction of the fourth embodiment will be described below using FIG. 88.

FIG. 88 shows internal data of the hierarchical DB transaction of the fourth embodiment.

The hierarchical DB transaction has information 13303 of an embedded DB transaction which is installed actually, and internal data of an object correspondence data table 13304 for storing relationships between application objects to be processed and DB objects after generation of the transaction, as indicated by 13302.

In FIG. 88, the embedded DB transaction 13303 serves as a remote embedded DB transaction via which an application program 13306 accesses a database 13311 present on a device 13307 different from a device 13301 on which execution of the transaction 13303 is in progress. More specifically, internal data of the remote embedded DB transaction includes a server embedded DB transaction 13308 of the different device 13307.

On the other hand, the server embedded DB transaction 13308 present on the device 13307 has an embedded DB transaction 13309 used to actually access the database 13311.

The embedded DB transaction information 13309 has a DB listener having information of a destination which is notified of a change in database, execution status indicating if execution of transaction is in progress, information 13311 of a database as a transaction target, a list 13312 of unconfirmed processes which are done during execution of the transaction, and update status for holding status indicating a change in database.

An entity of an actual DB listener indicates a notification remote 13310 for directly implementing inter-device communications without the intervention of an application. Furthermore, when the notification remote 13310 communicates with a notification server 13305, notify information can be sent to the application program 13306 present on the different device.

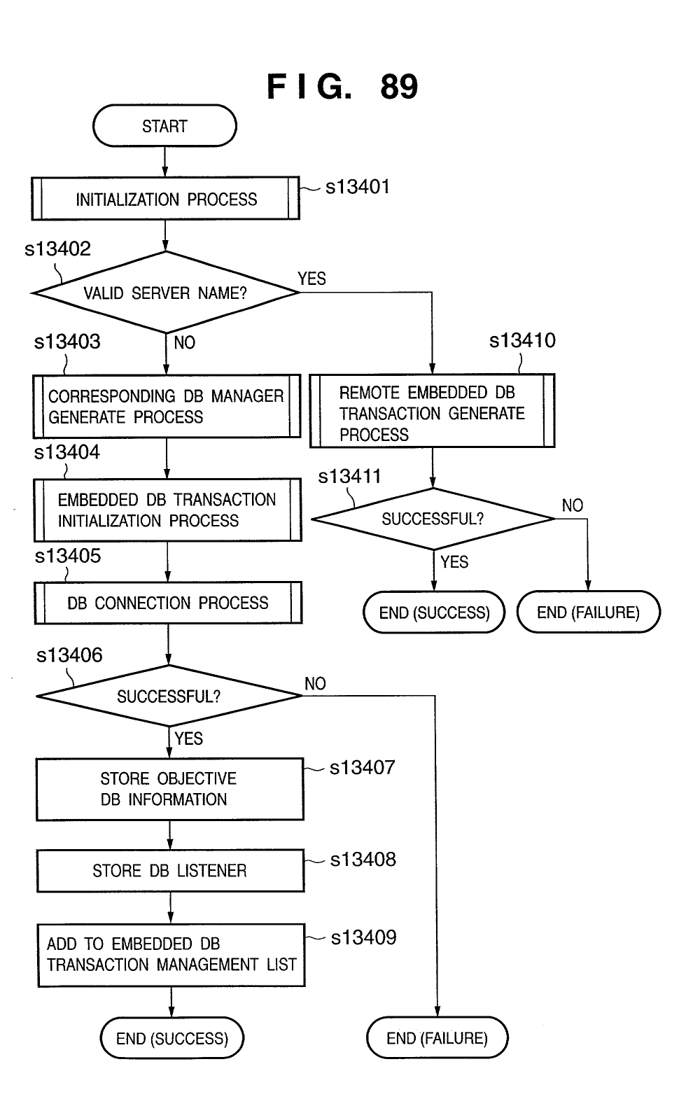

Details of the DB transaction generate process in step s603 in the fourth embodiment will be described below using FIG. 89.

FIG. 85 is a flow chart showing details of the DB transaction generate process in step s603 of the fourth embodiment.

When the DB transaction generate process is launched, an initialization process is executed in step s13401 to initialize internal data of the hierarchical DB transaction described using FIG. 88. It is then checked in step s13402 if the server name designated on the transaction generation window described using FIG. 46 is valid. If the server name is valid (YES in step s13402), the flow advances to step s13410.

In step s13410, a remote DB transaction generate process is executed to generate a DB transaction used to establish connection to a server designated by the server name. It is checked in step s13411 if generation of the DB transaction has succeeded. If generation of the DB transaction has succeeded (YES in step s13411), the processing ends as “success”. If generation of the DB transaction has failed (NO in step s13411), the processing ends as “failure”.

On the other hand, if the server name is not valid (NO in step s13402), the flow advances to step s13403.

In step s13403, a corresponding database manager generate process is executed to generate a database manager of a database designated by the transaction generation window described using FIG. 45. In step s13404, an embedded DB transaction initialization process provided by the generated database manager is executed to initialize internal data of the embedded DB transaction described using FIG. 88. In step s13405, a DB connection process provided by the generated database manager is executed to establish connection to a database under the designated condition.

It is checked in step s13406 if connection to a database has succeeded as a result of the DB connection process. If connection has failed (NO in step s13406), the processing ends as “failure”. If connection has succeeded (YES in step s13403), the flow advances to step s13407.

In step s13407, information that pertains to connection is stored in the internal data of the DB transaction. In step s13408, a given database change notify destination is stored in the DB listener. In step s13409, the generated embedded DB transaction is added to the embedded DB transaction management list, and the processing ends as “success”.

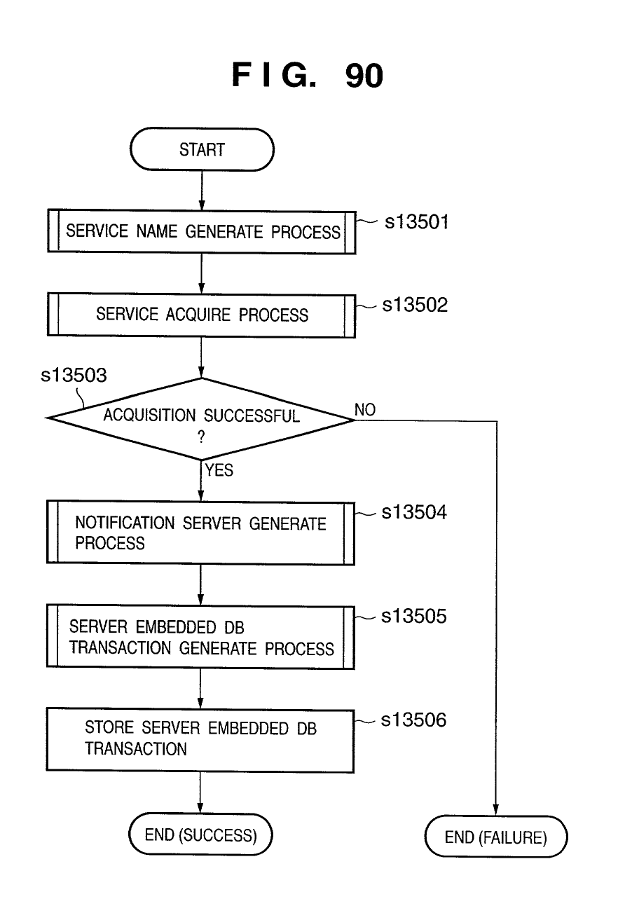

Details of the remote embedded DB transaction generate process in step s13410 will be described below using FIG. 90.

FIG. 90 is a flow chart showing details of the remote embedded DB transaction generate process in step s13410 of the fourth embodiment.

When the remote embedded DB transaction generate process is launched, a service name generate process is executed in step s13501 to generate a service name of a server DB manager on the basis of a given server name.

In step s13502, a service acquire process is executed to acquire a service corresponding to the generated service name. It is checked in step s13503 if acquisition of the service has succeeded. If acquisition of the service has failed (NO in step s13503), the processing ends as “failure”. On the other hand, if acquisition of the service has succeeded (YES in step s13503), the flow advances to step s13504.

In step s13504, a notification server generate process is executed to generate a notification server by expanding inter-device communication means from a given DB listener. In step s13505, a server embedded DB transaction generate process is executed to generate a server DB transaction by giving the generated notification server. In step s13506, the server embedded DB transaction is stored in internal data of the remote embedded DB transaction, and the processing ends as “success”.

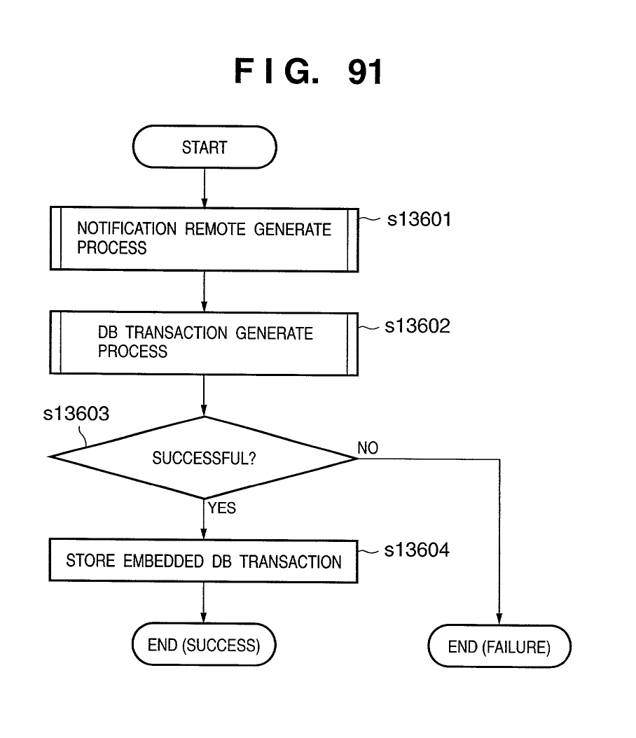

Details of the server embedded DB transaction generate process in step s13505 will be described below using FIG. 91.

FIG. 91 is a flow chart showing details of the server embedded DB transaction generate process in step s13505 of the fourth embodiment.

When the server embedded DB transaction generate process is launched, a notification remote generate process is executed in step s13601 to generate a notification remote hidden by the same interface as the DB listener of a local from the given notification server.

In step s13602, a DB transaction generate process is executed to generate a DB transaction without designating any server name. This DB transaction generate process is the same as that described above, and since no server name is designated, a local DB transaction is generated.

It is checked in step s13603 if generation of the DB transaction has succeeded as a result of the DB transaction generate process. If generation of the DB transaction has failed (NO in step s13603), the processing ends as “failure”. On the other hand, if generation of the DB transaction has succeeded (YES in step s13606), the flow advances to step s13604 to store the DB transaction in internal data of the server embedded DB transaction, and the processing ends as success.

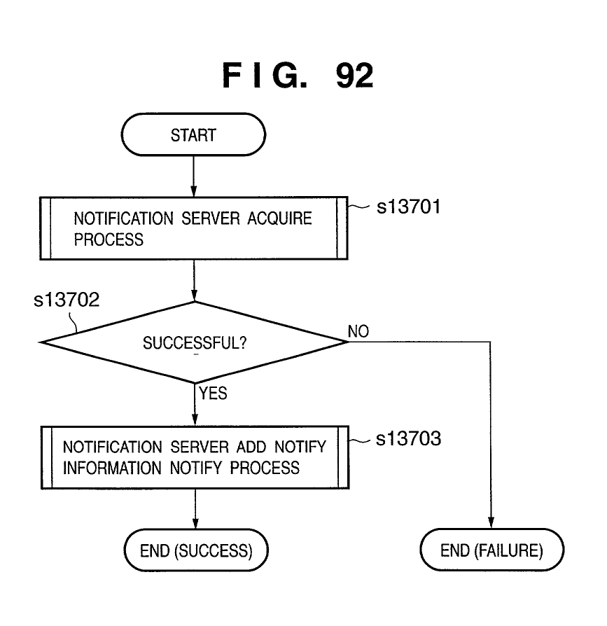

Details of a notification remote add notify information notify process as another embodiment of the DB listener add notify information notify process in step s11804 of the third embodiment will be described below using FIG. 92.

FIG. 92 is a flow chart showing details of the notification remote add notify information notify process of the fourth embodiment.

In the DB listener add notify information notify process of the third embodiment, notify information is sent to the notification destination present on the local device. In this embodiment, a method of sending notify information to a notify destination present on a different device will be described in detail below.

When the notification remote add notify information notify process is launched, a notification server acquire process is executed in step s13701 to acquire a notification server from information included in the internal data of the notification remote.

It is checked in step s13702 if acquisition of the notification server has succeeded as a result of the notification server acquire process. If acquisition of the notification server has failed (NO in step s13702), the processing ends as “failure”. On the other hand, if acquisition of the notification server has succeeded (YES in step s13702), the flow advances to step s13703.

In step s13703, a notification server add notify information notify process provided by the acquired notification server is executed to send notify information to the corresponding database, and the processing ends as “success”.

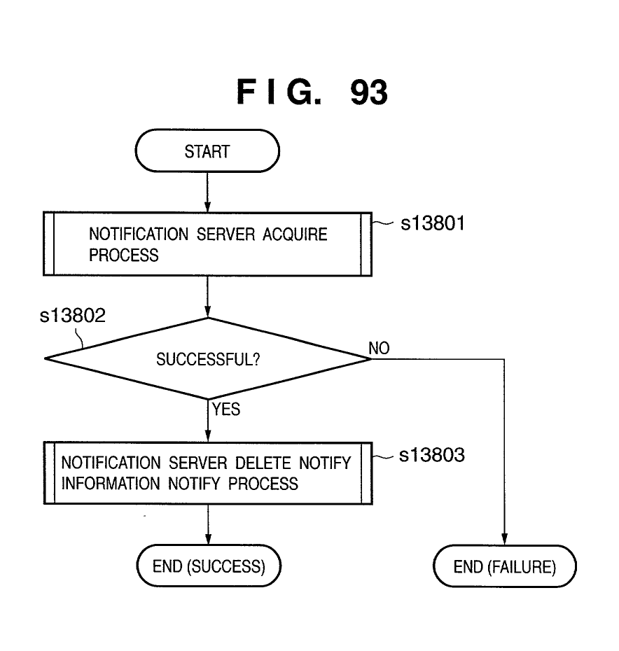

Details of a notification remote delete notify information notify process as another embodiment of the DB listener delete notify information notify process in step s11904 of the third embodiment will be described below using FIG. 93.

FIG. 93 is a flow chart showing details of the notification remote add notify information notify process of the fourth embodiment.

In the DB listener delete notify information notify process of the third embodiment, notify information is sent to the notification destination present on the local device. In this embodiment, a method of sending notify information to a notify destination present on a different device will be described in detail below.

When the notification remote delete notify information notify process is launched, a notification server acquire process is executed in step s13801 to acquire a notification server from information included in the internal data of the notification remote.

It is checked in step s13802 if acquisition of the notification server has succeeded as a result of the notification server acquire process. If acquisition of the notification server has failed (NO in step s13802), the processing ends as “failure”. On the other hand, if acquisition of the notification server has succeeded (YES in step s13802), the flow advances to step s13803.

In step s13803, a notification server delete notify information notify process provided by the acquired notification server is executed to send notify information to the corresponding database, and the processing ends as “success”.

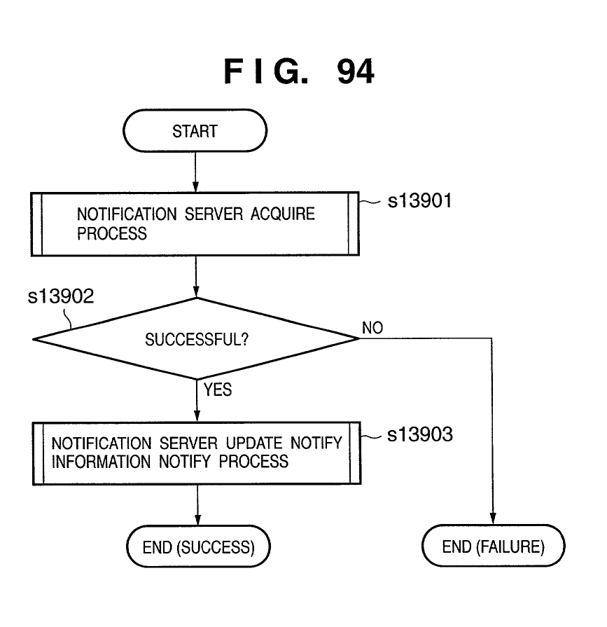

Details of a notification remote update notify information notify process as another embodiment of the DB listener update notify information notify process in step s12004 of the third embodiment will be described below using FIG. 94.

FIG. 94 is a flow chart showing details of the notification remote update notify information notify process of the fourth embodiment.

In the DB listener update notify information notify process of the third embodiment, notify information is sent to the notification destination present on the local device. In this embodiment, a method of sending notify information to a notify destination present on a different device will be described in detail below.

When the notification remote update notify information notify process is launched, a notification server acquire process is executed in step s13901 to acquire a notification server from information included in the internal data of the notification remote.

It is checked in step s13902 if acquisition of the notification server has succeeded as a result of the notification server acquire process. If acquisition of the notification server has failed (NO in step s13902), the processing ends as “failure”. On the other hand, if acquisition of the notification server has succeeded (YES in step s13902), the flow advances to step s13903.

In step s13903, a notification server update notify information notify process provided by the acquired notification server is executed to send notify information to the corresponding database, and the processing ends as “success”.

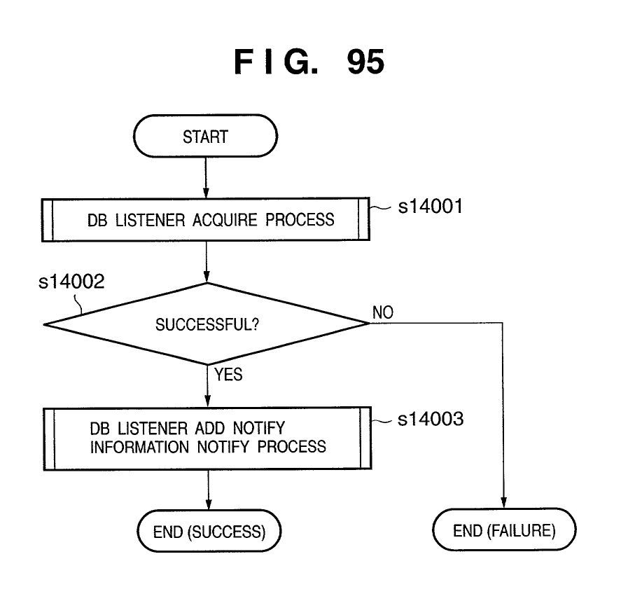

Details of the notification server add notify information notify process in step s13703 will be described below using FIG. 95.

FIG. 95 is a flow chart showing details of the notification server add notify information notify process in step s13703 of the fourth embodiment.

When the notification server add notify information notify process is launched, a DB listener acquire process is executed in step s14001 to acquire the previously registered database change notify destination. It is checked in step s14002 if acquisition of the database change notify destination has succeeded. If acquisition of the database change notify destination has failed (NO in step s14002), the processing ends as “failure”. On the other hand, if acquisition of the database change notify destination has succeeded (YES in step s14002), the flow advances to step s14003.

In step s14003, a DB listener add notify information notify process provided by the database change notify destination is executed to send notify information to the corresponding database, and the processing ends as “success”.

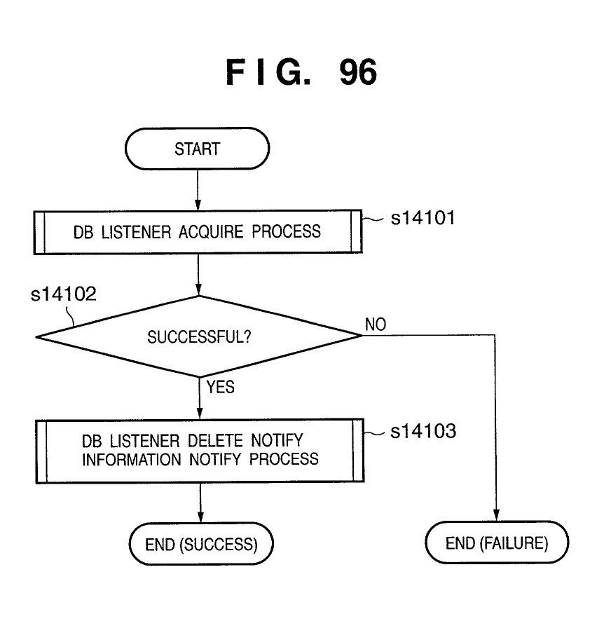

Details of the notification server delete notify information notify process in step s13803 will be described below using FIG. 96.

FIG. 96 is a flow chart showing details of the notification server delete notify information notify process in step s13803 of the fourth embodiment.

When the notification server delete notify information notify process is launched, a DB listener acquire process is executed in step s14101 to acquire the previously registered database change notify destination. It is checked in step s14102 if acquisition of the database change notify destination has succeeded. If acquisition of the database change notify destination has failed (NO in step s14102), the processing ends as “failure”. On the other hand, if acquisition of the database change notify destination has succeeded (YES in step s14102), the flow advances to step s14103.

In step s14103, a DB listener delete notify information notify process provided by the database change notify destination is executed to send notify information to the corresponding database, and the processing ends as “success”.

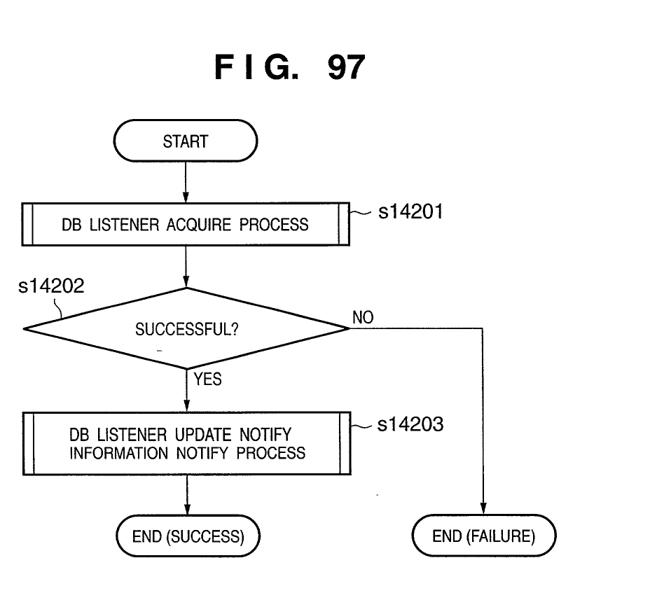

Details of the notification server update notify information notify process in step s13903 will be described below using FIG. 97.

FIG. 97 is a flow chart showing details of the notification server update notify information notify process in step s13903 of the fourth embodiment.

When the notification server update notify information notify process is launched, a DB listener acquire process is executed in step s14201 to acquire the previously registered database change notify destination. It is checked in step s14202 if acquisition of the database change notify destination has succeeded. If acquisition of the database change notify destination has failed (NO in step s14202), the processing ends as “failure”. On the other hand, if acquisition of the database change notify destination has succeeded (YES in step s14202), the flow advances to step s14203.

In step s14203, a DB listener update notify information notify process provided by the database change notify destination is executed to send notify information to the corresponding database, and the processing ends as “success”.

As described above, according to the fourth embodiment, since a database remote manipulation prepared by expanding inter-device communication means to allow a difference device to manipulate, and a database remote manipulation hiding process for hiding using the same interface as the database manipulation of the same device are done for a database that stores permanent data, a database on a device different from that on the same device can be similarly manipulated.

In this way, since methods of manipulating a database present on a given device and that present on another device are commonized without generating any overhead for inter-device communications in a single device, the need for acquisition of knowledge unique to a database and that required to implement inter-device communications can be obviated for an application developer.

Also, for a database interface provider, the need for acquisition of knowledge required to expand inter-device communication means can be obviated.

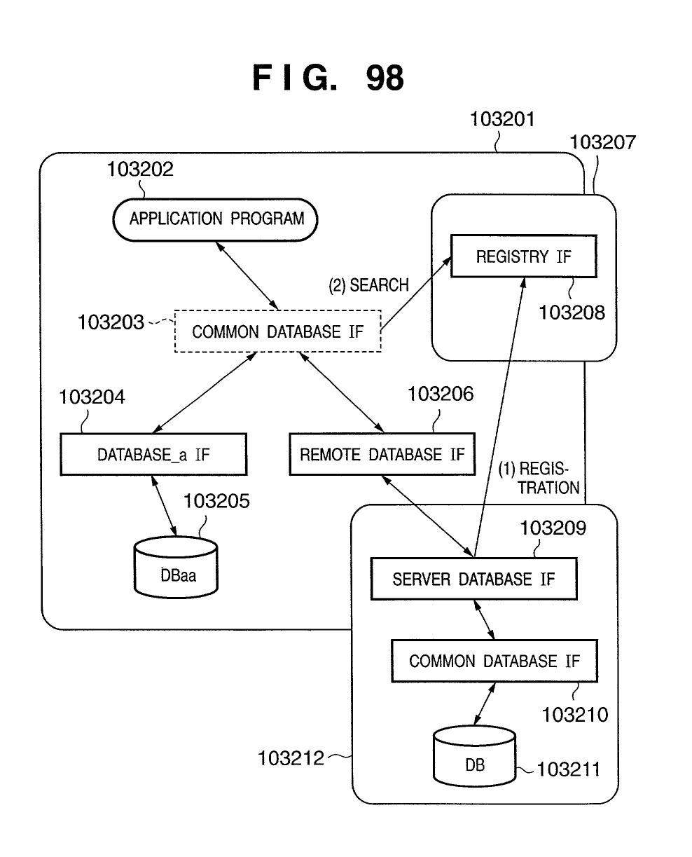

FIG. 98 shows an example of an application program in which a plurality of databases present on different devices are embedded using the fourth embodiment.

In order to access a database aa 103205 present on the same device 103201 as an application program 103202, and a database 103211 present on a different device 103212, only a common database interface 103203 is embedded.

At this time, in the common database interface 103203, a remote database interface 103206 obtained by acquiring a server database interface 103209 obtained by expanding inter-device communication means from an objective common database interface 103201 present on the different device using a registry interface 103208 of the device 103207, and hiding it by the common database interface 103203 is implemented.

For this reason, an application developer need only embed only the common database interface 103203 which does not recognize the (2) search method using the registry interface 103208, and differences of implementation methods of respective databases and devices. Conversely, a database interface provider can expand functions even if he or she does not know about the (1) registration method to the registry interface 103208 and an implementation method for expanding the inter-device communication means.

Note that the present invention may be applied to either a system constituted by a plurality of devices (e.g., a host computer, an interface device, a reader, a printer, and the like), or an apparatus consisting of a single equipment (e.g., a copying machine, a facsimile apparatus, or the like).

The objects of the present invention are also achieved by supplying a storage medium, which records a program code of a software program that can implement the functions of the above-mentioned embodiments to the system or apparatus, and reading out and executing the program code stored in the storage medium by a computer (or a CPU or MPU) of the system or apparatus.

In this case, the program code itself read out from the storage medium implements the functions of the above-mentioned embodiments, and the storage medium which stores the program code constitutes the present invention.

As the storage medium for supplying the program code, for example, a floppy disk, hard disk, optical disk, magneto-optical disk, CD-ROM, CD-R, magnetic tape, nonvolatile memory card, ROM, and the like may be used.

The functions of the above-mentioned embodiments may be implemented not only by executing the readout program code by the computer but also by some or all of actual processing operations executed by an OS (operating system) running on the computer on the basis of an instruction of the program code.

Furthermore, the functions of the above-mentioned embodiments may be implemented by some or all of actual processing operations executed by a CPU or the like arranged in a function extension board or a function extension unit, which is inserted in or connected to the computer, after the program code read out from the storage medium is written in a memory of the extension board or unit.

When the present invention is applied to the storage medium, the storage medium stores program codes corresponding to the flow charts shown in FIGS. 2, 8, 12, 15, 17 to 21, 24 to 27, 31 to 41, 47, 65 to 71, 73 to 84, and 89 to 97 described above.

As many apparently widely different embodiments of the present invention can be made without departing from the spirit and scope thereof, it is to be understood that the invention is not limited to the specific embodiments thereof except as defined in the appended claims.

What is claimed is:

1. An information processing apparatus for processing a database that manages data, comprising:
a plurality of types of databases for storing the data;
application interface interpretation processing means for interpreting and processing manipulations between said plurality of types of databases and an application program;
database interface interpretation processing means for interpreting and processing manipulations common to said plurality of types of databases; and
a plurality of individual database processing means for executing a processes unique to each database for each of said plurality of types of databases.

2. The apparatus according to claim 1, wherein said application interface interpretation processing means converts information to be processed into information that said database interface interpretation processing means can interpret, and into information that the application program can refer to.

3. The apparatus according to claim 2, wherein said application interface interpretation processing means converts an application object to be referred to by the application program and a database object to be stored in the database from one another.

4. The apparatus according to claim 1, wherein said database interface interpretation processing means selectively uses an appropriate one of said plurality of individual database processing means.

5. The apparatus according to claim 1, wherein each of said plurality of individual database processing means is implemented by expanding an interface provided by said database interface interpretation processing means.

6. An information processing method for processing a database that manages data, comprising:
a holding step of holding a plurality of types of databases for storing the data;
an application interface interpretation processing step of interpreting and processing manipulations between said plurality of types of databases and an application program;
a database interface interpretation processing step of interpreting and processing manipulations common to said plurality of types of databases; and
a plurality of individual database processing steps of executing a processes unique to each database for each of said plurality of types of databases.

7. The method according to claim 6, wherein the application interface interpretation processing step includes the step of converting information to be processed into information that said database interface interpretation processing step can interpret, and into information that the application program can refer to.

8. The method according to claim 7, wherein the application interface interpretation processing step includes the step of converting an application object to be referred to by the application program and a database object to be stored in the database from one another.

9. The method according to claim 6, wherein the database interface interpretation processing step includes the step of selectively using an appropriate one of the plurality of individual database processing steps.

10. The method according to claim 6, wherein each of the plurality of individual database processing steps is implemented by expanding an interface provided by the database interface interpretation processing step.

11. A computer readable memory that stores a program code of information processing for processing a database that manages data, comprising:
a program code of a holding step of holding a plurality of types of databases for storing the data;
a program code of an application interface interpretation processing step of interpreting and processing manipulations between said plurality of types of databases and an application program;
a program code of a database interface interpretation processing step of interpreting and processing manipulations common to said plurality of types of databases; and
program codes of a plurality of individual database processing steps of executing a processes unique to each database for each of said plurality of types of databases.

12. An information processing apparatus for processing a database that manages data, comprising:
a database for storing the data;
database manipulation means for manipulating said database;
inter-device communication means for making communications between said information processing apparatus and a different device;
database remote manipulation means for controlling manipulations of said database from the different device via said inter-device communication means; and
database remote manipulation hiding means for hiding said database remote manipulation means by the same interface as database manipulation means of the same device.

13. The apparatus according to claim 12, wherein said database manipulation hiding means manipulates said database using said database remote manipulation means, and
said database remote manipulation means manipulates said database using the database manipulation means.

14. An information processing apparatus for processing a database that manages data, comprising:
a database for storing the data;
database change notification means for notifying a change in database;
inter-device communication means for making communications between said information processing apparatus and a different device;
remote notification means for controlling notification of the change in database from the different device via said inter-device communication means; and
remote notification hiding means for hiding said remote notification means by the same interface as database change notification means of the same device.

15. The apparatus according to claim 14, further comprising:
database manipulation means for manipulating said database, and
in that said database manipulation means notifies a notification destination of the change in database using said remote notification hiding means,
said remote notification hiding means notifies the notification destination of the change in database using said remote notification means, and
said remote notification means notifies the notification destination of the change in database using said database change notification means.

16. The apparatus according to claim 12 or 15, further comprising:
database management means for managing a plurality of database manipulation means, and
in that said database management means manages only the database manipulation means that directly manipulates said database, and does not manage said database remote manipulation means and said database remote manipulation hiding means.

17. An information processing method of an information processing apparatus for processing a database that manages data, comprising:
a database manipulation step of manipulating a database for storing the data;
a inter-device communication step of making communications between said information processing apparatus and a different device;
a database remote manipulation step of controlling manipulations of said database from the different device via the inter-device communication step; and
a database remote manipulation hiding step of hiding the database remote manipulation step by the same interface as the database manipulation step of the same device.

18. The method according to claim 17, wherein the database manipulation hiding step includes the step of manipulating said database using the database remote manipulation step, and
the database remote manipulation step includes the step of manipulating said database using the database manipulation step.

19. An information processing method of an information processing apparatus for processing a database that manages data, comprising:
a database change notification step of notifying a change in database for storing the data;
an inter-device communication step of making communications between said information processing apparatus and a different device;
a remote notification step of controlling notification of the change in database from the different device via the inter-device communication step; and
a remote notification hiding step of hiding the remote notification step by the same interface as the database change notification step of the same device.

20. The method according to claim 19, further comprising:
a database manipulation step of manipulating said database, and
in that the database manipulation step includes the step of notifying a notification destination of the change in database using the remote notification hiding step,
a remote notification hiding step includes the step of notifying the notification destination of the change in database using the remote notification step, and
a remote notification step includes the step of notifying the notification destination of the change in database using the database change notification step.

21. The method according to claim 17 or 20, further comprising:
a database management step of managing the plurality of database manipulation steps in a storage medium, and
in that the database management step manages only the database manipulation step that directly manipulates said database, and does not manage the database remote manipulation step and the database remote manipulation hiding step.

22. A computer readable memory that stores a program code of information processing of an information processing apparatus for processing a database that manages data, comprising:
a program code of a database manipulation step of manipulating a database for storing the data;
a program code of an inter-device communication step of making communications between said information processing apparatus and a different device;
a program code of a database remote manipulation step of controlling manipulations of said database from the different device via the inter-device communication step; and
a program code of a database remote manipulation hiding step of hiding the database remote manipulation step by the same interface as the database manipulation step of the same device.

23. A computer readable memory that stores a program code of information processing of an information processing apparatus for processing a database that manages data, comprising:
a program code of a database change notification step of notifying a change in database for storing the data;
a program code of an inter-device communication step of making communications between said information processing apparatus and a different device;
a program code of the remote notification step of controlling notification of the change in database from the different device via the inter-device communication step; and
a program code of a remote notification hiding step of hiding the remote notification step by the same interface as the database change notification step of the same device.
